(19) United States
(12) Patent Application Publication
(10) Pub. No.: US 2024/0417320 A1
(43) Pub. Date: Dec. 19, 2024

(54) FOLDABLE SUBSTRATES AND METHODS OF MAKING

(71) Applicant: CORNING INCORPORATED, CORNING, NY (US)

(72) Inventors: ROBERT ALAN BELLMAN, ITHACA, NY (US); YUHUI JIN, PAINTED POST, NY (US); PETER JOSEPH LEZZI, CORNING, NY (US); CHUANCHE WANG, HORSEHEADS, NY (US)

(21) Appl. No.: 18/706,426

(22) PCT Filed: Oct. 26, 2022
(86) PCT No.: PCT/US2022/047827

§ 371 Date: May 1, 2024

Related U.S. Application Data
(60) Provisional application No. 63/275,053, filed on Nov. 3, 2021.

(51) Int. Cl. C03C 17/245; C03C 15/00; C03C 17/22; C03C 21/00; C23C 14/00; C23C 14/06; C23C 14/08; C23C 14/34; C23C 14/58; C23C 16/32; C23C 16/50; C23C 16/56

(52) U.S. Cl. CPC C03C 17/245; C03C 15/00; C03C 17/225; C03C 21/002; C23C 14/0036; C23C 14/0641; C23C 14/081; C23C 14/34; C23C 14/5873; C23C 16/325; C23C 16/50; C23C 16/56; C03C 2217/214; C03C 2217/281; C03C 2217/282; C03C 2218/153; C03C 2218/154; C03C 2218/155; C03C 2218/31; C03C 2218/33

(57) ABSTRACT

Foldable substrates comprise a first portion, a second portion, and a central portion positioned therebetween. The central portion comprises a first central surface area recessed from a first major surface by a first distance and a second central surface area. A second major surface comprises the second central surface area. A blunted edge extends around an entire periphery of the foldable substrate. The blunted edge comprising a first blunted surface area where the blunted edge meets the first major surface and a second blunted surface area where the blunted edge meets the second major surface. Methods comprise laminating the foldable substrate with support layers before removing a peripheral portion of an initial edge of the foldable substrate to form an intermediate edge. The intermediate edge is contacted with an etchant to form the blunted edge. Methods further comprise removing the support layers from the foldable substrate.

### CROSS-REFERENCE TO RELATED APPLICATION

This application claims the benefit of priority under 35 U.S.C. § 119 of U.S. Provisional Application Ser. No. 63/275,053 filed on Nov. 3, 2021, the content of which is relied upon and incorporated herein by reference in its entirety.

### FIELD

The present disclosure relates generally to foldable substrates and methods of making and, more particularly, to foldable substrates comprising a first central surface area recessed from a first major surface and methods of making foldable substrates.

### BACKGROUND

Glass-based substrates are commonly used, for example, in display devices, for example, liquid crystal displays (LCDs), electrophoretic displays (EPD), organic light-emitting diode displays (OLEDs), plasma display panels (PDPs), or the like.

There is a desire to develop foldable versions of displays as well as foldable protective covers to mount on foldable displays. Foldable displays and covers should have good impact and puncture resistance. At the same time, foldable displays and covers should have small minimum bend radii (e.g., about 10 millimeters (mm) or less). However, plastic displays and covers with small minimum bend radii tend to have poor impact and/or puncture resistance. Furthermore, conventional wisdom suggests that ultra-thin glass-based sheets (e.g., about 75 micrometers (μm or microns) or less thick) with small minimum bend radii tend to have poor impact and/or puncture resistance. Furthermore, thicker glass-based sheets (e.g., greater than 125 micrometers) with good impact and/or puncture resistance tend to have relatively large minimum bend radii (e.g., about 30 millimeters or more). Consequently, there is a need to develop foldable apparatus that have low minimum bend radii and good impact and puncture resistance.

### SUMMARY

There are set forth herein foldable substrates, foldable apparatus comprising foldable substrates, and methods of making foldable substrates comprising foldable substrates that comprise a first portion and a second portion and foldable apparatus comprising foldable substrates. The portions can comprise glass-based and/or ceramic-based portions, which can provide good dimensional stability, reduced incidence of mechanical instabilities, good impact resistance, and/or good puncture resistance. The first portion and/or the second portion can comprise glass-based and/or ceramic-based portions comprising one or more compressive stress regions, which can further provide increased impact resistance and/or increased puncture resistance. By providing a substrate comprising a glass-based and/or ceramic-based substrate, the substrate can also provide increased impact resistance and/or puncture resistance while simultaneously facilitating good folding performance. In aspects, the substrate thickness can be sufficiently large (e.g., from about 80 micrometers (microns or μm) to about 2 millimeters (mm)) to further enhance impact resistance and puncture resistance. Providing foldable substrates comprising a central portion comprising a central thickness that is less than a substrate thickness can enable a small parallel plate distance (e.g., about 10 millimeters or less) based on the reduced thickness in the central portion.

In aspects, the foldable apparatus and/or foldable substrates can comprise a recess, for example, a first central surface area recessed from a first major surface by a first distance. Providing a recess can increase bendability of the foldable apparatus since the central thickness can be less than the substrate thickness. Additionally, controlling properties of a material positioned in the recess can control the position of a neutral axis of the foldable apparatus and/or foldable substrates, which can reduce (e.g., mitigate, eliminate) the incidence of mechanical instabilities, apparatus fatigue, and/or apparatus failure.

Providing a blunted edge between the first major surface and the second major surface and/or between the first central surface area and the second major surface can increase an impact resistance and/or decrease an incidence of failure of the foldable substrate. Providing the blunted edge extending around an entire periphery of the foldable substrate can further increase an impact resistance and/or decrease an incidence of failure of the foldable substrate. Further, providing the blunted edge comprising the first blunted surface area, the second blunted surface area, and the central blunted surface area can reduce and/or avoid mechanical instabilities. For example, the foldable substrate can be symmetric about a first plane extending in a direction of the central thickness and along a midline between the first portion and the second portion, and/or the foldable substrate can be symmetric about a second plane extending in the direction of the central thickness and perpendicular to the first plane. Providing a central region of the central portion that can be symmetric about a third plane extending parallel to the first central surface area and the second central surface area at a midpoint therebetween. Since mechanical instabilities can develop from an asymmetry in a region of the foldable substrate as a region where stress and/or strain concentrates, providing the central region symmetric about the first plane, the second plane, and/or the third plane can reduce the incidence of mechanical instabilities. Since the regions comprising the smallest thickness are the most susceptible to mechanical instabilities (e.g., lower critical buckling strain, less stress required to reach a critical buckling strain), reducing the chance of mechanical instabilities in the central region comprising the central thickness reduces the incidence of mechanical instabilities for the foldable substrate overall.

Providing the foldable substrate with a central portion that can be substantially unstrengthened can reduce an incidence of mechanical instabilities. For example, the unstrengthened central portion can result in a chemical strengthening induced expansion strain profile of the foldable substrate measured from a midline of the central portion that monotonically increase, which can reduce an incidence of mechanical instabilities. Similarly, a profile of absolute values of the maximum tensile stress or the maximum compressive stress of the foldable substrate measured from a midline of the central portion can monotonically increase. Alternatively, providing a central portion comprising a depth of compression and/or depth of layer as a percentage of the central thickness that is less than or equal to the corresponding depth of the first portion as a percentage of the substrate thickness can reduce an incidence of mechanical instabilities while increasing the puncture resistance of the entire foldable substrate.

Method aspects of the disclosure can reduce an incidence of mechanical instabilities while increasing an impact resistance and/or increase a puncture resistance of the foldable apparatus. For example, methods can produce the blunted edge described above that includes the central blunted surface area. Using the method of aspects of the disclosure comprising etching the foldable substrate after removing an initial edge can produce an edge surface with minimal surface flaws (e.g., preexisting or generated during prior processing) since surface flaws can be treated (e.g., blunted, removed, reduced) during the etching. By forming the edge surface before chemically strengthening the foldable substrate, mechanical instabilities of the foldable substrate can be avoided during processing as well as in the final foldable substrate. Providing the first barrier layer and the second barrier layer over the central portion can reduce mechanical instabilities by establishing the chemical strengthening induced expansion strain profile, maximum tensile stress profile, and/or compressive stress profile described above, which can reduce an incidence of mechanical instabilities. Providing a barrier layer comprising a covalent solid can minimize an amount of material needed to achieve one of the above-mentioned profiles. Providing a barrier layer comprising aluminum nitride, aluminum oxynitride, and/or sputtered silicon nitride can achieve one of the above-mentioned profiles while being removable without damaging the foldable substrate.

Some example aspects of the disclosure are described below with the understanding that any of the features of the various aspects may be used alone or in combination with one another.

Aspect 1. A foldable substrate comprising:
a substrate thickness in a range from about 100 micrometers to about 2 millimeters defined between a first major surface and a second major surface opposite the first major surface;
a first portion comprising the substrate thickness between a first surface area of the first major surface and a second surface area of the second major surface;
a second portion comprising the substrate thickness between a third surface area of the first major surface and a fourth surface area of the second major surface;
a central portion comprising a central thickness in a range from about 25 micrometers to about 200 micrometers defined between a first central surface area and a second central surface area opposite the first central surface area, the first central surface area recessed from the first major surface by a first distance, and the second major surface comprising the second central surface area; and
a blunted edge extending around an entire periphery of the foldable substrate between the first major surface and the second major surface in the first portion and the second portion as well as between the first central surface area and the second central surface area in the central portion, the blunted edge comprising a first blunted surface area where the blunted edge meets the first major surface, and the blunted edge comprising a second blunted surface area where the blunted edge meets the second major surface.

Aspect 2. The foldable substrate of aspect 1, wherein a first thickness of the first blunted surface area in a direction of the substrate thickness is in a range from about 1 micrometer to about 50 micrometers, and a second thickness of the second blunted surface area in the direction of the substrate thickness is in a range from about 1 micrometer to about 50 micrometers.

Aspect 3. The foldable substrate of aspect 1, wherein a first thickness of the first blunted surface area in a direction of the substrate thickness is in a range from about 5 micrometers to about 25 micrometers, and a second thickness of the second blunted surface area in the direction of the substrate thickness is in a range from about 5 micrometers to about 25 micrometers.

Aspect 4. The foldable substrate of any one of aspects 1-3, wherein the first blunted surface area comprises a chamfered surface.

Aspect 5. The foldable substrate of any one of aspects 1-4, wherein the second blunted surface area comprises a chamfered surface.

Aspect 6. The foldable substrate of any one of aspects 1-5, wherein the first distance is about 20% to about 80% of the substrate thickness.

Aspect 7. The foldable substrate of aspect 6, wherein the first distance is about 50% to about 75% of the substrate thickness.

Aspect 8. The foldable substrate of any one of aspects 1-7, wherein the first portion comprises a first compressive stress region extending from the first major surface to a first depth of compression from the first major surface and a second compressive stress region extending from the second major surface to a second depth of compression from the second major surface, the second portion comprises a third compressive stress region extending from the first major surface to a third depth of compression from the first major surface and a fourth compressive stress region extending from the second major surface to a fourth depth of compression from the second major surface.

Aspect 9. The foldable substrate of aspect 8, further comprising a first depth of layer of one or more alkali metal ions associated with the first depth of compression, a second depth of layer of one or more alkali metal ions associated with the second depth of compression, a third depth of layer of one or more alkali metal ions associated with the third depth of compression, and a fourth depth of layer of one or more alkali metal ions associated with the fourth depth of compression.

Aspect 10. The foldable substrate of aspect 9, wherein the first depth of layer as a percentage of the substrate thickness is in a range from about 10% to about 30%, the second depth of layer as a percentage of the substrate thickness is in a range from about 10% to about 30%, the third depth of layer as a percentage of the substrate thickness is in a range from about 10% to about 30%, and the fourth depth of layer as a percentage of the substrate thickness is in a range from about 10% to about 30%.

Aspect 11. The foldable substrate of aspect 10, wherein the first depth of layer is substantially equal to the second depth of layer.

Aspect 12. The foldable substrate of any one of aspects 10-11, wherein the first depth of layer is substantially equal to the third depth of layer.

Aspect 13. The foldable substrate of any one of aspects 8-12, wherein the first depth of compression as a percentage of the substrate thickness is in a range from about 10% to about 30%, the second depth of compression as a percentage of the substrate thickness is in a range from about 10% to about 30%, the third depth of compression as a percentage of the substrate thickness is in a range from about 10% to about 30%, and the fourth depth of compression as a percentage of the substrate thickness is in a range from about 10% to about 30%.

Aspect 14. The foldable substrate of any one of aspects 9-13, wherein the first compressive stress region comprises a first maximum compressive stress of about 500 MegaPascals or more, the second compressive stress region comprises a second maximum compressive stress, the third compressive stress region comprises a third maximum compressive stress of about 500 MegaPascals or more, and the fourth compressive stress region comprises a fourth maximum compressive stress.

Aspect 15. The foldable substrate of aspect 14, wherein the second maximum compressive stress is about 500 MegaPascals or more, and the fourth maximum compressive stress is about 500 MegaPascals or more.

Aspect 16. The foldable substrate of any one of aspects 1-15, further comprising a first central compressive stress region extending to a first central depth of compression from the first central surface area, and a second central compressive stress region extending to a second central depth of compression extending from the second central surface area.

Aspect 17. The foldable substrate of aspect 16, wherein the first central depth of compression as a percentage of the central thickness is about 10% or less, and the second central depth of compression as a percentage of the central thickness is about 10% or less.

Aspect 18. The foldable substrate of any one of aspects 1-15, wherein the central portion is substantially unstrengthened.

Aspect 19. The foldable substrate of any one of aspects 1-18, wherein the foldable substrate is substantially symmetric about a first plane extending in the direction of the central thickness and along a midline between the first portion and the second portion.

Aspect 20. The foldable substrate of aspect 19, wherein the foldable substrate is substantially symmetric about a second plane extending in the direction of the central thickness and perpendicular to the first plane.

Aspect 21. The foldable substrate of any one of aspects 1-19, wherein a central region corresponding to the first central surface area is substantially symmetric about a third plane extending parallel to the first central surface area and positioned at a midpoint between the first central surface area and the second central surface area in a direction of central thickness.

Aspect 22. The foldable substrate of any one of aspects 1-21, wherein the substrate thickness is in a range from about 125 micrometers to about 200 micrometers.

Aspect 23. The foldable substrate of any one of aspects 1-22, wherein the central thickness is in a range from about 25 micrometers to about 80 micrometers.

Aspect 24. The foldable substrate of any one of aspects 1-23, wherein the foldable substrate comprises a glass-based substrate.

Aspect 25. The foldable substrate of any one of aspects 1-24, wherein the foldable substrate comprises a ceramic-based substrate.

Aspect 26. The foldable substrate of any one of aspects 1-25, wherein the foldable substrate achieves a parallel plate distance of 10 millimeters.

Aspect 27. The foldable substrate of any one of aspects 1-26, wherein the foldable substrate comprises a minimum parallel plate distance in a range from about 2 millimeters to about 10 millimeters.

Aspect 28. A foldable apparatus comprising:
the foldable substrate of any one of aspects 1-27; and
an adhesive comprising a first contact surface and a second contact surface opposite the first contact surface, the first contact surface facing the first major surface of the foldable substrate.

Aspect 29. The foldable apparatus of aspect 28, further comprising a polymer-based portion at least partially positioned in a recess defined between a first central plane defined by the first major surface and a second central plane defined by the first central surface area, the polymer-based portion comprising a third contact surface and a fourth contact surface opposite the third contact surface, the third contact surface facing the first central surface area, and the fourth contact surface area facing the first contact surface.

Aspect 30. The foldable apparatus of aspect 28, wherein at least a portion of the adhesive is positioned in a recess defined between a first central plane defined by the first major surface and a second central plane defined by the first central surface area.

Aspect 31. The foldable apparatus of any one of aspects 28-30, further comprising a display device attached to the second contact surface of the adhesive.

Aspect 32. The foldable apparatus of any one of aspects 28-31, further comprising a polymer layer disposed over the second major surface of the foldable substrate.

Aspect 33. A method of making a foldable substrate comprising a substrate thickness defined between a first major surface and a second major surface opposite the first major surface, a central thickness less than the substrate thickness defined between a first central surface area and a second central surface area opposite the first central surface area, the first central surface area recessed from the first major surface by a first distance, and a central portion comprising the central thickness positioned between a first portion and a second portion, the method comprising:
laminating the foldable substrate with a first support layer contacting the first major surface and a second support layer contacting the second major surface; then,
removing a peripheral portion of an initial edge of the foldable substrate to form an intermediate edge of the foldable substrate, the initial edge extending around an entire periphery of the foldable substrate between the first major surface and the second major surface in the first portion and the second portion as well as between the first central surface area and the second central surface area in the central portion; then,
contacting the intermediate edge with a second etchant to form a blunted edge extending around an entire periphery of the foldable substrate between the first major surface and the second major surface in the first portion and the second portion as well as between the first central surface area and the second central surface area in the central portion, the blunted edge comprising a first blunted surface area where the blunted edge meets the first major surface, and the blunted edge comprising a second blunted surface area where the blunted edge meets the second major surface;
removing the first support layer and the second support layer; then,
disposing a first barrier layer over the first central surface area and disposing a second barrier layer over the second central surface area opposite the first central surface area; then,
chemically strengthening the first portion and the second portion; and then,
removing the first barrier layer and removing the second barrier layer.

Aspect 34. A method of making a foldable substrate comprising a substrate thickness defined between a first major surface and a second major surface opposite the first major surface, the method comprising:
disposing a first etch mask over the first major surface in a first portion and disposing a second etch mask over the first major surface in a second portion, wherein a minimum distance is defined between the first etch mask and the second etch mask; then,
contacting a central portion of the foldable substrate with a first etchant to form a first central surface area, the first central surface area recessed from the first major surface by a first distance, the central portion positioned between the first portion and the second portion; then,
removing the first etch mask and removing the second etch mask; then,
laminating the foldable substrate with a first support layer contacting the first major surface and a second support layer contacting the second major surface; then,
removing a peripheral portion of an initial edge of the foldable substrate to form an intermediate edge of the foldable substrate, the initial edge extending around an entire periphery of the foldable substrate between the first major surface and the second major surface in the first portion and the second portion as well as between the first central surface area and the second central surface area in the central portion; then,
contacting the intermediate edge with a second etchant to form a blunted edge extending around an entire periphery of the foldable substrate between the first major surface and the second major surface in the first portion and the second portion as well as between the first central surface area and the second central surface area in the central portion, the blunted edge comprising a first blunted surface area where the blunted edge meets the first major surface, the blunted edge comprising a second blunted surface area where the blunted edge meets the second major surface, and the central portion comprises a central thickness defined between the first central surface area and a second central surface area opposite the first central surface area;
removing the first support layer and the second support layer; then,
disposing a first barrier layer over the first central surface area and disposing a second barrier layer over the second central surface area opposite the first central surface area; then,
chemically strengthening the first portion and the second portion; and then, removing the first barrier layer and removing the second barrier layer.

Aspect 35. The method of aspect 34, further comprising, before the contacting the central portion of the foldable substrate with the first etchant, disposing a third etch mask over the entire second major surface of the foldable substrate.

Aspect 36. The method of any one of aspects 34-35, wherein the first etchant comprises an acid.

Aspect 37. The method of aspect 36, wherein the first etchant comprises hydrofluoric acid.

Aspect 38. The method of any one of aspects 33-37, wherein the first barrier layer comprises one of aluminum nitride, aluminum oxynitride, sputtered silicon nitride, or combinations thereof.

Aspect 39. The method of any one of aspects 33-38, wherein the second barrier layer comprises the same material as the first barrier layer.

Aspect 40. The method of any one of aspects 33-39, wherein the disposing the first barrier layer comprises sputtering, chemical vapor deposition, thermal evaporation, or electron-beam deposition.

Aspect 41. The method of aspect 40, wherein the disposing the first barrier layer comprises sputtering.

Aspect 42. The method of any one of aspects 33-41, wherein a first barrier thickness of the first barrier layer is in a range from about 10 nanometers to about 2 micrometers.

Aspect 43. The method of any one of aspects 33-42, further comprising, before chemically strengthening the first portion and the second portion:
disposing a third etch mask over a portion of the first barrier layer, a width of the third etch mask is equal to or greater than the minimum distance; then,
removing another portion of the first barrier; and then,
removing the third etch mask.

Aspect 44. The method of aspect 43, wherein removing the another portion of the first barrier layer comprises contacting the another portion of the first barrier layer with an alkaline solution.

Aspect 45. The method of any one of aspects 43-44, further comprising, before chemically strengthening the first portion and the second portion:
disposing a fourth etch mask over a portion of the second barrier layer, a width of the fourth etch mask is equal to or greater than the minimum distance; then,
removing another portion of the second barrier; and then,
removing the fourth etch mask,
wherein the width of the fourth etch mask is substantially equal to the width of the third etch mask.

Aspect 46. The method of aspect 45, wherein removing the another portion of the second barrier layer comprises contacting the another portion of the second barrier layer with an alkaline solution.

Aspect 47. The method of any one of aspects 33-43, wherein removing the first barrier layer comprises contacting the first barrier layer with an alkaline solution.

Aspect 48. The method of any one of aspects 33-43, wherein removing the second barrier layer comprises contacting the second barrier layer with an alkaline solution.

Aspect 49. The method of any one of aspects 44 and 46-48 inclusive, wherein the alkaline solution comprises a temperature in a range from about 40° C. to about 90° C.

Aspect 50. The method of any one of aspects 33-49, wherein the second etchant comprises an acid.

Aspect 51. The method of aspect 50, wherein the second etchant comprises hydrofluoric acid.

Aspect 52. The method of any one of aspects 33-51, wherein the first etchant comprises the same composition as the second etchant.

Aspect 53. The method of any one of aspects 33-52, wherein a first thickness of the first blunted surface area in a direction of the substrate thickness is in a range from about 1 micrometer to about 50 micrometers, and a second thickness of the second blunted surface area in the direction of the substrate thickness is in a range from about 1 micrometer to about 50 micrometers.

Aspect 54. The method of any one of aspects 33-52, wherein a first thickness of the first blunted surface area in a direction of the substrate thickness is in a range from about 5 micrometers to about 25 micrometers, and a second thickness of the second blunted surface area in the direction of the substrate thickness is in a range from about 5 micrometers to about 25 micrometers.

Aspect 55. The method of any one of aspects 33-54, wherein contacting the intermediate edge with a second etchant comprises removing from about 1 micrometer to about 50 micrometers of material from the intermediate edge.

Aspect 56. The method of any one of aspects 33-55, wherein the first blunted surface area comprises a chamfered surface.

Aspect 57. The method of any one of aspects 33-56, wherein the second blunted surface area comprises a chamfered surface.

Aspect 58. The method of any one of aspects 33-57, wherein, before the chemically strengthening, the foldable substrate is substantially unstrengthened.

Aspect 59. The method of any one of aspects 33-58, further comprising, after removing the first etch mask and removing the second edge mask, further chemically strengthening the foldable substrate.

Aspect 60. The method of any one of aspects 33-59, wherein the first distance is about 20% to about 80% of the substrate thickness.

Aspect 61. The method of aspect 60, wherein the first distance is about 50% to about 75% of the substrate thickness.

Aspect 62. The method of any one of aspects 33-61, wherein the substrate thickness is in a range from about 125 micrometers to about 200 micrometers.

Aspect 63. The method of any one of aspects 33-62, wherein the foldable substrate comprises a glass-based substrate.

Aspect 64. The method of any one of aspects 33-63, wherein the foldable substrate comprises a ceramic-based substrate.

Aspect 65. The method of any one of aspects 33-64, wherein the foldable substrate achieves a parallel plate distance of 10 millimeters.

Aspect 66. The method of any one of aspects 33-65, wherein the foldable substrate comprises a minimum parallel plate distance in a range from about 2 millimeters to about 10 millimeters.

Aspect 67. The method of any one of aspects 33-66, wherein the foldable substrate is substantially symmetric about a first plane extending in the direction of the central thickness and along a midline between the first portion and the second portion.

Aspect 68. The method of aspect 67, wherein the foldable substrate is substantially symmetric about a second plane extending in the direction of the central thickness and perpendicular to the first plane.

Aspect 69. The method of any one of aspects 33-67, wherein a central region corresponding to the first central surface area is substantially symmetric about a third plane extending parallel to the first central surface area and positioned at a midpoint between the first central surface area and the second central surface area in a direction of the central thickness.

### BRIEF DESCRIPTION OF THE DRAWINGS

The above and other features and advantages of aspects of the present disclosure are better understood when the following detailed description is read with reference to the accompanying drawings, in which:

FIG. 1 is a schematic view of an example foldable apparatus in a flat configuration according to aspects, wherein a schematic view of the folded configuration may appear as shown in FIG. 7;

FIGS. 2-3 are cross-sectional views of the foldable apparatus along line 2-2 of FIG. 1 according to aspects;

FIG. 4 is a plan view of an example foldable apparatus in a flat configuration according to aspects;

FIGS. 5-6 are cross-sectional views of the foldable apparatus along lines 5-5 and 6-6 of FIG. 4, respectively, according to aspects;

FIG. 7 is a schematic view of example foldable apparatus of aspects of the disclosure in a folded configuration wherein a schematic view of the flat configuration may appear as shown in FIG. 1;

FIG. 8 is a cross-sectional view of a testing apparatus to determine the minimum parallel plate distance of a foldable apparatus taken along line 8-8 in FIG. 7;

FIG. 9 is a cross-sectional view of another testing apparatus to determine the minimum parallel plate distance of an example modified foldable apparatus taken along line 8-8 in FIG. 7;

FIG. 10 is a cross-sectional view of the foldable apparatus in a folded configuration taken along line 8-8 in FIG. 7, wherein a cross-sectional view of the flat configuration may appear as shown in FIG. 2;

FIG. 11 is a schematic plan view of an example consumer electronic device according to aspects;

FIG. 12 is a schematic perspective view of the example consumer electronic device of FIG. 11;

FIG. 13 is a flow chart illustrating example methods making foldable apparatus in accordance with aspects of the disclosure; and

FIGS. 14-33 schematically illustrate steps in methods of making a foldable substrate and/or foldable apparatus.

Throughout the disclosure, the drawings are used to emphasize certain aspects. As such, it should not be assumed that the relative size of different regions, portions, and substrates shown in the drawings are proportional to its actual relative size, unless explicitly indicated otherwise.

### DETAILED DESCRIPTION

Aspects will now be described more fully hereinafter with reference to the accompanying drawings in which example aspects are shown. Whenever possible, the same reference numerals are used throughout the drawings to refer to the same or like parts.

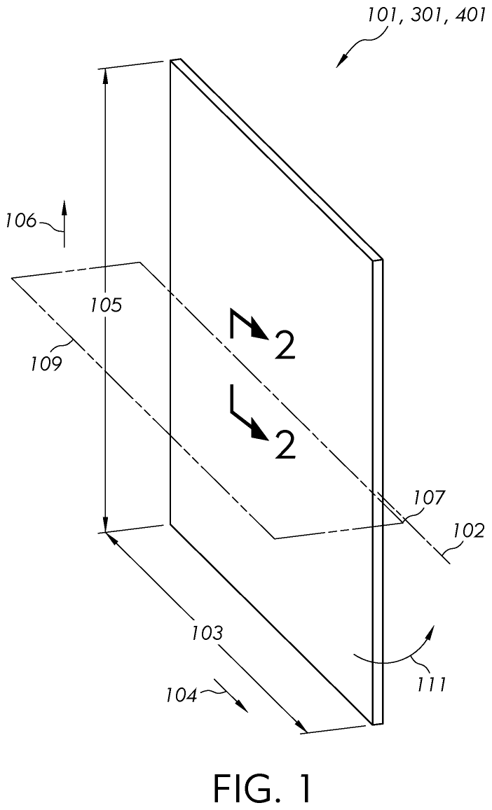

FIGS. 1-10 illustrate views of foldable apparatus 101, 301, 401, 701, 901, and 1001 comprising a foldable substrate 201 in accordance with aspects of the disclosure. Unless otherwise noted, a discussion of features of aspects of one foldable apparatus can apply equally to corresponding features of any aspects of the disclosure. For example, identical part numbers throughout the disclosure can indicate that, in some aspects, the identified features are identical to one another and that the discussion of the identified feature of one aspect, unless otherwise noted, can apply equally to the identified feature of any of the other aspects of the disclosure.

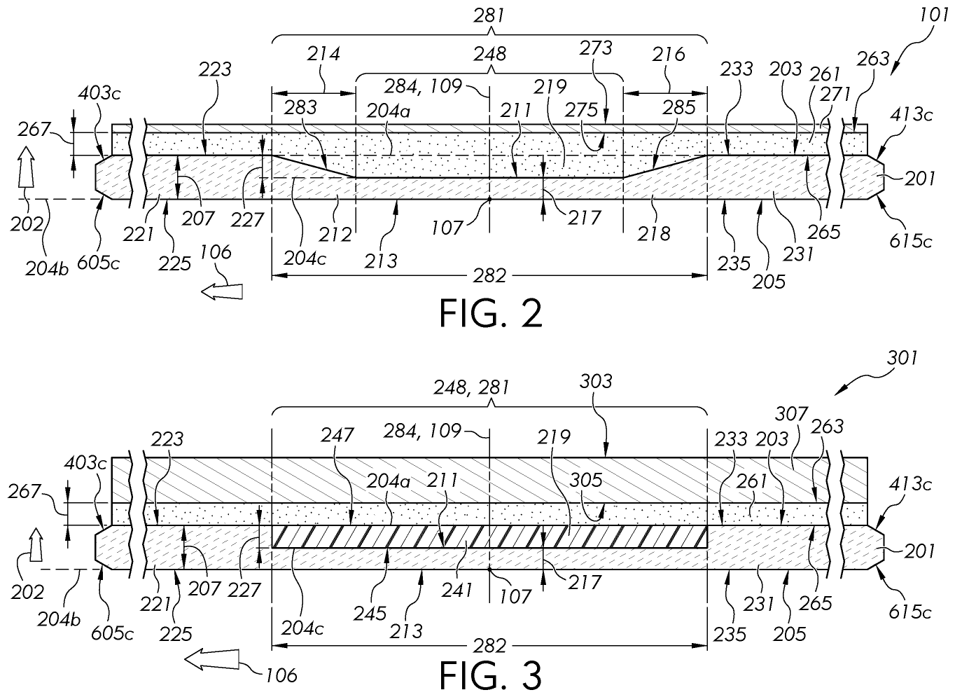

FIGS. 2-6 schematically illustrate example aspects of foldable apparatus 101, 301, and 401 comprising the foldable substrate 201 in accordance with aspects of the disclosure in an unfolded (e.g., flat) configuration while FIGS. 8-10 illustrates an example aspect of a foldable apparatus 701, 901, and 1001 comprising the foldable substrate 201 in accordance with aspects of the disclosure in a folded configuration.

The foldable apparatus 101, 301, and 401 comprise a first portion 221, a second portion 231, and a central portion 281 positioned between the first portion 221 and the second portion 231. In aspects, as shown in FIG. 2, the foldable apparatus 101 can comprise a release liner 271 although other substrates (e.g., a glass-based substrate and/or a ceramic-based substrate discussed throughout the application) may be used in further aspects rather than with the illustrated release liner 271. In aspects, as shown in FIG. 3, the foldable apparatus 301 can comprise a display device 307 although other substrates (e.g., a glass-based substrate and/or a ceramic-based substrate discussed throughout the application) may be used in further aspects rather than with the illustrated display device 307. In aspects, as shown in FIGS. 2-3, the foldable apparatus 101 can comprise an adhesive layer 261. In aspects, as shown in FIGS. 3 and 9-10, foldable apparatus 101, 901, and 1001 can comprise a polymer-based portion 241. As shown in FIGS. 2-3, the foldable substrate 201 can comprise a recess 219. It is to be understood that any of the foldable apparatus of the disclosure can comprise a second substrate (e.g., a glass-based substrate and/or a ceramic-based substrate), a release liner 271, a display device 307, a coating, an adhesive layer 261, and/or a polymer-based portion 241.

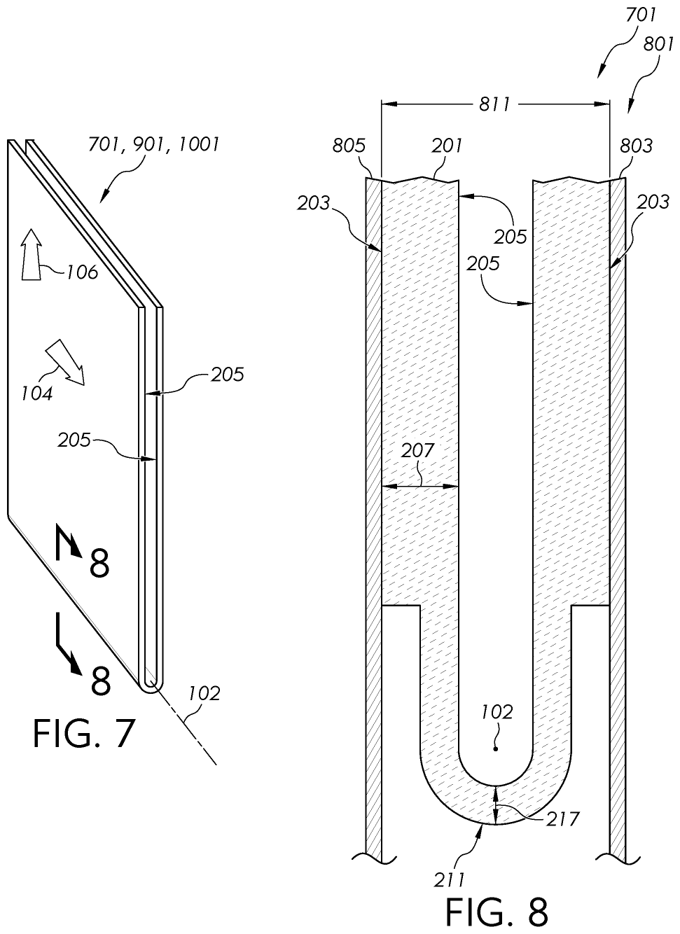

Throughout the disclosure, with reference to FIG. 1, the width 103 of the foldable apparatus 101, 301, 401, 701, 901, and/or 1001 is considered the dimension of the foldable apparatus taken between opposed edges of the foldable apparatus in a direction 104 of a fold axis 102 of the foldable apparatus, wherein the direction 104 also comprises the direction of the width 103. Furthermore, throughout the disclosure, the length 105 of the foldable apparatus 101, 301, 401, 701, 901, and/or 1001 is considered the dimension of the foldable apparatus 101, 301, 401, 701, 901, and/or 1001 taken between opposed edges of the foldable apparatus 101, 301, 401, 701, 901, and/or 1001 in a direction 106 perpendicular to the fold axis 102 of the foldable apparatus 101, 301, 401, 701, 901, and/or 1001. In aspects, as shown in FIGS. 1-3, the foldable apparatus of any aspects of the disclosure can comprise a fold plane 109 that includes the fold axis 102 when the foldable apparatus is in the flat configuration (e.g., see FIG. 1). In further aspects, as shown in FIGS. 2-3, the fold plane 109 can extend along the fold axis 102 and a direction of the substrate thickness 207 when the foldable apparatus is in the flat configuration (e.g., see FIGS. 2-3). The fold plane 109 may comprise a central axis 107 of the foldable apparatus. In aspects, the foldable apparatus can be folded in a direction 111 (e.g., see FIG. 1) about the fold axis 102 extending in the direction 104 of the width 103 to form a folded configuration (e.g., see FIGS. 7-10). As shown, the foldable apparatus may include a single fold axis to allow the foldable apparatus to comprise a bifold wherein, for example, the foldable apparatus may be folded in half. In further aspects, the foldable apparatus may include two or more fold axes with each fold axis including a corresponding central portion similar or identical to the central portion 281 discussed herein. For example, providing two fold axes can allow the foldable apparatus to comprise a trifold wherein, for example, the foldable apparatus may be folded with the first portion 221, the second portion 231, and a third portion similar or identical to the first portion or second portion with the central portion 281 and another central portion similar to or identical to the central portion positioned between the first portion and the second portion and between the second portion and the third portion, respectively.

The foldable substrate 201 can comprise a glass-based substrate and/or a ceramic-based substrate having a pencil hardness of 8H or more, for example, 9H or more. As used herein, pencil hardness is measured using ASTM D 3363-20 with standard lead graded pencils. Providing a glass-based foldable substrate and/or a ceramic-based foldable substrate can enhance puncture resistance and/or impact resistance.

In aspects, the foldable substrate 201 can comprise a glass-based substrate. As used herein, “glass-based” includes both glasses and glass-ceramics, wherein glass-ceramics have one or more crystalline phases and an amorphous, residual glass phase. A glass-based material (e.g., glass-based substrate) may comprise an amorphous material (e.g., glass) and optionally one or more crystalline materials (e.g., ceramic). Amorphous materials and glass-based materials may be strengthened. As used herein, the term “strengthened” may refer to a material that has been chemically strengthened, for example, through ion exchange of larger ions for smaller ions in the surface of the substrate, as discussed below. However, other strengthening methods, for example, thermal tempering, or utilizing a mismatch of the coefficient of thermal expansion between portions of the substrate to create compressive stress and central tension regions, may be utilized to form strengthened substrates. Exemplary glass-based materials, which may be free of lithia or not, comprise soda lime glass, alkali aluminosilicate glass, alkali-containing borosilicate glass, alkali-containing aluminoborosilicate glass, alkali-containing phosphosilicate glass, and alkali-containing aluminophosphosilicate glass. In aspects, glass-based material can comprise an alkali-containing glass or an alkali-free glass, either of which may be free of lithia or not. In aspects, the glass material can be alkali-free and/or comprise a low content of alkali metals (e.g., R₂O of about 10 mol % or less, wherein R₂O comprises Li₂O Na₂O, K₂O, or the more expansive list provided below). In one or more aspects, a glass-based material may comprise, in mole percent (mol %): SiO₂ in a range from about 40 mol % to about 80%, Al₂O₃ in a range from about 5 mol % to about 30 mol %, B₂O₃ in a range from 0 mol % to about 10 mol %, ZrO₂ in a range from 0 mol % to about 5 mol %, P₂O₅ in a range from 0 mol % to about 15 mol %, TiO₂ in a range from 0 mol % to about 2 mol %, R₂O in a range from 0 mol % to about 20 mol %, and RO in a range from 0 mol % to about 15 mol %. As used herein, R₂O can refer to an alkali-metal oxide, for example, Li₂O, Na₂O, K₂O, Rb₂O, and Cs₂O. As used herein, RO can refer to MgO, CaO, SrO, BaO, and ZnO. In aspects, a glass-based substrate may optionally further comprise in a range from 0 mol % to about 2 mol % of each of Na₂SO₄, NaCl, NaF, NaBr, K₂SO₄, KCl, KF, KBr, As₂O₃, Sb₂O₃, SnO₂, Fe₂O₃, MnO, MnO₂, MnO₃, Mn₂O₃, Mn₃O₄, Mn₂O₇. “Glass-ceramics” include materials produced through controlled crystallization of glass. In aspects, glass-ceramics have about 1% to about 99% crystallinity. Examples of suitable glass-ceramics may include Li₂O—Al₂O₃—SiO₂ system (i.e., LAS-System) glass-ceramics, MgO—Al₂O₃—SiO₂ system (i.e., MAS-System) glass-ceramics, ZnO×Al₂O₃×nSiO₂ (i.e., ZAS system), and/or glass-ceramics that include a predominant crystal phase including β-quartz solid solution, β-spodumene, cordierite, petalite, and/or lithium disilicate. The glass-ceramic substrates may be strengthened using the chemical strengthening processes. In one or more aspects, MAS-System glass-ceramic substrates may be strengthened in Li₂SO₄ molten salt, whereby an exchange of 2Li⁺ for Mg²⁺ can occur.

In aspects, the foldable substrate 201 can comprise a ceramic-based substrate. As used herein, “ceramic-based” includes both ceramics and glass-ceramics, wherein glass-ceramics have one or more crystalline phases and an amorphous, residual glass phase. Ceramic-based materials may be strengthened (e.g., chemically strengthened). In aspects, a ceramic-based material can be formed by heating a glass-based material to form ceramic (e.g., crystalline) portions. In further aspects, ceramic-based materials may comprise one or more nucleating agents that can facilitate the formation of crystalline phase(s). In aspects, ceramic-based materials can comprise one or more oxides, nitrides, oxynitrides, carbides, borides, and/or silicides. Example aspects of ceramic oxides include zirconia (ZrO₂), zircon (ZrSiO₄), an alkali-metal oxide (e.g., sodium oxide (Na₂O)), an alkali earth metal oxide (e.g., magnesium oxide (MgO)), titania (TiO₂), hafnium oxide (Hf₂O), yttrium oxide (Y₂O₃), iron oxides, beryllium oxides, vanadium oxide (VO₂), fused quartz, mullite (a mineral comprising a combination of aluminum oxide and silicon dioxide), and spinel (MgAl₂O₄). Example aspects of ceramic nitrides include silicon nitride (Si₃N₄), aluminum nitride (AlN), gallium nitride (GaN), beryllium nitride (Be₃N₂), boron nitride (BN), tungsten nitride (WN), vanadium nitride, alkali earth metal nitrides (e.g., magnesium nitride (Mg₃N₂)), nickel nitride, and tantalum nitride. Example aspects of oxynitride ceramics include silicon oxynitride, aluminum oxynitride, and a SiAlON (a combination of alumina and silicon nitride and can have a chemical formula, for example, Si₁₂₋ₘ₋ₙAlₘ₊ₙOₙN₁₆₋ₙ, Si₆₋ₙAlₙOₙN₈₋ₙ, or Si₂₋ₙAlₙO₁₊ₙN₂₋ₙ, where m, n, and the resulting subscripts are all non-negative integers). Example aspects of carbides and carbon-containing ceramics include silicon carbide (SiC), tungsten carbide (WC), an iron carbide, boron carbide (B₄C), alkali-metal carbides (e.g., lithium carbide (Li₄C₃)), alkali earth metal carbides (e.g., magnesium carbide (Mg₂C₃)), and graphite. Example aspects of borides include chromium boride (CrB₂), molybdenum boride (Mo₂B₅), tungsten boride (W₂B₅), iron boride, titanium boride, zirconium boride (ZrB₂), hafnium boride (HfB₂), vanadium boride (VB₂), Niobium boride (NbB₂), and lanthanum boride (LaB₆). Example aspects of silicides include molybdenum disilicide (MoSi₂), tungsten disilicide (WSi₂), titanium disilicide (TiSi₂), nickel silicide (NiSi), alkali earth silicide (e.g., sodium silicide (NaSi)), alkali-metal silicide (e.g., magnesium silicide (Mg₂Si)), hafnium disilicide (HfSi₂), and platinum silicide (PtSi).

Throughout the disclosure, a tensile strength, ultimate elongation (e.g., strain at failure), and yield point of a polymeric material (e.g., adhesive, polymer-based portion) is determined using ASTM D638 using a tensile testing machine, for example, an Instron 3400 or Instron 6800, at 23° C. and 50% relative humidity with a type I dogbone shaped sample. Throughout the disclosure, an elastic modulus (e.g., Young's modulus) and/or a Poisson's ratio is measured using ISO 527-1:2019. In aspects, the foldable substrate 201 can comprise an elastic modulus of about 1 GigaPascal (GPa) or more, about 3 GPa or more, about 5 GPa or more, about 10 GPa or more, about 100 GPa or less, about 80 GPa or less, about 60 GPa or less, or about 20 GPa or less. In aspects, the foldable substrate 201 can comprise an elastic modulus in a range from about 1 GPa to about 100 GPa, from about 1 GPa to about 80 GPa, from about 3 GPa to about 80 GPa, from about 3 GPa to about 60 GPa, from about 5 GPa to about 60 GPa, from about 5 GPa to about 20 GPa, from about 10 GPa to about 20 GPa, or any range or subrange therebetween. In further aspects, the foldable substrate 201 can comprise a glass-based material or a ceramic-based material comprising an elastic modulus in a range from about 10 GPa to about 100 GPa, from about 40 GPa to about 100 GPa, from about 60 GPa to about 100 GPa, from about 60 GPa to about 80 GPa, from about 80 GPa to about 100 GPa, or any range or subrange therebetween.

In aspects, the foldable substrate 201 can be optically transparent. As used herein, “optically transparent” or “optically clear” means an average transmittance of 70% or more in the wavelength range of 400 nm to 700 nm through a 1.0 mm thick piece of a material. In aspects, an “optically transparent material” or an “optically clear material” may have an average transmittance of 75% or more, 80% or more, 85% or more, or 90% or more, 92% or more, 94% or more, 96% or more in the wavelength range of 400 nm to 700 nm through a 1.0 mm thick piece of the material. The average transmittance in the wavelength range of 400 nm to 700 nm is calculated by measuring the transmittance of whole number wavelengths from about 400 nm to about 700 nm and averaging the measurements.

As shown in FIGS. 2-3, the foldable apparatus 101 and 301 comprise the foldable substrate 201 comprising a first major surface 203 and a second major surface 205 opposite the first major surface 203. As shown in FIGS. 2-3, the first major surface 203 can extend along a first plane 204a. The second major surface 205 can extend along a second plane 204b. In aspects, as shown, the second plane 204b can be parallel to the first plane 204a. As used herein, a substrate thickness 207 can be defined between the first major surface 203 and the second major surface 205 as a distance between the first plane 204a and the second plane 204b. In aspects, the substrate thickness 207 can be about 25 micrometers (μm) or more, about 80 μm or more, about 100 μm or more, about 125 μm or more, about 150 μm or more, about 2 millimeters (mm) or less, about 1 mm or less, about 800 μm or less, about 500 μm or less, about 300 μm or less, about 200 μm or less, about 180 μm or less, or about 160 μm or less. In aspects, the substrate thickness 207 can be in a range from about 25 μm to about 2 mm, from about 80 μm to about 2 mm, from about 100 μm to about 2 mm, from about 100 μm to about 1 mm, from about 100 μm to about 800 μm, from about 100 μm to about 500 μm, from about 125 μm to about 500 μm, from about 125 μm to about 300 μm, from about 125 μm to about 200 μm, from about 150 μm to about 200 μm, from about 150 μm to about 160 μm, or any range or subrange therebetween.

As shown in FIGS. 2-3, the first portion 221 of the foldable substrate 201 can comprise a first surface area 223 and a second surface area 225 opposite the first surface area 223. The first portion 221 will now be described with reference to the foldable apparatus 101 of FIG. 2 with the understanding that such description of the first portion 221, unless otherwise stated, can also apply to any aspects of the disclosure, for example, the foldable apparatus 301, 401, 701, 901, and/or 1001 illustrated in FIGS. 2-4 and 8-10. In aspects, as shown, the first surface area 223 can comprise a planar surface, and/or the second surface area 225 of the first portion 221 can comprise a planar surface. In further aspects, as shown, the second surface area 225 can be parallel to the first surface area 223. In aspects, as shown, the first major surface 203 can comprise the first surface area 223, and the second major surface 205 can comprise the second surface area 225. In further aspects, the first surface area 223 can extend along the first plane 204a. In further aspects, the second surface area 225 can extend along the second plane 204b. In aspects, the substrate thickness 207 can correspond to the distance between the first surface area 223 of the first portion 221 and the second surface area 225 of the first portion 221. In aspects, the substrate thickness 207 can be substantially uniform across the first surface area 223 (e.g., across its corresponding length (i.e., in the direction 106 of the length 105 of the foldable apparatus) and/or its corresponding width (i.e., in the direction 104 of the width 103 of the foldable apparatus)).

As shown in FIGS. 2-3, the second portion 231 of the foldable substrate 201 can comprise a third surface area 233 and a fourth surface area 235 opposite the third surface area 233. The second portion 231 will now be described with reference to the foldable apparatus 101 of FIG. 2 with the understanding that such description of the second portion 231, unless otherwise stated, can also apply to any aspects of the disclosure, for example, the foldable apparatus 301, 401, 701, 901, and/or 1001 illustrated in FIGS. 3-4 and 8-10. In aspects, as shown, the third surface area 233 of the second portion 231 can comprise a planar surface, and/or the fourth surface area 235 of the second portion 231 can comprise a planar surface. In further aspects, the third surface area 233 of the second portion 231 can be in a common plane (e.g., first plane 204a) with the first surface area 223 of the first portion 221. In further aspects, as shown, the fourth surface area 235 can be parallel to the third surface area 233. In further aspects, the fourth surface area 235 of the second portion 231 can be in a common plane (e.g., second plane 204b) with the second surface area 225 of the first portion 221. A second thickness can be defined between the third surface area 233 of the second portion 231 and the fourth surface area 235 of the second portion 231. In aspects, the second thickness can be within the range discussed above with regards to the substrate thickness 207. In further aspects, the second thickness can comprise the substrate thickness 207. In further aspects, as shown, the second thickness can be substantially equal to the substrate thickness 207 (e.g., first thickness). In aspects, the second thickness of the second portion 231 may be substantially uniform between the third surface area 233 and the fourth surface area 235 (e.g., across its corresponding length (i.e., in the direction 106 of the length 105 of the foldable apparatus) and/or its corresponding width (i.e., in the direction 104 of the width 103 of the foldable apparatus)).

As shown in FIGS. 2-4, the foldable substrate 201 can comprise a central portion 281 positioned between the first portion 221 and the second portion 231. In aspects, as shown, the central portion 281 can comprise a first central surface area 211. In further aspects, as shown in FIGS. 2-3, the central portion 281 can comprise a second central surface area 213 opposite the first central surface area 211. As shown in FIGS. 2-4, the first central surface area 211 of the central portion 281 can be positioned between the first surface area 223 and the third surface area 233. In further aspects, as shown in FIG. 2, the first central surface area 211 can correspond to a central region 248 of the central portion 281. As used herein, the central region 248 refers to the region of the central portion 281 comprising the first central surface area 211 extending along the third plane 204c and adjacent edge surfaces (e.g., blunted surface areas). In further aspects, as shown in FIGS. 2-3, the first central surface area 211 can extend along the third plane 204c when the foldable apparatus 101, 301, and/or 401 is in a flat configuration. The recess 219 can be defined between the first central surface area 211 (e.g., third plane 204c) and the first plane 204a. As shown in FIGS. 2-3, the second central surface area 213 of the central portion 281 can be positioned between the second surface area 225 and the fourth surface area 235. In further aspects, as shown in FIGS. 2-3, the second central surface area 213 can extend along the second plane 204b when the foldable apparatus 101 and/or 301 is in a flat configuration. In further aspects, as shown, the second major surface 205 can comprise the second central surface area 213.

In aspects, the third plane 204c can be substantially parallel to the first plane 204a and/or the second plane 204b. In further aspects, as shown in FIGS. 2-3, the first central surface area 211 can be recessed from the first major surface 203 by a first distance 227. In further aspects, the first distance 227 that the first central surface area 211 is recessed from the first plane 204a can be about 1 μm or more, about 5 μm or more, about 10 μm or more, about 25 μm or more, about 40 μm or more, about 80 μm or more, about 100 μm or more, about 125 μm or more, about 150 μm or more, about 1 mm or less, about 800 μm or less, about 500 μm or less, about 300 μm or less, about 200 μm or less, about 180 μm or less, or about 160 μm or less. In further aspects, the first distance 227 can be in a range from about 1 μm to about 1 mm, from about 1 μm to about 800 μm, from about 5 μm to about 800 μm, from about 5 μm to about 500 μm, from about 10 μm to about 500 μm, from about 10 μm to about 300 μm, from about 25 μm to about 300 μm, from about 25 μm to about 200 μm, from about 40 μm to about 200 μm, from about 80 μm to about 200 μm, from about 100 μm to about 200 μm, from about 125 μm to about 200 μm, from about 125 μm to about 180 μm, from about 125 μm to about 160 μm, from about 125 μm to about 150 μm, or any range or subrange therebetween. In further aspects, the first distance 227 that the first central surface area 211 is recessed from the first plane 204a as a percentage of the substrate thickness 207 can be about 1% or more, about 5% or more, about 10% or more, about 15% or more, about 20% or more, about 25% or more, about 30% or more, about 40% or more, about 50% or more, about 80% or less, about 75% or less, about 60% or less, about 50% or less, about 40% or less, about 35% or less, or about 30% or less. In further aspects, the first distance 227 as a percentage of the substrate thickness 207 can be in a range from about 1% to about 80%, from about 1% to about 75%, from about 1% to about 60%, from about 5% to about 60%, from about 5% to about 50%, from about 10% to about 50%, from about 10% to about 45%, from about 15% to about 45%, from about 20% to about 45%, from about 20% to about 35%, from about 20% to about 30%, from about 25% to about 30%, or any range or subrange therebetween. In further aspects, the first distance 227 as a percentage of the substrate thickness 207 can be in a range from about 5% to about 80%, from about 10% to about 80%, from about 15% to about 80%, from about 20% to about 80% from about 25% to about 80%, from about 30% to about 80%, from about 40% to about 80%, from about 50% to about 80%, from about 50% to about 75%, from about 50% to about 60%, or any range or subrange therebetween.

A central thickness 217 can be defined between the first central surface area 211 and the second central surface area 213, which can be measured as the distance between the third plane 204c and the second plane 204b. In aspects, the central thickness 217 can be about 1 μm or more, about 5 μm or more, about 10 μm or more, about 25 μm or more, about 40 μm or more, about 200 μm or less, about 150 μm or less, about 100 μm or less, about 80 μm or less, about 60 μm or less, or about 50 μm or less. In aspects, the central thickness 217 can be in a range from about 1 μm to about 200 μm, from about 1 μm to about 150 μm from about 1 μm to about 100 μm, from about 5 μm to about 100 μm, from about 10 μm to about 100 μm, from about 10 μm to about 80 μm, from about 25 μm to about 80 μm, from about 25 μm to about 60 μm, from about 40 μm to about 60 μm, or any range or subrange therebetween. In aspects, the central thickness 217 can be in a range from about 5 μm to about 200 μm, from about 10 μm to about 200 μm, from about 25 μm to about 200 μm, from about 25 μm to about 150 μm, from about 40 μm to about 150 μm, from about 40 μm to about 100 μm, from about 40 μm to about 80 μm, or any range or subrange therebetween. In aspects, the central thickness 217 as a percentage of the substrate thickness 207 can be about 0.5% or more, about 1% or more, about 2% or more, about 5% or more, about 6% or more, about 20% or less, about 13% or less, about 10% or less, or about 8% or less. In aspects, the central thickness 217 as a percentage of the substrate thickness 207 can be in a range from about 0.5% to about 20%, from about 0.5% to about 13%, from about 1% to about 13%, from about 1% to about 10%, from about 2% to about 10%, from about 2% to about 8%, from about 5% to about 8%, from about 6% to about 8%, or any range or subrange therebetween. In aspects, the central region 248 of the central portion 281 can correspond to a region comprising the central thickness 217. By providing the first central surface area 211 of the central portion 281 extending along the third plane 204c parallel to the second central surface area 213 of the central portion 281 extending along the second plane 204b, a uniform central thickness 217 may extend across the central portion 281 that can provide enhanced folding performance at a predetermined thickness for the central thickness 217. A uniform central thickness 217 across the central portion 281 can improve folding performance by preventing stress concentrations that would occur if a portion of the central portion 281 was thinner than the rest of the central portion 281.

In aspects, as shown in FIG. 2, the central portion 281 of the foldable substrate 201 can comprise a first transition region 212 comprising a first transition surface area 283 extending between the first surface area 223 and the first central surface area 211. In further aspects, as shown, a width (e.g., first transition width 214) of the first transition region 212 can be measured as the minimum distance in a direction 106 of the length 105 (see FIG. 1) between a portion of the first central surface area 211 extending along the third plane 204c and a portion of the first surface area 223. In even further aspects, the first transition width 214 of the first transition region 212 can be about 0.15 mm or more, about 0.2 mm or more, about 0.3 mm or more, about 0.4 mm or more, about 0.5 mm or more, about 0.6 mm or more, about 0.7 mm or more, about 0.8 mm or more, about 0.9 mm or more, about 2 mm or less, about 1.8 mm or less, about 1.5 mm or less, about 1.2 mm or less, about 1 mm or less, about 0.8 mm or less, about 0.7 mm or less, or about 0.5 mm or less. In even further aspects, the first transition width 214 of the first transition region 212 can be in a range from about 0.15 mm to about 2 mm, from about 0.2 mm to about 2 mm, from about 0.3 mm to about 2 mm, from about 0.4 mm to about 2 mm, about 0.5 mm to about 2 mm, from about 0.5 mm to about 1.8 mm, from about 0.6 mm to about 1.8 mm, from about 0.6 mm to about 1.5 mm, from about 0.7 mm to about 1.5 mm, from about 0.7 mm to about 1.2 mm, from about 0.8 mm to about 1.2 mm, from about 0.8 mm to about 1 mm, from about 0.9 mm to about 1 mm, or any range or subrange therebetween. In even further aspects, the first transition width 214 of the first transition region 212 can be in a range from about 0.5 mm to about 1.8 mm, from about 0.5 mm to about 1.5 mm, from about 0.5 mm to about 1.2 mm, from about 0.5 mm to about 1 mm, from about 0.6 mm to about 1 mm, from about 0.7 mm to about 1 mm, or any range or subrange therebetween. In even further aspects, the first transition width 214 of the first transition region 212 can be in a range from about 0.15 mm to about 1.8 mm, from about 0.15 mm to about 1.5 mm, from about 0.15 mm to about 1.2 mm, from about 0.15 mm to about 1 mm, from about 0.15 mm to about 0.7 mm, from about 0.15 mm to about 0.7 mm, from about 0.2 mm to about 0.5 mm, from about 0.3 mm to about 0.5 mm, from about 0.4 mm to about 0.5 mm, or any range or subrange therebetween. In aspects, as shown in FIG. 3, the foldable substrate 201 may not comprise a transition region but instead comprise a more abrupt (e.g., about 100 μm or less) and/or stepped change in thickness from the substrate thickness to the central thickness. Reducing a width of the first transition region and/or the second transition region can reduce a total chemical strengthening induced stress exerted on the central portion by the corresponding transition regions such that a strain of the first central surface area and/or the second central surface area is less than a critical buckling strain (e.g., onset of mechanical instabilities).

In aspects, as shown in FIG. 2, a thickness of the first transition region 212 can decrease between the substrate thickness 207 of the first portion 221 and the central thickness 217 of the central portion 281 (e.g., central region 248). In further aspects, as shown, a thickness of the first transition region 212 can smoothly decrease, monotonically decrease, and/or smoothly and monotonically decrease between the substrate thickness 207 of the first portion 221 and the central thickness 217 of the central portion 281. As used herein, a thickness decreases smoothly if changes in the cross-sectional area are smooth (e.g., gradual) rather than abrupt (e.g., step) changes in thickness. As used herein, a thickness decreases monotonically in a direction if the thickness decreases for a portion and for the rest of the time either stays the same, decreases, or a combination thereof (i.e., the thickness decreases but never increases in the direction). Providing a smooth shape of the first transition region and/or the second transition region can reduce optical distortions. Providing a monotonically decreasing thickness of the first transition region and/or the second transition region can reduce an incidence of mechanical instabilities and/or decrease a visibility of the transition region.

In aspects, as shown in FIG. 2, the first transition surface area 283 can comprise a linearly inclined surface extending between the first central surface area 211 and the first surface area 223. In aspects, although not shown, the first transition surface area can comprise a concave up shape, for example, with a local slope of the first transition surface area smoothly transitioning to a slope of the first central surface area 211 while a local slope of the first transition surface area is substantially different from a slope of the first surface area 223. In aspects, although not shown, the first transition surface area can comprise a sigmoid shape. In aspects, although not shown, a local slope of the first transition surface area can be greater at a midpoint of the first transition surface area than where the first transition surface area meets the first central surface area 211 and where the first transition surface area meets the first surface area 223. In aspects, although not shown, the first transition surface area can comprise a convex up shape, for example, with a local slope of the first transition surface area smoothly transitioning to a slope of the first surface area 223 while a local slope of the first transition surface area is substantially different from a slope of the first central surface area 211. In aspects, the second transition surface area can comprise one of the shapes or properties discussed above in this paragraph for the first transition surface area. For example, as shown in FIG. 2, the second transition surface area 285 can comprise a linearly inclined surface extending between the second central surface area 213 and the second surface area 225.

In aspects, as shown in FIG. 2, a thickness of the first transition region 212 can decrease at a constant rate (e.g., linearly change) from the substrate thickness 207 to the central thickness 217. In aspects, although not shown, a thickness of the first transition region can decrease slower where the first transition surface area meets the first central surface area 211 than at a midpoint of the first transition region and/or than where the first transition surface area meets the first surface area 223 (e.g., first portion 221). In aspects, although not shown, a thickness of the first transition region can decrease faster where the first transition surface area meets the first central surface area 211 than at a midpoint of the first transition region and/or than where the first transition surface area meets the first surface area 223. Providing a non-uniform slope of a surface area of the first transition region and/or the second transition region can reduce an amount of the corresponding transition region comprising intermediate thicknesses, for example, comprising a chemical strengthening induced expansion strain less than a portion of the corresponding transition region closer to the first central surface area and/or the second central surface area and/or than the first central surface area and/or the second central surface area.

In aspects, as shown in FIG. 2, the central portion 281 of the foldable substrate 201 can comprise a second transition region 218 comprising a second transition surface area 285 extending between the third surface area 233 and the first central surface area 211. In further aspects, as shown, a width (e.g., second transition width 216) of the second transition region 218 can be measured as the minimum distance in a direction 106 of the length 105 (see FIG. 1) between a portion of the first central surface area 211 extending along the third plane 204c and a portion of the third surface area 233. In even further aspects, the second transition width 216 of the second transition region 218 can be within one or more of the ranges discussed above for the first transition width 214. In still further aspects, the second transition width 216 of the second transition region 218 can be substantially equal to (e.g., equal to) the first transition width 214. In further aspects, as shown, a thickness of the second transition region 218 can smoothly decrease, monotonically decrease, or smoothly and monotonically decrease between the substrate thickness 207 of the second portion 231 and the central thickness 217 of the central portion 281. In even further aspects, as shown in FIG. 2, the second transition surface area 285 can comprise a linearly inclined surface extending between the first central surface area 211 and the third surface area 233. In even further aspects, the second transition surface area can comprise one of the shapes or properties discussed above with reference to the first transition surface area. In even further aspects, as shown in FIG. 2, a thickness of the second transition region 218 can decrease at a constant rate (e.g., linearly change) from the substrate thickness 207 to the central thickness 217. In further aspects, although not shown, a thickness of the second transition region can decrease slower where the second transition surface area meets the first central surface area 211 than at a midpoint of the second transition region and/or than where the second transition surface area meets the third surface area 233 (e.g., first portion 221). In further aspects, although not shown, a thickness of the second transition region can decrease faster where the second transition surface area meets the first central surface area 211 than at a midpoint of the second transition region and/or than where the second transition surface area meets the third surface area 233. In aspects, as shown in FIGS. 2-3, the second major surface 205 can comprise a surface opposite the first transition surface area 283 of the first transition region 212 and/or a surface opposite the second transition surface area 285 of the second transition region 218.

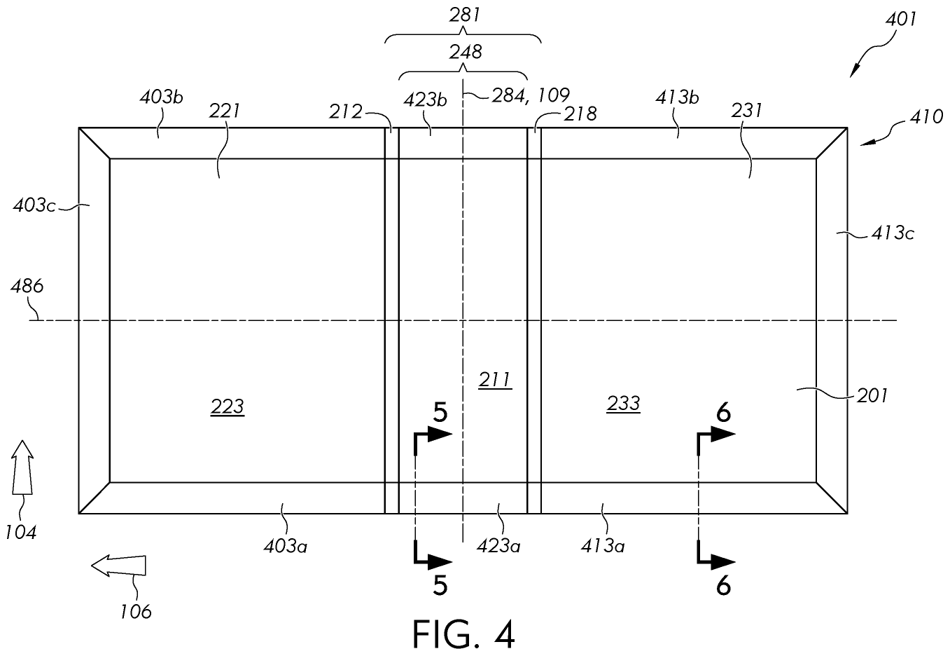

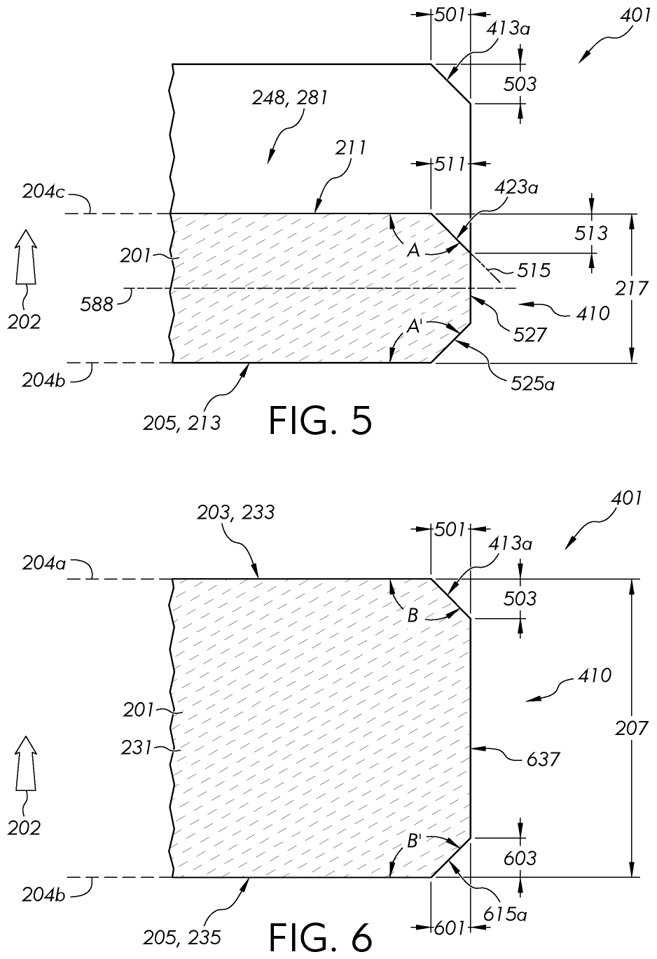

In aspects, as shown in FIGS. 4-6, the foldable substrate 201 can comprise a blunted edge 410 extending around an entire periphery of the foldable substrate 201. In further aspects, as shown in FIG. 6, the blunted edge 410 of the foldable substrate 201 can extend between the first major surface 203 and the second major surface 205, for example, in the second portion 231. In further aspects, as shown in FIG. 5, the blunted edge 410 of the foldable substrate 201 can extend between the first central surface area 211 and the second central surface area 213 in the central portion 281. In further aspects, as shown in FIG. 4, the blunted edge can be in the first portion 221 (i.e., between the first major surface 203 and the second major surface 205 in the first portion 221), the second portion 231 (i.e., between the first major surface 203 and the second major surface 205 in the second portion 231), and the central portion 281 (i.e., between the first central surface area 211 and the second central surface area 213, between the first transition surface area 283 and the second central surface area 213, and/or between the second transition surface area 285 and the second central surface area 213). In further aspects, as indicated by FIG. 4, the central blunted surface area 423b and the associated portion of the edge can be a mirror image of the profile shown in FIG. 5. In further aspects, as indicated by FIG. 4, the first blunted surface areas in the second portion 413b-c and associated second blunted surface areas (e.g., second blunted surface area 615c) can be similar to or identical to (e.g., a mirror image of) the profile shown in FIG. 6. In further aspects, as indicated by FIG. 4, the first blunted surface areas 403a-c and associated second blunted surface area (e.g., second blunted surface area 605c) can be similar to or identical to (e.g., a mirror image of) the profile shown in FIG. 6. For example, the entire first blunted surface area 403a-c and 413a-c can be similar to or identical to the profile shown in FIG. 6 for the first blunted surface area 413a. For example, the entire second blunted surface area (e.g., second blunted surface area 605c, 615a, 615c) can be similar to or identical to the profile shown in FIG. 6 for the second blunted surface area 615a.

Throughout the disclosure, an edge is considered to be “blunted” if a first surface area of the edge forms an obtuse internal angle with the first major surface, a second surface area of the edge forms an obtuse internal angle with the second major surface, and/or a central surface area of the edge forms an obtuse internal angle with the first central surface area. An angle is measured using two points of each surface, where each set of points is spaced along the corresponding surface by at least 1 μm. For example, as shown in FIG. 5, internal angle A is determined by finding the angle between the third plane 204c corresponding to the first central surface area 211 and a line 515 based on two points measured on a central blunted surface area 423a of the blunted edge 410 that are spaced apart by at least 1 μm, where the angle passes through the interior of the foldable substrate 201. As shown in FIG. 5, the internal angle A is obtuse because it is greater than 90°, and the internal angle A is an internal angle because it passes through the interior of the foldable substrate 201.

In aspects, as shown in FIG. 6, the blunted edge 410 can comprise a first blunted surface area 413a positioned where the blunted edge 410 meets the first major surface 203. In further aspects, as shown in FIG. 6, an internal angle B between the first blunted surface area 413a and the first major surface 203 can be obtuse. In further aspects, as shown in FIG. 4, the first blunted surface areas 413a-c can extend around the outer periphery of the second portion 231 where the blunted edge 410 meets the first major surface 203. In even further aspects, the first blunted surface areas 413a-c can comprise obtuse internal angles, for example, the obtuse internal angles can be substantially equal to the internal angle B. In further aspects, as shown in FIG. 4, the first blunted surface areas 403a-c can extend around the outer periphery of the first portion 221 where the blunted edge 410 meets the first major surface 203. In even further aspects, the first blunted surface areas 403a-c can comprise obtuse internal angles, for example, the obtuse internal angles can be substantially equal to the internal angle B. In aspects, as shown in FIGS. 5-6, the first blunted surface area 413a can comprise a first thickness 503 in the direction 202 of the substrate thickness 207. In further aspects, the first thickness 503 can be about 1 μm or more, about 2 μm or more, about 5 μm or more, about 10 μm or more, about 15 μm or more, about 100 μm or less, about 50 μm or less, about 40 μm or less, about 30 μm or less, or about 25 μm or less. In further aspects, the first thickness 503 can be in a range from about 1 μm to about 50 μm, from about 1 μm to about 40 μm, from about 2 μm to about 40 μm, from about 2 μm to about 30 μm, from about 5 μm to about 30 μm, from about 5 μm to about 25 μm, from about 10 μm to about 25 μm, from about 15 μm to about 25 μm, or any range or subrange therebetween. In aspects, as shown in FIGS. 5-6, the first blunted surface area 413a can comprise a first width 501 perpendicular to the first thickness 503. In further aspects, the first width 501 can be within one or more of the ranges discussed above for the first thickness 503. In even further aspects, the first width 501 can be substantially equal to the first thickness 503.

In aspects, as shown in FIG. 6, the blunted edge 410 can comprise a second blunted surface area 615a positioned where the blunted edge 410 meets the second major surface 205. In further aspects, as shown, the second blunted surface area 615a can comprise the internal angle B′ that can be obtuse. In further aspects, although not shown, the second blunted surface area (e.g., second blunted surface area 615a shown in FIG. 6 and second blunted surface area 615c shown in FIGS. 2-3) can extend around the outer periphery of the second portion 231 where the blunted edge 410 meets the second major surface 205 (e.g., similar to or identical to the first blunted surface area 413a-c discussed above with reference to FIG. 4). In further aspects, although not shown, the second blunted surface area (e.g., second blunted surface area 605c) can extend around the outer periphery of the first portion 221 where the blunted edge 410 meets the second major surface 205 (e.g., similar to or identical to the first blunted surface area 403a-c discussed above with reference to FIG. 4). In aspects, as shown in FIG. 6, the second blunted surface area 615a can comprise a second thickness 603 in the direction 202 of the substrate thickness 207. In further aspects, the second thickness 603 within one or more of the ranges discussed above for the first thickness 503. In even further aspects, the first thickness 503 can be substantially equal to the second thickness 603. In aspects, as shown in FIG. 6, the second blunted surface area 615a can comprise a second width 601 perpendicular to the second thickness 603. In further aspects, the second width 601 can be within one or more of the ranges discussed above for the first thickness 503. In even further aspects, the first width 501 can be substantially equal to the second width 601.

In aspects, as shown in FIG. 5, the blunted edge 410 can comprise a central blunted surface area 423a positioned where the blunted edge meets the first central surface area 211. In further aspects, as shown, the internal angle A between the central blunted surface area 423a and the first central surface area 211 can be an obtuse angle. In further aspects, as shown in FIG. 4, the central blunted surface areas 423a and 423b can be positioned on opposite sides of the first central surface area 211, and/or the central blunted surface area 423a-b can extend between portions of the first blunted surface area 403a-c and 413a-c (e.g., with the central blunted surface area 423a positioned between the first blunted surface area 403a and the first blunted surface area 413a). In further aspects, an internal angle of the central blunted surface area 423b can be substantially equal to the internal angle A. In aspects, as shown in FIG. 5, the second blunted surface area of the blunted edge 410 can comprise a second blunted surface area 525a opposite the central blunted surface area 423a. In further aspects, as shown, an internal angle A′ between the second blunted surface area 525a and the second major surface 205 (e.g., second central surface area 213) can be an obtuse angle In even further aspects, the internal angle A′ can be substantially equal to the internal angle B′. In further aspects, although not shown, the second blunted surface area can be opposite the central blunted surface area 423b and comprise an obtuse internal angle with the second major surface 205 (e.g., second central surface area 213), which can be substantially equal to the internal angle A′. In further aspects, as shown in FIG. 5, the central region 248 (e.g., central portion 281) can comprise a first edge surface 527 positioned between the central blunted surface area 423a and the second blunted surface area 525a. In further aspects, as shown in FIG. 6, the second portion 231 can comprise a first edge surface 637 positioned between the first blunted surface area 413a and the second blunted surface area 615a.

In aspects, as shown in FIG. 5, the central blunted surface area 423a can comprise a third thickness 513 in the direction 202 of the substrate thickness 207. In further aspects, the third thickness 513 within one or more of the ranges discussed above for the first thickness 503. In even further aspects, the first thickness 503 can be substantially equal to the third thickness 513. In even further aspects, the second thickness 603 can be substantially equal to the third thickness 513. In aspects, as shown in FIG. 5, the central blunted surface area 423a can comprise a third width 511 perpendicular to the third thickness 513. In further aspects, the third width 511 can be within one or more of the ranges discussed above for the first width 501 and/or the first thickness 503. In even further aspects, the first width 501 can be substantially equal to the third width 511. In even further aspects, the second width 601 can be substantially equal to the third width 511.

As shown in FIGS. 5-6, the blunted edge 410 is “blunted” because the internal angle A between the first major surface 203 and the first blunted surface area 413a of the blunted edge 410 is obtuse, the angle A′ between the second major surface 205 and the second blunted surface area 525a of the blunted edge 410 is obtuse (see FIG. 5), and the internal angle B between the first central surface area 211 and the central blunted surface area 423a is obtuse (see FIG. 5). In aspects, as shown in FIGS. 5-6, the first blunted surface area 403a-c and 413a-c can comprise a chamfered surface such that the internal angle B is substantially constant along the first blunted surface area (e.g., first blunted surface area 403a). In aspects, as shown in FIGS. 5-6, the second blunted surface area 525a, 605c, and 615a can comprise a chamfered surface such that the internal angle A′ and/or B′ is substantially constant along the second blunted surface area 525a, 605c, and 615a. In further aspects, the internal angle A′ can be substantially equal to the internal angle B′. In aspects, as shown in FIG. 5, the central blunted surface area 423a-b can comprise a chamfered surface such that the internal angle A is substantially constant along the central blunted surface area 423a-b. In aspects, although not shown, the first blunted surface area, the second blunted surface area, and/or the central blunted surface area can comprise a curved surface (e.g., ellipsoidal, circular) or a curvilinear surface. Providing the blunted edge can reduce stress concentrations where the edge meets the first major surface, the second major surface, and/or the first major surface, which can increase an impact resistance and/or decrease an incidence of failure of the foldable substrate.

In aspects, as shown in FIG. 4, the foldable substrate 201 can be substantially symmetric about a first plane 284 extending in a direction of the central thickness 217 (see FIGS. 2-3 and 5) and along a midline between the first portion 221 and the second portion 231. For example, the first blunted surface areas 403a-c in the first portion 221 can be mirror images of the first blunted surface areas 413a-c in the second portion 231, the central blunted surface areas 423a-b can be symmetric about the first plane 284, and the second blunted surface areas (e.g., second blunted surface area 605c in the first portion 221) in the first portion 221 can be mirror images of the second blunted surface areas (e.g., second blunted surface areas 615a and 615c) in the second portion 231. In further aspects, as shown, the first plane 284 can be coincident with the fold plane 109. In aspects, as shown in FIG. 4, the foldable substrate 201 can be substantially symmetric about a second plane 486 extending in the direction of the central thickness 217 (see FIGS. 2-3 and 5) and perpendicular to the first plane 284. For example, the first blunted surface areas 403a and 413a can be mirror images of the first blunted surface areas 403b and 413b, the central blunted surface area 423a can be a mirror image of the central blunted surface area 423b, the central blunted surface areas 403c and 413c can be symmetric about the second plane 486, and the corresponding second blunted surface areas can have the same relationships as the corresponding first blunted surface areas. In aspects, as shown in FIG. 5, the central region 248 of the central portion 281 can be symmetric about a third plane 588 extending parallel to the first central surface area 211 and the second central surface area 213 (e.g., second major surface 205) at a midpoint therebetween (i.e., half of the central thickness 217 from the first central surface area 211 and half of the central thickness 217 from the second central surface area 213). For example, as shown, the central blunted surface areas 423a-b can be symmetric with the second blunted surface areas (e.g., second blunted surface area 525a).

Foldable substrates (e.g., foldable substrate 201) can be subject to a variety of types of mechanical instabilities. Throughout the disclosure, mechanical instabilities include localized mechanical instabilities as well as systemic mechanical instabilities. As used herein, a localized mechanical instability manifests as a deviation (e.g., a plurality of deviations) from a plane of a surface (e.g., first central surface area) without distorting the surface as a whole, for example, buckling and/or wrinkling. As used herein, a systemic mechanical instability manifests as a distortion of an entire surface from a plane, for example, warpage. An onset of mechanical instability (e.g., localized mechanical instability) may occur when a critical strain (e.g., critical buckling strain) of a portion (e.g., central portion) of the foldable substrate is exceeded. For example, a critical buckling strain of a central portion resembling the foldable substrate 201 of FIGS. 2-4 comprising a width of the central portion 281 of 20 mm can be approximated by 10⁶ times the central thickness squared minus 23 times the central thickness plus 0.0006. For example, without wishing to be bound by theory, a critical buckling strain of a central portion resembling the foldable substrate 201 of FIGS. 2-4 comprising a central thickness 217 of 30 μm can be approximated by 3×10⁷ divided by a square of the width of the central portion 281.

Chemical strengthening induced expansion strain of the central portion of the foldable substrate resulting from chemically strengthening the foldable substrate is proportional to a product of the network dilation coefficient (B), a concentration difference (C), and a difference between a depth of layer of the central portion divided by the central thickness and a depth of layer of the first portion (or second portion) divided by the substrate thickness. As used herein, a network dilation coefficient refers to how much a volume of a foldable substrate (e.g., first portion, second portion, central portion) expands as a result of an increase in the concentration of one or more alkali ions exchanged into the substrate (e.g., as a result of chemical strengthening). In aspects, a network dilation constant of the first portion and/or a network dilation constant of the second portion can be substantially equal to a network dilation constant of the central portion, for example, if the first portion and/or the second portion and the central portion all comprise the same material prior to the chemically strengthening. Without wishing to be bound by theory, it has been observed that mechanical instabilities in the central portion occur when the chemical strengthening induced expansion strain of the central portion is not greater than that in the first transition region and/or the second transition region.

One way to reduce and/or avoid mechanical instabilities is to produce a chemical strengthening induced expansion strain profiles where the strain monotonically increases as thickness increases (i.e., away from a midline of the central portion between the first portion and the second portion). For example, by providing a substantially unstrengthened central portion (e.g., first transition region, central region, second transition region), the chemical strengthening induced expansion strain can be 0 in the central portion with positive chemically strengthened induced expansion strain in the first portion and the second portion. In aspects, the maximum tensile stress of the central region can be less than or equal to the maximum tensile stress of the first transition region and/or the second transition region. In aspects, a depth of layer of the central region as a percentage of the central thickness can be less than or equal to a depth of layer of the first transition region and/or the second transition region as a percentage of a local thickness where the measurement was taken. In aspects, a depth of compression of the central region as a percentage of the central thickness can be less than or equal to a depth of compression of the first transition region and/or the second transition region as a percentage of a local thickness where the measurement was taken.

Another way to reduce and/or avoid mechanical instabilities is to provide a central portion (e.g., central region) that is symmetric along one or more planes. Without wishing to be bound by theory, mechanical instabilities can develop from an asymmetry in a region of the foldable substrate, where the strain concentrates. In aspects, as discussed above with reference to FIG. 4, the foldable substrate 201 (e.g., central portion 281, central region 248) can be substantially symmetric about a first plane 284 extending in a direction of the central thickness 217 (see FIGS. 2-3 and 5) and along a midline between the first portion 221 and the second portion 231. In aspects, as discussed above with reference to FIG. 4, the foldable substrate 201 (e.g., central portion 281, central region 248) can be substantially symmetric about a second plane 486 extending in the direction of the central thickness 217 (see FIGS. 2-3 and 5) and perpendicular to the first plane 284. In aspects, as discussed above with reference to FIG. 5, the central region 248 of the central portion 281 can be symmetric about a third plane 588 extending parallel to the first central surface area 211 and the second central surface area 213 (e.g., second major surface 205) at a midpoint therebetween (i.e., half of the central thickness 217 from the first central surface area 211 and half of the central thickness 217 from the second central surface area 213). In particular, providing a central region 248 that is symmetric about the first plane 284, the second plane 486, and the third plane 588 can reduce and/or avoid mechanical instabilities in the central portion. Since the regions comprising the smallest thickness are the most susceptible to mechanical instabilities (e.g., lower critical buckling strain, less stress required to reach a critical buckling strain), reducing the chance of mechanical instabilities in the central region 248 comprising the central thickness 217 reduces the incidence of mechanical instabilities for the foldable substrate 201 overall. Further, proving a foldable substrate 201 comprising a recess 219 while the second major surface 205 comprises the second central surface area 213, the central portion 281 (e.g., central region 248) can be especially susceptible to mechanical instabilities since the central thickness 217 is offset from a midline of the substrate thickness 207 (unless the symmetry planes discussed above are provided).

As used herein, if a first layer and/or component is described as “disposed over” a second layer and/or component, other layers may or may not be present between the first layer and/or component and the second layer and/or component. Furthermore, as used herein, “disposed over” does not refer to a relative position with reference to gravity. For example, a first layer and/or component can be considered “disposed over” a second layer and/or component, for example, when the first layer and/or component is positioned underneath, above, or to one side of a second layer and/or component. As used herein, a first layer and/or component described as “bonded to” a second layer and/or component means that the layers and/or components are bonded to each other, either by direct contact and/or bonding between the two layers and/or components or via an adhesive layer. As used herein, a first layer and/or component described as “contacting” or “in contact with” a second layer and/or components refers to direct contact and includes the situations where the layers and/or components are bonded to each other.

As shown in FIGS. 2-3, the foldable apparatus 101 can comprise an adhesive layer 261. As shown, the adhesive layer 261 can comprise a first contact surface 263 and a second contact surface 265 opposite the first contact surface 263. In further aspects, as shown in FIG. 3, the second contact surface 265 of the adhesive layer 261 can comprise a planar surface. In further aspects, as shown in FIGS. 2-3, the first contact surface 263 of the adhesive layer 261 can comprise a planar surface. An adhesive thickness 267 of the adhesive layer 261 can be defined as a minimum distance between the first contact surface 263 and the second contact surface 265. In aspects, the adhesive thickness 267 of the adhesive layer 261 can be about 1 μm or more, about 5 μm or more, about 10 μm or more, about 100 μm or less, about 60 μm or less, about 30 μm or less, or about 20 μm or less. In aspects, the adhesive thickness 267 of the adhesive layer 261 can be in a range from about 1 μm to about 100 μm, from about 5 μm to about 100 μm, from about 5 μm to about 60 μm, from about 5 μm to about 30 μm, from about 10 μm to about 30 μm, from about 10 μm to about 20 μm, or any range or subrange therebetween.

In aspects, as shown in FIG. 2, the first contact surface 263 of the adhesive layer 261 can face and/or contact the second major surface 275 of a release liner 271 (described below). In aspects, as shown in FIG. 3, the first contact surface 263 of the adhesive layer 261 can face and/or contact the second major surface 305 of a display device 307 (described below). In aspects, as shown in FIGS. 2-3, the second contact surface 265 of the adhesive layer 261 can face and/or contact the first major surface 203. In aspects, as shown in FIGS. 2-3, the second contact surface 265 of the adhesive layer 261 can face and/or contact the first surface area 223 of the first portion 221. In aspects, as shown in FIGS. 2-3, the second contact surface 265 of the adhesive layer 261 can face and/or contact the third surface area 233 of the second portion 231. In aspects, as shown in FIGS. 2-3, the second contact surface 265 of the adhesive layer 261 can face the first central surface area 211. In further aspects, as shown in FIG. 2, the second contact surface 265 of the adhesive layer 261 can contact the first central surface area 211.

In aspects, the adhesive layer 261 can comprise one or more of a polyolefin, a polyamide, a halide-containing polymer (e.g., polyvinylchloride or a fluorine-containing polymer), an elastomer, a urethane, phenolic resin, parylene, polyethylene terephthalate (PET), and polyether ether ketone (PEEK). Example aspects of polyolefins include low molecular weight polyethylene (LDPE), high molecular weight polyethylene (HDPE), ultrahigh molecular weight polyethylene (UIMWPE), and polypropylene (PP). Example aspects of fluorine-containing polymers include polytetrafluoroethylene (PTFE), polyvinylfluoride (PVF), polyvinylidene fluoride (PVDF), perfluoropolyether (PFPE), perfluorosulfonic acid (PFSA), a perfluoroalkoxy (PFA), fluorinated ethylene propylene (FEP) polymers, and ethylene tetrafluoro ethylene (ETFE) polymers. Example aspects of elastomers include rubbers (e.g., polybutadiene, polyisoprene, chloroprene rubber, butyl rubber, nitrile rubber) and block copolymers (e.g., styrene-butadiene, high-impact polystyrene, poly(dichlorophosphazene). In further aspects, the adhesive layer 261 can comprise an optically clear adhesive. In even further aspects, the optically clear adhesive can comprise one or more optically transparent polymers: an acrylic (e.g., polymethylmethacrylate (PMMA)), an epoxy, silicone, and/or a polyurethane. Examples of epoxies include bisphenol-based epoxy resins, novolac-based epoxies, cycloaliphatic-based epoxies, and glycidylamine-based epoxies. In even further aspects, the optically clear adhesive can comprise, but is not limited to, acrylic adhesives, for example, 3M 8212 adhesive, or an optically transparent liquid adhesive, for example, a LOCTITE optically transparent liquid adhesive. Exemplary aspects of optically clear adhesives comprise transparent acrylics, epoxies, silicones, and polyurethanes. For example, the optically transparent liquid adhesive could comprise one or more of LOCTITE AD 8650, LOCTITE AA 3922, LOCTITE EA E-05MR, LOCTITE UK U-09LV, which are all available from Henkel.

In aspects, the adhesive layer 261 can comprise an elastic modulus of about 0.001 MegaPascals (MPa) or more, about 0.01 MPa or more, about 0.1 MPa or more, about 1 MPa or less, about 0.5 MPa or less, about 0.1 MPa or less, or about 0.05 MPa or less. In aspects, the adhesive layer 261 can comprise an elastic modulus in a range from about 0.001 MPa to about 1 MPa, from about 0.01 MPa to about 1 MPa, from about 0.01 MPa to about 0.5 MPa, from about 0.05 MPa to about 0.5 MPa, from about 0.1 MPa to about 0.5 MPa, from about 0.001 MPa to about 0.5 MPa, from about 0.001 MPa to about 0.01 MPa, or any range or subrange therebetween. In aspects, the adhesive layer can comprise an elastic modulus within one or more of the ranges discussed below for the elastic modulus of the polymer-based portion 241.

As shown in FIG. 3, the polymer-based portion 241 of the foldable apparatus 101 can be positioned between the first portion 221 and the second portion 231. In aspects, as shown, the polymer-based portion 241 can be at least partially positioned in and/or filling the recess 219, which can be defined between the first plane 204a and the third plane 204c, as discussed above. As shown in FIG. 3, the polymer-based portion 241 can comprise a fourth contact surface 247 opposite a third contact surface 245. In aspects, as shown, the third contact surface 245 can comprise a planar surface, for example, being substantially coplanar (e.g., extend along a common plane, third plane 204c) with the first central surface area 211. In further aspects, as shown, the third contact surface 245 can contact the first central surface area 211. In aspects, as shown in FIG. 3 the fourth contact surface 247 can comprise a planar surface, for example, being substantially coplanar (e.g., extend along a common plane, first plane 204a) with the first surface area 223 and the third surface area 233. In aspects, as shown in FIG. 3, the fourth contact surface 247 can face and/or contact the second contact surface 265 of the adhesive layer 261. In aspects, as shown in FIG. 3, the fourth contact surface 247 can face the second major surface 305 the display device 307. Although not shown, the release liner could be used in place of the display device for the foldable apparatus shown in FIG. 3.

In aspects, the polymer-based portion 241 comprises a polymer (e.g., optically transparent polymer). In further aspects, the polymer-based portion 241 can comprise one or more of an optically transparent: an acrylic (e.g., polymethylmethacrylate (PMMA)), an epoxy, a silicone, and/or a polyurethane. Examples of epoxies include bisphenol-based epoxy resins, novolac-based epoxies, cycloaliphatic-based epoxies, and glycidylamine-based epoxies. In further aspects, the polymer-based portion 241 comprise one or more of a polyolefin, a polyamide, a halide-containing polymer (e.g., polyvinylchloride or a fluorine-containing polymer), an elastomer, a urethane, phenolic resin, parylene, polyethylene terephthalate (PET), and polyether ether ketone (PEEK). Example aspects of polyolefins include low molecular weight polyethylene (LDPE), high molecular weight polyethylene (HDPE), ultrahigh molecular weight polyethylene (UHMWPE), and polypropylene (PP). Example aspects of fluorine-containing polymers include polytetrafluoroethylene (PTFE), polyvinylfluoride (PVF), polyvinylidene fluoride (PVDF), perfluoropolyether (PFPE), perfluorosulfonic acid (PFSA), a perfluoroalkoxy (PFA), fluorinated ethylene propylene (FEP) polymers, and ethylene tetrafluoro ethylene (ETFE) polymers. Example aspects of elastomers include rubbers (e.g., polybutadiene, polyisoprene, chloroprene rubber, butyl rubber, nitrile rubber) and block copolymers (e.g., styrene-butadiene, high-impact polystyrene, poly(dichlorophosphazene), for example, comprising one or more of polystyrene, polydichlorophosphazene, and poly(5-ethylidene-2-norbornene). In aspects, the polymer-based portion can comprise a sol-gel material. Example aspects of polyurethanes comprise thermoset polyurethanes, for example, Dispurez 102 available from Incorez and thermoplastic polyurethanes, for example, KrystalFlex PE505 available from Huntsman. In even further aspects, the second portion can comprise an ethylene acid copolymer. An exemplary aspect of an ethylene acid copolymer includes SURLYN available from Dow (e.g., Surlyn PC-2000, Surlyn 8940, Surlyn 8150). An additional exemplary aspect for the second portion comprises Eleglass w802-GL044 available from Axalta with from 1 wt % to 2 wt % cross-linker. In aspects, the polymer-based portion 241 can further comprise nanoparticles, for example, carbon black, carbon nanotubes, silica nanoparticles, or nanoparticles comprising a polymer. In aspects, the polymer-based portion can further comprise fibers to form a polymer-fiber composite.

In aspects, the polymer-based portion 241 can comprise an elastic modulus of about 0.001 MegaPascals (MPa) or more, about 0.001 MP or more, about 1 MPa or more, about 10 MPa or more, about 20 MPa or more, about 100 MPa or more, about 200 MPa or more, about 1,000 MPa or more, about 5,000 MPa or less, about 3,000 MPa or less, about 1,000 MPa or less, about 500 MPa or less, or about 200 MPa or less. In aspects, the polymer-based portion 241 can comprise an elastic modulus in a range from about 0.001 MPa to about 5,000 MPa, from about 0.01 MPa to about 3,000 MPa, from about 0.01 MPa to about 1,000 MPa, from about 0.01 MPa to about 500 MPa, from about 0.01 MPa to about 200 MPa, from about 1 MPa to about 200 MPa, from about 10 MPa to about 200 MPa, from about 100 MPa to about 200 MPa, or any range or subrange therebetween. In aspects, the polymer-based portion 241 can comprise an elastic modulus in a range from about 1 MPa to about 5,000 MPa, from about 10 MPa to about 5,000 MPa, from about 10 MPa to about 1,000 MPa, from about 20 MPa to about 1,000 MPa, from about 20 MPa to about 200 MPa, or any range or subrange therebetween. In aspects, the elastic modulus of the polymer-based portion 241 can be in a range from about 1 GPa to about 20 GPa, from about 1 GPa to about 18 GPa, from about 1 GPa to about 10 GPa, from about 1 GPa to about 5 GPa, from about 1 GPa to about 3 GPa, or any range or subrange therebetween. By providing a polymer-based portion 241 with an elastic modulus in a range from about 0.001 MPa to about 5,000 MPa (e.g., in a range from about 10 MPa to about 3 GPa), folding of the foldable apparatus without failure can be facilitated. In aspects, the adhesive layer 261 comprises an elastic modulus greater than the elastic modulus of the polymer-based portion 241, which arrangement provides improved performance in puncture resistance. In aspects, the elastic modulus of the polymer-based portion 241 can be less than the elastic modulus of the foldable substrate 201. In aspects, the adhesive layer 261 may comprise an elastic modulus within the ranges listed above in this paragraph. In further aspects, the adhesive layer 261 may comprise substantially the same elastic modulus as the elastic modulus of the polymer-based portion 241. In further aspects, the elastic modulus of the adhesive layer 261 can be in a range from about 1 GPa to about 20 GPa, from about 1 GPa to about 18 GPa, from about 1 GPa to about 10 GPa, from about 1 GPa to about 5 GPa, from about 1 GPa to about 3 GPa, or any range or subrange therebetween. In aspects, the elastic modulus of the polymer-based portion 241 can be less than the elastic modulus of the foldable substrate 201.

In aspects, although not shown, a coating can be disposed over the second major surface 205 of the foldable substrate 201. In further aspects, the coating can be disposed over the first portion 221, the second portion 231, and the central portion 281. In aspects, the coating can contact the foldable substrate 201. In aspects, although not shown, a coating can be disposed over the first major surface 203 of the foldable substrate 201 with one or more of an adhesive layer, polymer-based portion, release liner, or display device facing the second major surface 205 instead of the first major surface 203. In further aspects, at least a part of the coating can be positioned in the recess 219. In even further aspects, the coating can fill the recess 219. In aspects, the coating can comprise a coating thickness defined as a minimum distance in the direction 202 of the substrate thickness 207. In further aspects, the coating thickness can be about 0.1 μm or more, about 1 μm or more, about 5 μm or more, about 10 μm or more, about 15 μm or more, about 20 μm or more, about 25 μm or more, about 40 μm or more, about 50 μm or more, about 60 μm or more, about 70 μm or more, about 80 μm or more, about 90 μm or more, about 200 μm or less, about 100 μm or less, or about 50 μm or less, about 30 μm or less, about 25 μm or less, about 20 μm or less, about 20 μm or less, about 15 μm or less, or about 10 μm or less. In aspects, the coating thickness can be in a range from about 0.1 μm to about 200 μm, from about 1 μm to about 200 μm, from about 10 μm to about 200 μm, from about 50 μm to about 200 μm, from about 0.1 μm to about 100 μm, from about 1 μm to about 100 μm, from about 10 μm to about 100 μm, from about 20 μm to about 100 μm, from about 30 μm to about 100 μm, from about 40 μm to about 100 μm, from about 50 μm to about 100 μm, from about 60 μm to about 100 μm, from about 70 μm to about 100 μm, from about 80 μm to about 100 μm, from about 90 μm to about 100 μm, from about 0.1 μm to about 50 μm, from about 1 μm to about 50 μm, from about 10 μm to about 50 μm, or any range or subrange therebetween. In further aspects, the coating thickness can be in a range from about 0.1 μm to about 50 μm, from about 0.1 μm to about 30 μm, from about 0.1 μm to about 25 μm, from about 0.1 μm to about 20 μm, from about 0.1 μm to about 15 μm, from about 0.1 μm to about 10 μm, from about 1 μm to about 30 μm, from about 1 μm to about 25 μm, from about 1 μm to about 20 μm, from about 1 μm to about 15 μm, from about 1 μm to about 10 μm, from about 5 μm to about 30 μm, from about 5 μm to about 25 μm, from about 5 μm to about 20 μm, from about 5 μm to about 15 μm, from about 5 μm to about 10 μm, from about 10 μm to about 30 μm, from about 10 μm to about 25 μm, from about 10 μm to about 20 μm, from about 10 μm to about 15 μm, from about 15 μm to about 30 μm, from about 15 μm to about 25 μm, from about 15 μm to about 20 μm, from about 20 μm to about 30 μm, from about 20 μm to about 25 μm, or any range or subrange therebetween.

In aspects, the coating can comprise a polymeric hard coating. In further aspects, the polymeric hard coating can comprise one or more of an ethylene-acid copolymer, a polyurethane-based polymer, an acrylate resin, and a mercapto-ester resin. Example aspects of ethylene-acid copolymers include ethylene-acrylic acid copolymers, ethylene-methacrylic acid copolymers, and ethylene-acrylic-methacrylic acid terpolymers (e.g., Nucrel, manufactured by DuPont), ionomers of ethylene acid copolymers (e.g., Surlyn, manufactured by DuPont), and ethylene-acrylic acid copolymer amine dispersions (e.g., Aquacer, manufactured by BYK). Example aspects of polyurethane-based polymers include aqueous modified polyurethane dispersions (e.g., Eleglas®, manufactured by Axalta). Example aspects of acrylate resins that can be UV curable include acrylate resins (e.g., Uvekol® resin, manufactured by Allinex), cyanoacrylate adhesives (e.g., Permabond® UV620, manufactured by Krayden), and UV radical acrylic resins (e.g., Ultrabond windshield repair resin, for example, Ultrabond (45CPS)). Example aspects of mercapto-ester resins include mercapto-ester triallyl isocyanurates (e.g., Norland optical adhesive NOA 61). In further aspects, the polymeric hard coating can comprise ethylene-acrylic acid copolymers and ethylene-methacrylic acid copolymers, which may be ionomerized to form ionomer resins through neutralization of the carboxylic acid residue with typically alkali-metal ions, for example, sodium and potassium, and also zinc. Such ethylene-acrylic acid and ethylene-methacrylic acid ionomers may be dispersed in water and coated onto the substrate to form an ionomer coating. Alternatively, such acid copolymers may be neutralized with ammonia which, after coating and drying liberates the ammonia to reform the acid copolymer as the coating. By providing a coating comprising a polymeric coating, the foldable apparatus can comprise low energy fracture.

In aspects, the coating can comprise a polymeric hard coating comprising an optically transparent polymeric hard-coat layer. Suitable materials for an optically transparent polymeric hard-coat layer include but are not limited to a cured acrylate resin material, an inorganic-organic hybrid polymeric material, an aliphatic or aromatic hexafunctional urethane acrylate, a siloxane-based hybrid material, and a nanocomposite material, for example, an epoxy and urethane material with nanosilicate. In aspects, an optically transparent polymeric hard-coat layer may consist essentially of one or more of these materials. In aspects, an optically transparent polymeric hard-coat layer may consist of one or more of these materials. As used herein, “inorganic-organic hybrid polymeric material” means a polymeric material comprising monomers with inorganic and organic components. An inorganic-organic hybrid polymer is obtained by a polymerization reaction between monomers having an inorganic group and an organic group. An inorganic-organic hybrid polymer is not a nanocomposite material comprising separate inorganic and organic constituents or phases, for example, inorganic particulates dispersed within an organic matrix. More specifically, suitable materials for an optically transparent polymeric (OTP) hard-coat layer include, but are not limited to, a polyimide, a polyethylene terephthalate (PET), a polycarbonate (PC), a poly methyl methacrylate (PMMA), organic polymer materials, inorganic-organic hybrid polymeric materials, and aliphatic or aromatic hexafunctional urethane acrylates. In aspects, an OTP hard-coat layer may consist essentially of an organic polymer material, an inorganic-organic hybrid polymeric material, or aliphatic or aromatic hexafunctional urethane acrylate. In aspects, an OTP hard-coat layer may consist of a polyimide, an organic polymer material, an inorganic-organic hybrid polymeric material, or aliphatic or aromatic hexafunctional urethane acrylate. In aspects, an OTP hard-coat layer may include a nanocomposite material. In aspects, an OTP hard-coat layer may include a nano-silicate at least one of epoxy and urethane materials. Suitable compositions for such an OTP hard-coat layer are described in U.S. Pat. Pub. No. 2015/0110990, which is hereby incorporated by reference in its entirety by reference thereto. As used herein, “organic polymer material” means a polymeric material comprising monomers with only organic components. In aspects, an OTP hard-coat layer may comprise an organic polymer material manufactured by Gunze Limited and having a hardness of 9H, for example Gunze's “Highly Durable Transparent Film.” As used herein, “inorganic-organic hybrid polymeric material” means a polymeric material comprising monomers with inorganic and organic components. An inorganic-organic hybrid polymer is obtained by a polymerization reaction between monomers having an inorganic group and an organic group. An inorganic-organic hybrid polymer is not a nanocomposite material comprising separate inorganic and organic constituents or phases, for example, inorganic particulates dispersed within an organic matrix. In aspects, the inorganic-organic hybrid polymeric material may include polymerized monomers comprising an inorganic silicon-based group, for example, a silsesquioxane polymer. A silsesquioxane polymer may be, for example, an alkyl-silsesquioxane, an aryl-silsesquioxane, or an aryl alkyl-silsesquioxane having the following chemical structure: (RSiO_{1.5})ₙ, where R is an organic group for example, but not limited to, methyl or phenyl. In aspects, an OTP hard-coat layer may comprise a silsesquioxane polymer combined with an organic matrix, for example, SILPLUS manufactured by Nippon Steel Chemical Co., Ltd. In aspects, an OTP hard-coat layer may comprise 90 wt % to 95 wt % aromatic hexafunctional urethane acrylate (e.g., PU662NT (Aromatic hexafunctional urethane acrylate) manufactured by Miwon Specialty Chemical Co.) and 10 wt % to 5 wt % photo-initiator (e.g., Darocur 1173 manufactured by Ciba Specialty Chemicals Corporation) with a hardness of 8H or more. In aspects, an OTP hard-coat layer composed of an aliphatic or aromatic hexafunctional urethane acrylate may be formed as a stand-alone layer by spin-coating the layer on a polyethylene terephthalate (PET) substrate, curing the urethane acrylate, and removing the urethane acrylate layer from the PET substrate. In aspects, an OTP coating layer may be an aliphatic or aromatic hexafunctional urethane acrylate material layer having a thickness within one or more of the thickness ranges discussed above for the coating thickness.

In aspects, the coating, if provided, may also comprise one or more of an easy-to-clean coating, a low-friction coating, an oleophobic coating, a diamond-like coating, a scratch-resistant coating, or an abrasion-resistant coating. A scratch-resistant coating may comprise an oxynitride, for example, aluminum oxynitride or silicon oxynitride with a thickness of about 500 micrometers or more. In such aspects, the abrasion-resistant layer may comprise the same material as the scratch-resistant layer. In aspects, a low friction coating may comprise a highly fluorinated silane coupling agent, for example, an alkyl fluorosilane with oxymethyl groups pendant on the silicon atom. In such aspects, an easy-to-clean coating may comprise the same material as the low friction coating. In other aspects, the easy-to-clean coating may comprise a protonatable group, for example an amine, for example, an alkyl aminosilane with oxymethyl groups pendant on the silicon atom. In such aspects, the oleophobic coating may comprise the same material as the easy-to-clean coating. In aspects, a diamond-like coating comprises carbon and may be created by applying a high voltage potential in the presence of a hydrocarbon plasma.

Additionally, controlling properties of a first material (e.g., coating, polymer-based portion 241) positioned in a first recess can control the position of a neutral axis of the foldable apparatus and/or foldable substrates, which can reduce (e.g., mitigate, eliminate) the incidence of mechanical instabilities, apparatus fatigue, and/or apparatus failure. In aspects, a strain at yield of the polymer-based portion and/or adhesive layer can be about 5% or more, about 6% or more, about 7% or more, about 8% or more, about 9% or more, about 500% or less, about 100% or less, about 50% or less, about 20% or less, about 15% or less, about 12% or less, or about 10% or less. In aspects, the strain at yield of the polymer-based portion and/or adhesive layer can be in a range from about 5% to about 500%, from about 5% to about 100%, from about 6% to about 100%, from about 6% to about 50%, from about 7% to about 50%, from about 7% to about 20%, from about 8% to about 20%, from about 8% to about 15%, from about 9% to about 15%, from about 9% to about 10%, from about 5% to about 15%, from about 5% to about 10%, or any range or subrange therebetween.

In aspects, as shown in FIG. 2, the foldable apparatus 101 can comprise the release liner 271 although other substrates (e.g., glass-based substrate and/or ceramic-based substrate discussed throughout the application) may be used in further aspects rather than the illustrated release liner 271. In further aspects, as shown, the release liner 271, or another substrate, can be disposed over the adhesive layer 261. In even further aspects, as shown, the release liner 271, or another substrate, can directly contact the first contact surface 263 of the adhesive layer 261. The release liner 271, or another substrate, can comprise a first major surface 273 and a second major surface 275 opposite the first major surface 273. As shown, the release liner 271, or another substrate, can be disposed on the adhesive layer 261 by attaching the first contact surface 263 of the adhesive layer 261 to the second major surface 275 of the release liner 271, or another substrate. In aspects, as shown, the second major surface 275 of the release liner 271, or another substrate, can comprise a planar surface. In aspects, as shown, the first major surface 273 of the release liner 271, or another substrate, can comprise a planar surface. A substrate comprising the release liner 271 can comprise a paper and/or a polymer. Exemplary aspects of paper comprise kraft paper, machine-finished paper, poly-coated paper (e.g., polymer-coated, glassine paper, siliconized paper), or clay-coated paper. Exemplary aspects of polymers comprise polyesters (e.g., polyethylene terephthalate (PET)) and polyolefins (e.g., low-density polyethylene (LDPE), high-density polyethylene (HDPE), polypropylene (PP)).

In aspects, as shown in FIG. 3, the foldable apparatus 301 can comprise the display device 307. In further aspects, as shown, the display device 307 can be disposed over the adhesive layer 261. In further aspects, as shown, the display device 307 can contact the first contact surface 263 of the adhesive layer 261. In aspects, producing the foldable apparatus 301 may be achieved by removing the release liner 271 of the foldable apparatus 101 of FIG. 2 and attaching the display device 307 to the first contact surface 263 of the adhesive layer 261. Alternatively, the foldable apparatus 301 may be produced without the extra step of removing a release liner 271 before attaching the display device 307 to the first contact surface 263 of the adhesive layer 261, for example, when a release liner 271 is not applied to the first contact surface 263 of the adhesive layer 261. The display device 307 can comprise a first major surface 303 and a second major surface 305 opposite the first major surface 303. As shown, the display device 307 can be disposed on the adhesive layer 261 by attaching the first contact surface 263 of the adhesive layer 261 to the second major surface 305 of the display device 307. In aspects, as shown, the first major surface 303 of the display device 307 can comprise a planar surface. In aspects, as shown, the second major surface 305 of the display device 307 can comprise a planar surface. The display device 307 can comprise a liquid crystal display (LCD), an electrophoretic display (EPD), an organic light-emitting diode (OLED) display, or a plasma display panel (PDP). In aspects, the display device 307 can be part of a portable electronic device, for example, a consumer electronic product, a smartphone, a tablet, a wearable device, or a laptop.

Aspects of the disclosure can comprise a consumer electronic product. The consumer electronic product can comprise a front surface, a back surface, and side surfaces. The consumer electronic product can further comprise electrical components at least partially within the housing. The electrical components can comprise a controller, a memory, and a display. The display can be at or adjacent to the front surface of the housing. The display can comprise a liquid crystal display (LCD), an electrophoretic display (EPD), an organic light-emitting diode (OLED) display, or a plasma display panel (PDP). The consumer electronic product can comprise a cover substrate disposed over the display. In aspects, at least one of a portion of the housing or the cover substrate comprises the foldable apparatus discussed throughout the disclosure. The consumer electronic product can comprise a portable electronic device, for example, a smartphone, a tablet, a wearable device, or a laptop.

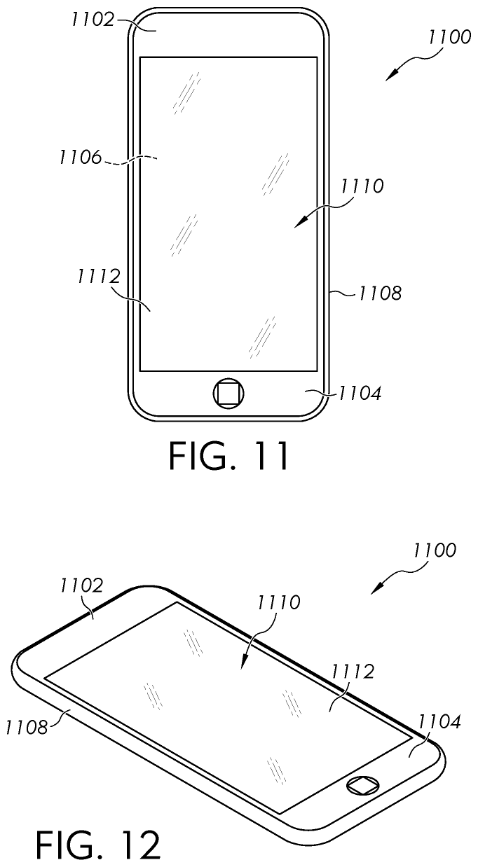

The foldable apparatus disclosed herein may be incorporated into another article, for example, an article with a display (or display articles) (e.g., consumer electronics, including mobile phones, tablets, computers, navigation systems, wearable devices (e.g., watches), and the like), architectural articles, transportation articles (e.g., automotive, trains, aircraft, sea craft, etc.), appliance articles, or any article that may benefit from some transparency, scratch-resistance, abrasion resistance or a combination thereof. An exemplary article incorporating any of the foldable apparatus disclosed herein is shown in FIGS. 11-12. Specifically, FIGS. 11-12 show a consumer electronic device 1100 including a housing 1102 having front 1104, back 1106, and side surfaces 1108. Although not shown, the consumer electronic device can comprise electrical components that are at least partially inside or entirely within the housing. For example, electrical components include at least a controller, a memory, and a display. As shown in FIGS. 11-12, the display 1110 can be at or adjacent to the front surface of the housing 1102. The consumer electronic device can comprise a cover substrate 1112 at or over the front surface of the housing 1102 such that it is over the display 1110. In aspects, at least one of the cover substrate 1112 or a portion of housing 1102 may include any of the foldable apparatus disclosed herein, for example, the foldable substrate.

In aspects, the foldable substrate 201 can comprise a glass-based substrate and/or a ceramic-based substrate, and the first portion 221, the second portion 231, and/or the central portion 281 can comprise one or more compressive stress regions. In aspects, a compressive stress region may be created by chemically strengthening. Chemically strengthening may comprise an ion exchange process, where ions in a surface layer are replaced by—or exchanged with—larger ions having the same valence or oxidation state. Methods of chemically strengthening will be discussed later. Without wishing to be bound by theory, chemically strengthening the first portion 221, the second portion 231, and/or the central portion 281 can enable good impact and/or puncture resistance (e.g., resists failure for a pen drop height of about 15 centimeters (cm) or more, about 20 cm or more, about 50 cm or more). Without wishing to be bound by theory, chemically strengthening the first portion 221, the second portion 231, and/or the central portion 281 can enable small (e.g., smaller than about 10 mm or less) bend radii because the compressive stress from the chemical strengthening can counteract the bend-induced tensile stress on the outermost surface of the substrate. A compressive stress region may extend into a portion of the first portion and/or the second portion for a depth called the depth of compression. As used herein, depth of compression means the depth at which the stress in the chemically strengthened substrates and/or portions described herein changes from compressive stress to tensile stress. Depth of compression may be measured by a surface stress meter or a scattered light polariscope (SCALP, wherein values reported herein were made using SCALP-5 made by Glasstress Co., Estonia) depending on the ion exchange treatment and the thickness of the article being measured. Where the stress in the substrate and/or portion is generated by exchanging potassium ions into the substrate, a surface stress meter, for example, the FSM-6000 (Orihara Industrial Co., Ltd. (Japan)), is used to measure depth of compression. Unless specified otherwise, compressive stress (including surface CS) is measured by surface stress meter (FSM) using commercially available instruments, for example the FSM-6000, manufactured by Orihara. Surface stress measurements rely upon the accurate measurement of the stress optical coefficient (SOC), which is related to the birefringence of the glass. Unless specified otherwise, SOC is measured according to Procedure C (Glass Disc Method) described in ASTM standard C770-16, entitled “Standard Test Method for Measurement of Glass Stress-Optical Coefficient,” the contents of which are incorporated herein by reference in their entirety. Where the stress is generated by exchanging sodium ions into the substrate, and the article being measured is thicker than about 400 μm, SCALP is used to measure the depth of compression and central tension (CT). Where the stress in the substrate and/or portion is generated by exchanging both potassium and sodium ions into the substrate and/or portion, and the article being measured is thicker than about 400 μm, the depth of compression and CT are measured by SCALP. Without wishing to be bound by theory, the exchange depth of sodium may indicate the depth of compression while the exchange depth of potassium ions may indicate a change in the magnitude of the compressive stress (but not the change in stress from compressive to tensile). The refracted near-field (RNF; the RNF method is described in U.S. Pat. No. 8,854,623, entitled “Systems and methods for measuring a profile characteristic of a glass sample”, which is incorporated herein by reference in its entirety) method also may be used to derive a graphical representation of the stress profile. When the RNF method is utilized to derive a graphical representation of the stress profile, the maximum central tension value provided by SCALP is utilized in the RNF method. The graphical representation of the stress profile derived by RNF is force balanced and calibrated to the maximum central tension value provided by a SCALP measurement. As used herein, “depth of layer” (DOL) means the depth that the ions have exchanged into the substrate and/or portion (e.g., sodium, potassium). Through the disclosure, when the maximum central tension cannot be measured directly by SCALP (as when the article being measured is thinner than about 400 μm) the maximum central tension can be approximated by a product of a maximum compressive stress and a depth of compression divided by the difference between the thickness of the substrate and twice the depth of compression, wherein the compressive stress and depth of compression are measured by FSM.

In aspects, the first portion 221 comprising the glass-based portion and/or ceramic-based portion may comprise a first compressive stress region at the first surface area 223 that can extend to a first depth of compression from the first surface area 223. In aspects, the first portion 221 comprising a first glass-based and/or ceramic-based portion may comprise a second compressive stress region at the second surface area 225 that can extend to a second depth of compression from the second surface area 225. In aspects, the first depth of compression and/or the second depth of compression as a percentage of the substrate thickness 207 can be about 1% or more, about 5% or more, about 10% or more, about 30% or less, about 25% or less, or about 20% or less. In aspects, the first depth of compression and/or the second depth of compression as a percentage of the substrate thickness 207 can be in a range from about 1% to about 30%, from about 5% to about 30%, from about 5% to about 25%, from about 5% to about 20%, from about 10% to about 30%, from about 10% to about 25%, from about 10% to about 20%, or any range or subrange therebetween. In further aspects, the first depth of compression and/or the second depth of compression as a percentage of the substrate thickness 207 can be about 10% or less, for example, from about 1% to about 10%, from about 1% to about 8%, from about 3% to about 8%, from about 5% to about 8%, or any range or subrange therebetween. In further aspects, the first depth of compression can be substantially equal to the second depth of compression. In aspects, the first depth of compression and/or the second depth of compression can be about 1 μm or more, about 10 μm or more, about 30 μm or more, about 50 μm or more, about 200 μm or less, about 150 μm or less, about 100 μm or less, or about 60 μm or less. In aspects, the first depth of compression and/or the second depth of compression can be in a range from about 1 μm to about 200 μm, from about 1 μm to about 150 μm, from about 10 μm to about 150 μm, from about 10 μm to about 100 μm, from about 30 μm to about 100 μm, from about 30 μm to about 60 μm, from about 50 μm to about 60 μm, or any range or subrange therebetween. By providing a first portion comprising a first glass-based and/or ceramic-based portion comprising a first depth of compression and/or a second depth of compression in a range from about 1% to about 30% of the first thickness, good impact and/or puncture resistance can be enabled.

In aspects, the first compressive stress region can comprise a maximum first compressive stress. In aspects, the second compressive stress region can comprise a maximum second compressive stress. In further aspects, the maximum first compressive stress and/or the maximum second compressive stress can be about 100 MegaPascals (MPa) or more, about 300 MPa or more, about 500 MPa or more, about 600 MPa or more, about 700 MPa or more, about 1,500 MPa or less, about 1,200 MPa or less, about 1,000 MPa or less, or about 800 MPa or less. In further aspects, the maximum first compressive stress and/or the maximum second compressive stress can be in a range from about 100 MPa to about 1,500 MPa, from about 100 MPa to about 1,200 MPa, from about 300 MPa to about 1,200 MPa, from about 300 MPa to about 1,000 MPa, from about 500 MPa to about 1,000 MPa, from about 600 MPa to about 1,000 MPa, from about 600 MPa to about 1,000 MPa, from about 700 MPa to about 1,000 MPa, from about 700 MPa to about 800 MPa, from about 500 MPa to about 800 MPa, or any range or subrange therebetween. By providing a maximum first compressive stress and/or a maximum second compressive stress in a range from about 100 MPa to about 1,500 MPa, good impact and/or puncture resistance can be enabled.

In aspects, the first portion 221 can comprise a first depth of layer of one or more alkali-metal ions associated with the first compressive stress region. In aspects, the first portion 221 can comprise a second depth of layer of one or more alkali-metal ions associated with the second compressive stress region and the second depth of compression. As used herein, the one or more alkali-metal ions of a depth of layer of one or more alkali-metal ions can include sodium, potassium, rubidium, cesium, and/or francium. In aspects, the one or more alkali ions of the first depth of layer of the one or more alkali ions and/or the second depth of layer of the one or more alkali ions comprises potassium. In aspects, the first depth of layer and/or the second depth of layer as a percentage of the substrate thickness 207 can be about 1% or more, about 5% or more, about 10% or more, about 40% or less, about 35% or less, about 30% or less, about 25% or less, or about 20% or less. In aspects, the first depth of layer and/or the second depth of layer as a percentage of the substrate thickness 207 can be in a range from about 1% to about 40%, from about 1% to about 35%, from about 1% to about 30%, from about 1% to about 25%, from about 1% to about 20%, from about 5% to about 30%, from about 5% to about 25%, from about 5% to about 20%, from about 10% to about 30%, from about 10% to about 25%, from about 10% to about 20%, or any range or subrange therebetween. In further aspects, the first depth of layer of the one or more alkali-metal ions and/or the second depth of layer of the one or more alkali-metal ions as a percentage of the substrate thickness 207 can be about 10% or less, for example, from about 1% to about 10%, from about 1% to about 8%, from about 3% to about 8%, from about 5% to about 8%, or any range or subrange therebetween. In aspects, the first depth of layer of the one or more alkali-metal ions and/or the second depth of layer of the one or more alkali-metal ions can be about 1 μm or more, about 10 μm or more, about 30 μm or more, about 50 μm or more, about 200 μm or less, about 150 μm or less, about 100 μm or less, or about 60 μm or less. In aspects, the first depth of layer of the one or more alkali-metal ions and/or the second depth of layer of the one or more alkali-metal ions can be in a range from about 1 μm to about 200 μm, from about 1 μm to about 150 μm, from about 10 μm to about 150 μm, from about 10 μm to about 100 μm, from about 30 μm to about 100 μm, from about 30 μm to about 60 μm, from about 50 μm to about 60 μm, or any range or subrange therebetween.

In aspects, the first portion 221 may comprise a first tensile stress region. In aspects, the first tensile stress region can be positioned between the first compressive stress region and the second compressive stress region. In aspects, the first tensile stress region can comprise a maximum first tensile stress. In further aspects, the maximum first tensile stress can be about 10 MPa or more, about 20 MPa or more, about 30 MPa or more, about 100 MPa or less, about 80 MPa or less, or about 60 MPa or less. In further aspects, the maximum first tensile stress can be in a range from about 10 MPa to about 100 MPa, from about 10 MPa to about 80 MPa, from about 10 MPa to about 60 MPa, from about 20 MPa to about 100 MPa, from about 20 MPa to about 80 MPa, from about 20 MPa to about 60 MPa, from about 30 MPa to about 100 MPa, from about 30 MPa to about 80 MPa, from about 30 MPa to about 60 MPa, or any range or subrange therebetween. Providing a maximum first tensile stress in a range from about 10 MPa to about 100 MPa can enable good impact and/or puncture resistance while providing low energy fractures, as discussed below.

In aspects, the second portion 231 comprising a second glass-based and/or ceramic-based portion may comprise a third compressive stress region at the third surface area 233 that can extend to a third depth of compression from the third surface area 233. In aspects, the second portion 231 comprising a second glass-based and/or ceramic-based portion may comprise a fourth compressive stress region at the fourth surface area 235 that can extend to a fourth depth of compression from the fourth surface area 235. In aspects, the third depth of compression and/or the fourth depth of compression as a percentage of the substrate thickness 207 can be about 1% or more, about 5% or more, about 10% or more, about 30% or less, about 25% or less, or about 20% or less. In aspects, the third depth of compression and/or the fourth depth of compression as a percentage of the substrate thickness 207 can be within one or more of the ranges discussed above for the first depth of compression and/or the second depth of compression as a percentage of the substrate thickness 207. In further aspects, the third depth of compression can be substantially equal to the fourth depth of compression. In aspects, the third depth of compression and/or the fourth depth of compression can be within one or more of the ranges discussed above for the first depth of compression and/or the second depth of compression. By providing a second portion comprising a glass-based and/or ceramic-based portion comprising a third depth of compression and/or a fourth depth of compression in a range from about 1% to about 30% of the substrate thickness, good impact and/or puncture resistance can be enabled.

In aspects, the third compressive stress region can comprise a maximum third compressive stress. In aspects, the fourth compressive stress region can comprise a maximum fourth compressive stress. In further aspects, the maximum third compressive stress and/or the maximum fourth compressive stress can be within one or more of the ranges discussed above for the maximum first compressive stress and/or the maximum second compressive stress. By providing a maximum third compressive stress and/or a maximum fourth compressive stress in a range from about 100 MPa to about 1,500 MPa, good impact and/or puncture resistance can be enabled.

In aspects, the second portion 231 can comprise a third depth of layer of one or more alkali-metal ions associated with the third compressive stress region and the third depth of compression. In aspects, the second portion 231 can comprise a fourth depth of layer of one or more alkali-metal ions associated with the fourth compressive stress region and the fourth depth of compression. In aspects, the one or more alkali ions of the third depth of layer of the one or more alkali ions and/or the fourth depth of layer of the one or more alkali ions comprises potassium. In aspects, the third depth of layer and/or the fourth depth of layer as a percentage of the substrate thickness 207 can be within one or more of the ranges discussed above for the first depth of layer and/or the second depth of layer as a percentage of the substrate thickness 207. In aspects, the third depth of layer of the one or more alkali-metal ions and/or the fourth depth of layer of the one or more alkali-metal ions can be equal to the first depth of layer and/or the second depth of layer.

In aspects, the second portion 231 may comprise a second tensile stress region. In aspects, the second tensile stress region can be positioned between the third compressive stress region and the fourth compressive stress region. In aspects, the second tensile stress region can comprise a maximum second tensile stress. In further aspects, the maximum second tensile stress can be within one or more of the ranges discussed above for the maximum first tensile stress. In aspects, the maximum first tensile stress can be substantially equal to the maximum second tensile stress. Providing a maximum second tensile stress in a range from about 10 MPa to about 100 MPa can enable good impact and/or puncture resistance while providing low energy fractures, as discussed below.

In aspects, the first depth of compression can be substantially equal to the third depth of compression. In aspects, the second depth of compression can be substantially equal to the fourth depth of compression. In aspects, the maximum first compressive stress can be substantially equal to the maximum third compressive stress. In aspects, the maximum second compressive stress can be substantially equal to the maximum fourth compressive stress. In aspects, the first depth of layer of one or more alkali-metal ions can be substantially equal to the third depth of layer of one or more alkali-metal ions. In aspects, the second depth of layer of one or more alkali-metal ions can be substantially equal to the fourth depth of layer of one or more alkali-metal ions.

In aspects, the central portion (e.g., the central region) can be substantially unstrengthened (e.g., unstressed, not chemically strengthened, not thermally strengthened) with substantially no tensile stress region or a small magnitude maximum tensile stress. As used herein, substantially unstrengthened refers to a substrate comprising either no depth of layer or a depth of layer in a range from 0% to about 5% of the substrate thickness. In further aspects, the central region can be substantially unstrengthened while the first transition portion and/or the second transition portion can be chemically strengthened.

In aspects, the central portion 281 (e.g., central region 248) can comprise a first central compressive stress region at the first central surface area 211 that can extend to a first central depth of compression from the first central surface area 211. In aspects, the central portion 281 (e.g., central region 248) can comprise a second central compressive stress region at the second central surface area 213 that can extend to a second central depth of compression from the second central surface area 213. In further aspects, the first central compressive stress region and/or the second compressive stress region can be within the central region 248 of the central portion 281 (e.g., coextensive with the first central surface area 211 and/or the second central surface area 213). In further aspects, the first central depth of compression and/or the second central depth of compression as a percentage of the central thickness 217 can be within one or more of the ranges discussed above for the first depth of compression and/or the second depth of compression as a percentage of the substrate thickness 207. In further aspects, the first central depth of compression and/or the second central depth of compression as a percentage of the central thickness 217 can be about 10% or more, for example, from about 10% to about 30%, from about 10% to about 25%, from about 15% to about 25%, from about 15% to about 20%, or any range or subrange therebetween. In further aspects, the first central depth of compression can be substantially equal to the second central depth of compression. In aspects, the first central depth of compression and/or the second central depth of compression can be within one or more of the ranges discussed above for the first depth of compression and/or the second depth of compression. By providing a central portion comprising a glass-based and/or ceramic-based portion comprising a first central depth of compression and/or a second central depth of compression in a range from about 1% to about 30% of the central thickness, good impact and/or puncture resistance can be enabled.

In aspects, the first central compressive stress region can comprise a maximum first central compressive stress. In aspects, the second central compressive stress region can comprise a maximum second central compressive stress. In further aspects, the maximum first central compressive stress and/or the maximum second central compressive stress can be within one or more of the ranges discussed above for the maximum first compressive stress and/or the maximum second compressive stress. By providing a maximum first central compressive stress and/or a maximum second central compressive stress of about 500 MPa or more or in a range from about 100 MPa to about 1,500 MPa, good impact and/or puncture resistance can be enabled.

In aspects, the central portion 281 can comprise a first central depth of layer of one or more alkali-metal ions associated with the first central compressive stress region and the first central depth of compression. In aspects, the central portion 281 can comprise a second central depth of layer of one or more alkali-metal ions associated with the second central compressive stress region and the second central depth of compression. In aspects, the one or more alkali ions of the first central depth of layer of the one or more alkali ions and/or the second central depth of layer of the one or more alkali ions comprises potassium. In aspects, the first central depth of layer and/or the second central depth of layer as a percentage of the central thickness 217 can be within one or more of the ranges discussed above for the first depth of layer and/or the second depth of layer as a percentage of the substrate thickness 207. In aspects, the first central depth of layer of the one or more alkali-metal ions and/or the second central depth of layer of the one or more alkali-metal ions can be within one or more of the ranges discussed above for the first depth of layer and/or the second depth of layer. In aspects, the first depth of compression and/or the third depth of compression can be greater than the first central depth of compression. In aspects, the second depth of compression and/or the fourth depth of compression can be greater than the second central depth of compression. In aspects, the first depth of layer and/or the third depth of layer can be greater than the first central depth of layer. In aspects, the second depth of layer and/or the fourth depth of layer can be greater than the second central depth of layer.

In aspects, the central portion 281 may comprise a central tensile stress region. In aspects, the central tensile stress region can be positioned between the first central compressive stress region and the second central compressive stress region. In aspects, the central tensile stress region can comprise a maximum central tensile stress. In further aspects, the maximum central tensile stress can be about 125 MPa or more, about 150 MPa or more, about 200 MPa or more, about 375 MPa or less, about 300 MPa or less, or about 250 MPa or less. In further aspects, the maximum central tensile stress can be in a range from about 125 MPa to about 375 MPa, from about 125 MPa to about 300 MPa, from about 125 MPa to about 250 MPa, from about 150 MPa to about 375 MPa, from about 150 MPa to about 300 MPa, from about 150 MPa to about 250 MPa, from about 200 MPa to about 375 MPa, from about 200 MPa to about 300 MPa, from about 200 MPa to about 250 MPa, or any range or subrange therebetween. Providing a maximum central tensile stress in a range from about 125 MPa to about 375 MPa can enable low minimum bend radii.

In aspects, the first transition region 212 can comprise a first transition compressive stress region at the first transition surface area 283 that can extend to a first transition depth of compression from the first transition surface area 283. In aspects, the second transition region 218 can comprise a second transition compressive stress region at the second transition surface area 285 that can extend to a second transition depth of compression from the second transition surface area 285. In further aspects, the first transition depth of compression can be substantially equal to the second transition depth of compression. In aspects, the first transition depth of compression and/or the second transition depth of compression can be within one or more of the ranges discussed above for the first depth of compression and/or the second depth of compression. In aspects, the first transition compressive stress region can comprise a maximum first transition compressive stress. In aspects, the second transition compressive stress region can comprise a maximum second transition compressive stress. In further aspects, the maximum first transition compressive stress and/or the maximum second transition compressive stress can be within one or more of the ranges discussed above for the maximum first compressive stress and/or the maximum second compressive stress.

In aspects, the first transition region 212 can comprise a first transition depth of layer of one or more alkali-metal ions associated with the first transition compressive stress region and the first depth of compression. In aspects, the second transition region 218 can comprise a second transition depth of layer of one or more alkali-metal ions associated with the second transition compressive stress region and the second depth of compression. In aspects, the one or more alkali ions of the first transition depth of layer of the one or more alkali ions and/or the second transition depth of layer of the one or more alkali ions comprises potassium. In aspects, the first transition depth of layer of the one or more alkali-metal ions and/or the second transition depth of layer of the one or more alkali-metal ions can be within one or more of the ranges discussed above for the first depth of layer and/or the second depth of layer. In aspects, the first transition region 212 may comprise a first transition tensile stress region. In aspects, the second transition region 218 may comprise a second transition tensile stress region. In aspects, the first transition tensile stress region can comprise a maximum first transition tensile stress. In aspects, the second transition tensile stress region can comprise a maximum second transition tensile stress. In further aspects, the maximum first transition tensile stress and/or the maximum second transition tensile stress can be within one or more of the ranges discussed above for the maximum central tensile stress.

In aspects, the maximum first transition tensile stress can be greater than or equal to the maximum central tensile stress. In further aspects, the maximum first transition tensile stress can be less than or equal to the maximum first tensile stress of the first tensile stress region. In further aspects, the maximum first tensile stress of the first tensile stress region can be greater than or equal to the maximum central tensile stress. In aspects, the maximum second transition tensile stress can be greater than or equal to the maximum central tensile stress. In further aspects, the maximum second transition tensile stress can be less than or equal to the maximum second tensile stress of the second tensile stress region. In further aspects, the maximum second tensile stress of the second tensile stress region can be greater than or equal to the maximum central tensile stress. Providing a maximum first transition tensile stress and/or a maximum second transition tensile stress greater than or equal to a maximum central tensile stress can reduce the incidence of mechanical instabilities (e.g., of the central portion).

In aspects, the first depth of compression as a percentage of the substrate thickness can be greater than or equal to the first central depth of compression as a percentage of the central thickness. In even further aspects, the third depth of compression as a percentage of the substrate thickness can be greater than or equal to the first central depth of compression as a percentage of the central thickness. In aspects, the second depth of compression as a percentage of the substrate thickness can be greater than or equal to the second central depth of compression as a percentage of the central thickness. In further aspects, the fourth depth of compression as a percentage of the substrate thickness can be greater than or equal to the second central depth of compression as a percentage of the central thickness.

In aspects, the first depth of layer as a percentage of the substrate thickness can be greater than or equal to the first central depth of layer as a percentage of the central thickness. In even further aspects, the third depth of layer as a percentage of the substrate thickness can be greater than or equal to the first central depth of layer as a percentage of the central thickness. In aspects, the second depth of layer as a percentage of the substrate thickness can be greater than or equal to the second central depth of layer as a percentage of the central thickness. In further aspects, the fourth depth of layer as a percentage of the substrate thickness can be greater than or equal to the second central depth of layer as a percentage of the central thickness.

In aspects, the polymer-based portion 241 can be optically clear. The polymer-based portion 241 can comprise a first index of refraction. The first refractive index may be a function of a wavelength of light passing through the optically clear adhesive. For light of a first wavelength, a refractive index of a material is defined as the ratio between the speed of light in a vacuum and the speed of light in the corresponding material. Without wishing to be bound by theory, a refractive index of the optically clear adhesive can be determined using a ratio of a sine of a first angle to a sine of a second angle, where light of the first wavelength is incident from air on a surface of the optically clear adhesive at the first angle and refracts at the surface of the optically clear adhesive to propagate light within the optically clear adhesive at a second angle. The first angle and the second angle are both measured relative to a direction normal to a surface of the optically clear adhesive. As used herein, the refractive index is measured in accordance with ASTM E1967-19, where the first wavelength comprises 589 nm. In aspects, the first refractive index of the polymer-based portion 241 may be about 1 or more, about 1.3 or more, about 1.4 or more, about 1.45 or more, about 1.49 or more, about 3 or less, about 2 or less, or about 1.7 or less, about 1.6 or less, or about 1.55 or less. In aspects, the first refractive index of the polymer-based portion 241 can be in a range from about 1 to about 3, from about 1 to about 2 from about 1 to about 1.7, from about 1.3 to about 1.7, from about 1.4 to about 1.7, from about 1.4 to about 1.6, from about 1.45 to about 1.55, from about 1.49 to about 1.55, or any range or subrange therebetween.

In aspects, the foldable substrate 201 can comprise a second index of refraction. In aspects, the second refractive index of the foldable substrate 201 may be about 1 or more, about 1.3 or more, about 1.4 or more, about 1.45 or more, about 1.49 or more, about 3 or less, about 2 or less, or about 1.7 or less, about 1.6 or less, or about 1.55 or less. In aspects, the second refractive index of the foldable substrate 201 can be in a range from about 1 to about 3, from about 1 to about 2 from about 1 to about 1.7, from about 1.3 to about 1.7, from about 1.4 to about 1.7, from about 1.4 to about 1.6, from about 1.45 to about 1.55, from about 1.49 to about 1.55, or any range or subrange therebetween. In aspects, a differential equal to the absolute value of the difference between the second index of refraction of the foldable substrate 201 and the first index of refraction of the polymer-based portion 241 can be about 0.1 or less, about 0.07 or less, about 0.05 or less, about 0.001 or more, about 0.01 or more, or about 0.02 or more. In aspects, the differential is in a range from about 0.001 to about 0.1, from about 0.001 to about 0.07, from about 0.001 to about 0.05, from about 0.01 to about 0.1, from about 0.01 to about 0.07, from about 0.01 to about 0.05, from about 0.02 to about 0.1, from about 0.02 to about 0.07, from about 0.02 to about 0.05, or any range or subrange therebetween. In aspects, the second index of refraction of the foldable substrate 201 may be greater than the first index of refraction of the polymer-based portion 241. In aspects, the second index of refraction of the foldable substrate 201 may be less than the first index of refraction of the polymer-based portion 241.

In aspects, the adhesive layer 261 can comprise a third index of refraction. In aspects, the third index of refraction of the adhesive layer 261 can be within one or more of the ranges discussed above with regards to the first index of refraction of the polymer-based portion 241. In aspects, a differential equal to the absolute value of the difference between the third index of refraction of the adhesive layer 261 and the first index of refraction of the polymer-based portion 241 can be about 0.1 or less, about 0.07 or less, about 0.05 or less, about 0.001 or more, about 0.01 or more, or about 0.02 or more. In aspects, the differential is in a range from about 0.001 to about 0.1, from about 0.001 to about 0.07, from about 0.001 to about 0.05, from about 0.01 to about 0.1, from about 0.01 to about 0.07, from about 0.01 to about 0.05, from about 0.02 to about 0.1, from about 0.02 to about 0.07, from about 0.02 to about 0.05, or any range or subrange therebetween. In aspects, the third index of refraction of the adhesive layer 261 may be greater than the first index of refraction of the polymer-based portion 241. In aspects, the third index of refraction of the adhesive layer 261 may be less than the first index of refraction of the polymer-based portion 241.

In aspects, a differential equal to the absolute value of the difference between the third index of refraction of the adhesive layer 261 and the second index of refraction of the foldable substrate 201 can be about 0.1 or less, about 0.07 or less, about 0.05 or less, about 0.001 or more, about 0.01 or more, or about 0.02 or more. In aspects, the differential is in a range from about 0.001 to about 0.1, from about 0.001 to about 0.07, from about 0.001 to about 0.05, from about 0.01 to about 0.1, from about 0.01 to about 0.07, from about 0.01 to about 0.05, from about 0.02 to about 0.1, from about 0.02 to about 0.07, from about 0.02 to about 0.05, or any range or subrange therebetween. In aspects, the third index of refraction of the adhesive layer 261 may be greater than the second index of refraction of the foldable substrate 201. In aspects, the third index of refraction of the adhesive layer 261 may be less than the second index of refraction of the foldable substrate 201.

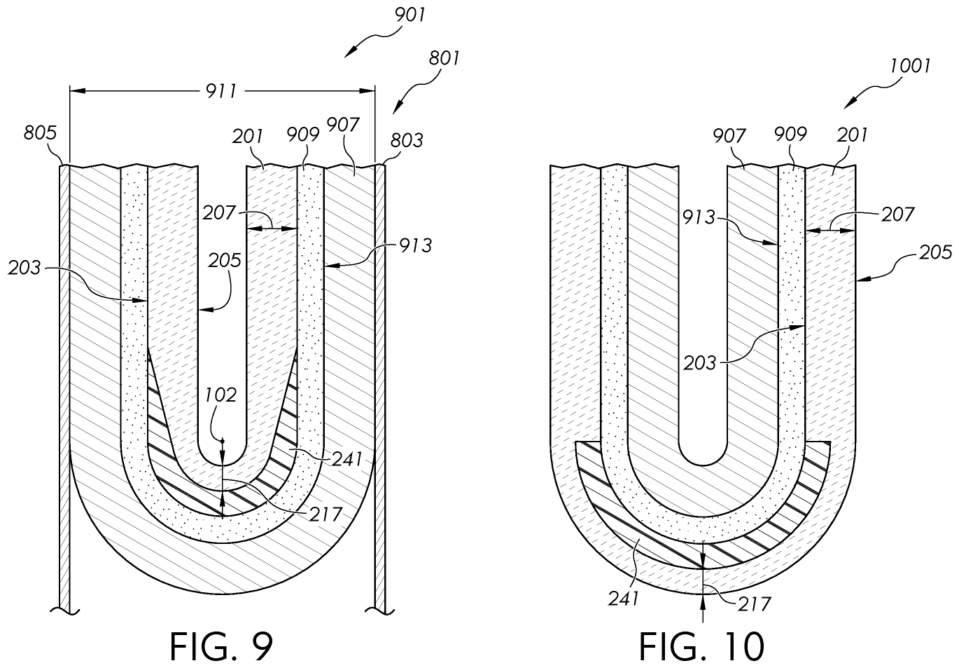

FIGS. 8-10 schematically illustrate aspects of a foldable apparatus 701, 901, and/or 1001 in accordance with aspects of the disclosure in a folded configuration. As shown in FIG. 8, the foldable apparatus 701 is folded such that the second major surface 205 of the foldable substrate 201 is on the inside of the folded foldable apparatus 701. In this case, for example, a display could be located on the side of the second major surface 205, and a user would view the display from the side of the first major surface 203. Alternatively, a display could be located on the side of the first major surface 203, and a user would view the display from the side of the second major surface 205. As shown in FIG. 9, the foldable apparatus 301 shown in FIG. 3 is folded to form folded foldable apparatus 901 such that the second major surface 205 of the foldable substrate 201 is on the inside of the folded foldable apparatus 901. In FIG. 10, a user would view a display device in place of the PET sheet 907 through the foldable substrate 201 and, thus, would be positioned on the side of the second major surface 205. In aspects, as shown in FIGS. 9-10, the polymer-based portion 241 can be disposed over the foldable substrate 201.

As used herein, “foldable” includes complete folding, partial folding, bending, flexing, or multiple capabilities. As used herein, the terms “fail,” “failure” and the like refer to breakage, destruction, delamination, or crack propagation. Likewise, a foldable apparatus achieves a parallel plate distance of “X,” or has a parallel plate distance of “X,” or comprises a parallel plate distance of “X” if it resists failure when the foldable apparatus is held at a parallel plate distance of “X” for 24 hours at about 85° C. and about 85% relative humidity.

As used herein, the “parallel plate distance” of a foldable apparatus and/or foldable substrate is measured with the following test configuration and process using a parallel plate apparatus 801 (see FIGS. 8-9) that comprises a pair of parallel rigid stainless-steel plates 803, 805 comprising a first rigid stainless-steel plate 803 and a second rigid stainless-steel plate 805. When measuring the “parallel plate distance” for the foldable substrate 201 (e.g., the foldable apparatus 401 shown in FIG. 4 consisting of foldable substrate 201), the foldable substrate 201 is placed between the pair of plates 803 and 805 such that the first major surface 203 is in contact with the pair of plates 803 and 805, as shown in FIG. 8. When measuring the “parallel plate distance” for a foldable apparatus resembling the foldable apparatus 101 or 301 shown in FIGS. 2-3, the adhesive layer 261 is removed and is replaced by a test adhesive layer 909 comprising a thickness of 50 μm. Further, the test is conducted with a 100 μm thick sheet 907 of polyethylene terephthalate (PET) rather than with the release liner 271 of FIG. 2 with the PET sheet 907 contacts a first contact surface 913 of the test adhesive layer 909. Thus, during the test to determine the “parallel plate distance” of a configuration of a foldable apparatus, the foldable apparatus 901 is produced by using the 100 μm thick sheet 907 of polyethylene terephthalate (PET) rather than with the release liner 271 of FIG. 2. For example, foldable apparatus 1001 shown in FIG. 10 corresponds to the foldable apparatus 301 shown in FIG. 3 after the adhesive layer 261 and the display device 307 are removed and replaced with the test adhesive layer 909 and the PET sheet 907; however, the parallel plate test would be performed with the foldable apparatus 1001 folded such that the PET sheet 907 is on the outside of the foldable apparatus 1001 such that the pair of parallel rigid stainless-steel plates 803 and 805 contact the PET sheet 907 instead of the PET sheet 907 being on the inside of the foldable apparatus 1001, as shown.

For determining a “parallel plate distance”, the distance between the parallel plates is reduced at a rate of 50 μm/second until the parallel plate distance 811 or 911 is equal to the “parallel plate distance” to be tested. Then, the parallel plates are held at the “parallel plate distance” to be tested for 24 hours at about 85° C. and about 85% relative humidity. As used herein, the “minimum parallel plate distance” is the smallest parallel plate distance that the foldable apparatus can withstand without failure under the conditions and configuration described above.

In aspects, the foldable apparatus 101, 301, 401, 701, 901, and/or 1001 can achieve a parallel plate distance of 100 mm or less, 50 mm or less, 20 mm or less, 10 mm or less, 5 mm or less, or 3 mm or less. In further aspects, the foldable apparatus 101, 301, 401, 701, 901, and/or 1001 can achieve a parallel plate distance of 50 millimeters (mm), or 20 mm, or 10 mm, of 5 mm, or 3 mm. In aspects, the foldable apparatus 101, 301, 401, 701, 901, and/or 1001 can comprise a minimum parallel plate distance of about 40 mm or less, about 20 mm or less, about 10 mm or less, about 5 mm or less, about 3 mm or less, about 1 mm or less, about 1 mm or more, about 3 mm or more, about 5 mm or more, or about 10 mm or more. In aspects, the foldable apparatus 101, 301, 401, 701, 901, and/or 1001 can comprise a minimum parallel plate distance in a range from about 1 mm to about 40 mm, from about 1 mm to about 20 mm, from about 1 mm to about 10 mm, from about 1 mm to about 5 mm, from about 1 mm to about 3 mm. In aspects, the foldable apparatus 101, 301, 401, 701, 901, and/or 1001 can achieve a minimum parallel plate distance in a range from about 2 mm to about 40 mm, from about 2 mm to about 20 mm, from about 2 mm to about 10 mm, from about 3 mm to about 10 mm, from about 3 mm to about 5 mm, from about 5 mm to about 10 mm, or any range or subrange therebetween.

A width 282 of the central portion 281 of the foldable substrate 201 is defined between the first portion 221 and the second portion 231 in the direction 106 of the length 105. In aspects, the width 282 of the central portion 281 of the foldable substrate 201 can extend from the first portion 221 to the second portion 231. A width 282 of the first central surface area 211 of the foldable substrate 201 is defined between the first transition region 212 and the second transition region 218, for example, as the portion comprising the central thickness 217, in the direction 106 of the length 105. In aspects, the width 282 of the central portion 281 of the foldable substrate 201 and/or the width 282 of the first central surface area 211 of the foldable substrate 201 can be about 1.4 times or more, about 1.6 times or more, about 2 times or more, about 2.2 times or more, about 3 times or less, or about 2.5 times or less the minimum parallel plate distance. In aspects, the width 282 of the central portion 281 of the foldable substrate 201 and/or the width 282 of the first central surface area 211 of the foldable substrate 201 as a multiple of the minimum parallel plate distance can be in a range from about 1.4 times to about 3 times, from about 1.6 times to about 3 times, from about 1.6 times to about 2.5 times, from about 2 times to about 2.5 times, from about 2.2 times to about 2.5 times, from about 2.2 times to about 3 times, or any range or subrange therebetween. Without wishing to be bound by theory, the length of a bent portion in a circular configuration between parallel plates can be about 1.6 times the parallel plate distance 811 or 911. Without wishing to be bound by theory, the length of a bend portion in an elliptical configuration between parallel plates can be about 2.2 times the parallel plate distance 811 or 911. In aspects, the width 282 of the central portion 281 of the foldable substrate 201 and/or the width 282 of the first central surface area 211 of the foldable substrate 201 can be about 1 mm or more, about 3 mm or more, about 5 mm or more, about 8 mm or more, about 10 mm or more, about 15 mm or more, about 20 mm or more, about 100 mm or less, about 60 mm or less, about 50 mm or less, about 40 mm or less, about 35 mm or less, about 30 mm or less, or about 25 mm or less. In aspects, the width 282 of the central portion 281 of the foldable substrate 201 and/or the width 282 of the first central surface area 211 of the foldable substrate 201 can be in a range from about 1 mm to about 100 mm, from about 3 mm to about 100 mm, from about 3 mm to about 60 mm, from about 5 mm to about 60 mm, from about 5 mm to about 50 mm, from about 8 mm to about 50 mm, from about 8 mm to about 40 mm, from about 10 mm to about 40 mm, from about 10 mm to about 35 mm, from about 15 mm to about 35 mm, from about 15 mm to about 30 mm, from about 20 mm to about 30 mm, from about 20 mm to about 25 mm, or any range of subrange therebetween. In aspects, the width 282 of the central portion 281 of the foldable substrate 201 and/or the width 282 of the first central surface area 211 of the foldable substrate 201 can be about 2.8 mm or more, about 6 mm or more, about 9 mm or more, about 60 mm or less, about 40 mm, or less, or about 24 mm or less. In aspects, the width 282 of the central portion 281 of the foldable substrate 201 and/or the width 282 of the first central surface area 211 of the foldable substrate 201 can be in a range from about 2.8 mm to about 60 mm, from about 2.8 mm to about 40 mm, from about 2.8 mm to about 24 mm, from about 6 mm to about 60 mm, from about 6 mm to about 40 mm, from about 6 mm to about 24 mm, from about 9 mm to about 60 mm, from about 9 mm to about 40 mm, from about 9 mm to about 24 mm, or any range of subrange therebetween. By providing a width within the above-noted ranges for the central portion (e.g., between the first portion and the second portion), folding of the foldable apparatus without failure can be facilitated.

The foldable apparatus 101, 301, 401, 701, 901, and/or 1001 may have an impact resistance defined by the capability of a region of the foldable apparatus (e.g., a region comprising the first portion 221, a region comprising the second portion 231, a region comprising the polymer-based portion 241 and/or central portion 281) to avoid failure at a pen drop height (e.g., 5 centimeters (cm) or more, 10 centimeters or more, 20 cm or more), when measured according to the “Pen Drop Test.” As used herein, the “Pen Drop Test” is conducted such that samples of foldable apparatus are tested with the load (i.e., from a pen dropped from a certain height) imparted to a major surface (e.g., second major surface 205 of the foldable substrate 201) configured as in the parallel plate test with 100 μm thick sheet 907 of PET attached to the test adhesive layer 909 having a thickness of 50 μm instead of the release liner 271 shown in FIG. 2. As such, the PET layer in the Pen Drop Test is meant to simulate a foldable electronic display device (e.g., an OLED device). During testing, the foldable apparatus bonded to the PET layer is placed on an aluminum plate (6063 aluminum alloy, as polished to a surface roughness with 400 grit paper) with the PET layer in contact with the aluminum plate. No tape is used on the side of the sample resting on the aluminum plate.

A tube is used for the Pen Drop Test to guide a pen to an outer surface of the foldable apparatus. For the foldable apparatus 101, 301, 401, 701, 901, and/or 1001 illustrated in FIGS. 2-4 and 8-10, the pen is guided to an outer surface (e.g., second major surface 205 of the foldable substrate 201), and the tube is placed in contact with the outer surface (e.g., second major surface 205 of the foldable substrate 201) so that the longitudinal axis of the tube is substantially perpendicular to the outer surface (e.g., second major surface 205 of the foldable substrate 201) with the longitudinal axis of the tube extending in the direction of gravity. The tube has an outside diameter of 1 inch (2.54 cm), an inside diameter of nine-sixteenths of an inch (1.4 cm), and a length of 90 cm. An acrylonitrile butadiene (ABS) shim is employed to hold the pen at a predetermined height for each test. After each drop, the tube is relocated relative to the sample to guide the pen to a different impact location on the sample. The pen employed in Pen Drop Test is a BIC Easy Glide Pen, Fine, having a tungsten carbide ballpoint tip of 0.7 mm (0.68 mm) diameter, and a weight of 5.73 grams (g) including the cap (4.68 g without the cap).

For the Pen Drop Test, the pen is dropped with the cap attached to the top end (i.e., the end opposite the tip) so that the ballpoint can interact with the test sample. In a drop sequence according to the Pen Drop Test, one pen drop is conducted at an initial height of 1 cm, followed by successive drops in 0.5 cm increments up to 20 cm, and then after 20 cm, 2 cm increments until failure of the test sample. After each drop is conducted, the presence of any observable fracture, failure, or other evidence of damage to the sample is recorded along with the particular pen drop height. Using the Pen Drop Test, multiple samples can be tested according to the same drop sequence to generate a population with improved statistical accuracy. For the Pen Drop Test, the pen is to be changed to a new pen after every 5 drops, and for each new sample tested. In addition, all pen drops are conducted at random locations on the sample at or near the center of the sample, with no pen drops near or on the edge of the samples.

For purposes of the Pen Drop Test, “failure” means the formation of a visible mechanical defect in a laminate. The mechanical defect may be a crack or plastic deformation (e.g., surface indentation). The crack may be a surface crack or a through crack. The crack may be formed on an interior or exterior surface of a laminate. The crack may extend through all or a portion of the foldable substrate 201 and/or coating. A visible mechanical defect has a minimum dimension of 0.2 mm or more.

In aspects, the foldable apparatus can resist failure for a pen drop in a region comprising the first portion 221 or the second portion 231 at a pen drop height of 10 centimeters (cm), 12 cm, 14 cm, 16 cm, or 20 cm. In aspects, a maximum pen drop height that the foldable apparatus can withstand without failure over a region comprising the first portion 221 or the second portion 231 may be about 10 cm or more, about 12 cm or more, about 14 cm or more, about 16 cm or more, about 40 cm or less, or about 30 cm or less, about 20 cm or less, about 18 cm or less. In aspects, a maximum pen drop height that the foldable apparatus can withstand without failure over a region comprising the first portion 221 or the second portion 231 can be in a range from about 10 cm to about 40 cm, from about 12 cm to about 40 cm, from about 12 cm to about 30 cm, from about 14 cm to about 30 cm, from about 14 cm to about 20 cm, from about 16 cm to about 20 cm, from about 18 cm to about 20 cm, or any range or subrange therebetween.

In aspects, the foldable apparatus can resist failure for a pen drop in a region (e.g., central portion 281) comprising the polymer-based portion 241 between the first portion 221 and the second portion 231 at a pen drop height of 1 cm, 2 cm, 3 cm, 4 cm, 5 cm, or more. In aspects, a maximum pen drop height that the foldable apparatus can withstand without failure over a region comprising the polymer-based portion 241 between the first portion 221 and the second portion 231 may be about 1 cm or more, about 2 cm or more, about 3 cm or more, about 4 cm or more, about 20 cm or less, about 10 cm or less, about 8 cm or less, or about 6 cm or less. In aspects, a maximum pen drop height that the foldable apparatus can withstand without failure over a region comprising the polymer-based portion 241 between the first portion 221 and the second portion 231 can be in a range from about 1 cm to about 20 cm, from about 2 cm to about 20 cm, from about 2 cm to about 10 cm, from about 3 cm to about 10 cm, from about 3 cm to about 8 cm, from about 4 cm to about 8 cm, from about 4 cm to about 6 cm, or any range or subrange therebetween. In aspects, a maximum pen drop height that the foldable apparatus can withstand without failure of a region comprising the polymer-based portion 241 between the first portion 221 and the second portion 231 can be in a range from about 1 cm to about 10 cm, from about 1 cm to about 8 cm, from about 1 cm to about 5 cm, from about 2 cm to about 5 cm, from about 3 cm to about 5 cm, from about 4 cm to about 5 cm, or any range or subrange therebetween.

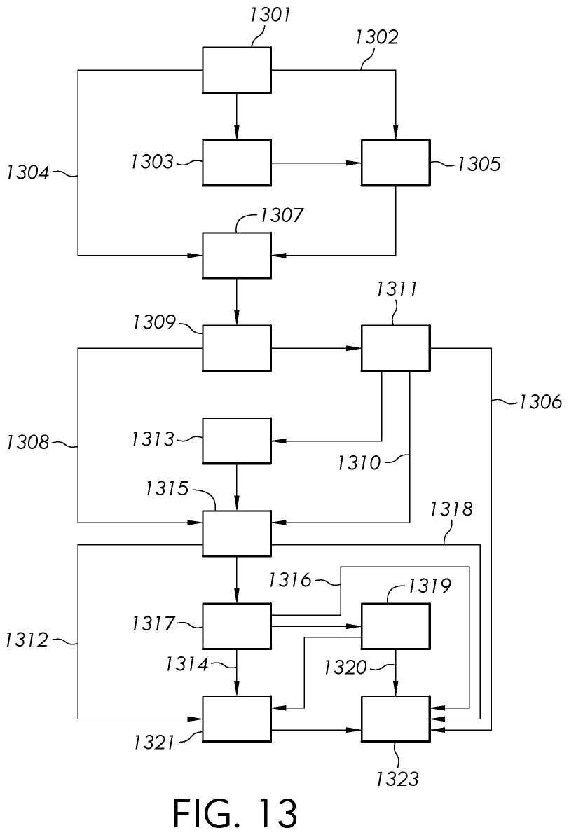

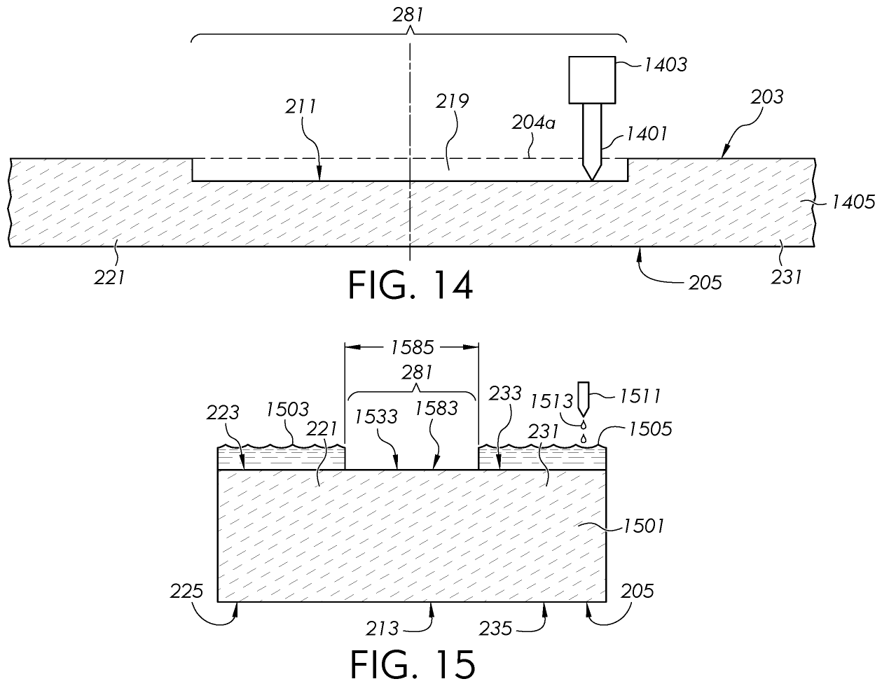

Aspects of methods of making the foldable apparatus and/or foldable substrate in accordance with aspects of the disclosure will be discussed with reference to the flow chart in FIG. 13 and example method steps illustrated in FIGS. 14-33. Example aspects of making the foldable apparatus 101, 301, 401, 701, 901, and/or 1001 illustrated in FIGS. 2-6 and 8-10 will now be discussed with reference to FIGS. 14-33 and the flow chart in FIG. 13. In a first step 1301 of methods of the disclosure, methods can start with providing a foldable substrate 1405 or 1501 (see FIGS. 14-15). In aspects, the foldable substrate 1405 or 1501 may be provided by purchase or otherwise obtaining a substrate or by forming the foldable substrate. In aspects, the foldable substrate 1405 or 1501 can comprise a glass-based substrate and/or a ceramic-based substrate. In further aspects, glass-based substrates and/or ceramic-based substrates can be provided by forming them with a variety of ribbon forming processes, for example, slot draw, down-draw, fusion down-draw, up-draw, press roll, redraw, or float. In further aspects, ceramic-based substrates can be provided by heating a glass-based substrate to crystallize one or more ceramic crystals. The foldable substrate 1405 or 1501 may comprise a second major surface 205 (see FIGS. 14-15) that can extend along a plane. The second major surface 205 can be opposite a first major surface 203 or 1533 (see FIGS. 14-15). In aspects, as shown in FIG. 15, in step 1301, the foldable substrate 1405 or 1501 can comprise an existing first central surface area 1583 that is coplanar with the first surface area 223 and/or the third surface area 233, for example, the initial first major surface 1533 can comprise the existing first central surface area 1583, the first surface area 223, and the third surface area 233. In aspects, as shown in FIGS. 14-15, in step 1301, the foldable substrate 1405 or 1501 can comprise the second major surface 205 comprising the second central surface area 213, the second surface area 225, and the fourth surface area 235. In aspects, the foldable substrate 1405 or 1501 can be substantially unstrengthened (e.g., not chemically strengthened) at the end of step 1301.

After step 1301, as shown in FIGS. 14-17, methods can proceed to step 1303 comprising forming the recess 219 by removing at least a portion of the existing first central surface area 1583 (see FIG. 15) to form the first central surface area 211 of the central portion 281. As discussed above with reference to FIGS. 2-3, forming the recess 219 can optionally comprise forming the first transition surface area 283 and the second transition surface area 285. In aspects, as shown in FIG. 14, step 1303 can comprise forming the recess 219 by mechanically working (e.g., grinding) at least a portion of the existing first central surface area 1583. For example, the existing first central surface area 1583 may be mechanically worked by diamond engraving to produce very precise patterns in glass-based substrates and/or ceramic-based substrates. As shown in FIG. 14, diamond engraving can be used to create the recess 219, where a diamond-tip probe 1401 can be controlled using a computer numerical control (CNC) machine 1403. Materials other than diamond can be used for engraving with a CNC machine.

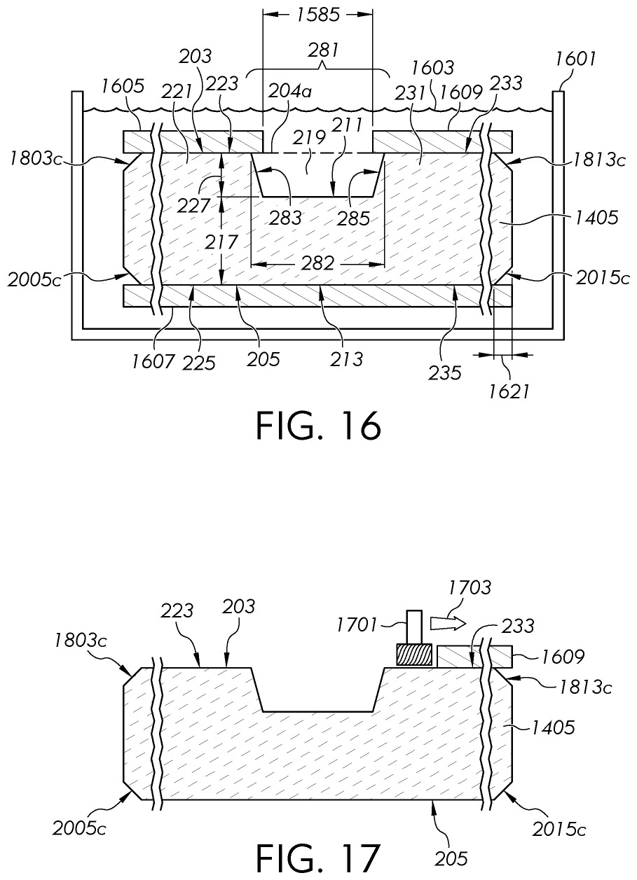

In aspects, as shown in FIGS. 15-20, step 1303 can comprise forming the recess 219 by etching at least a portion of the existing first central surface area 1583. In further aspects, as shown in FIGS. 15-16, step 1303 can comprise disposing a first etch mask 1605 over the first major surface 203 in the first portion 221 and disposing a second etch mask 1609 over the first major surface 203 in the second portion 231. In even further aspects, as shown in FIG. 15, step 1303 can comprise disposing a first liquid 1513 over one or more portions of the foldable substrate 1501. In still further aspects, as shown, the first liquid 1513 can be dispensed from a container 1511 (e.g., conduit, flexible tube, micropipette, or syringe). In still further aspects, as shown, the first liquid 1513 can be disposed over the first surface area 223 (e.g., first major surface 203 in the first portion 221) as a first liquid deposit 1503 and over the third surface area 233 (e.g., first major surface 203 in the second portion 231) as a second liquid deposit 1505. Although not shown, it is to be understood a liquid deposit can be formed over the entire second major surface to form a third etch mask 1607 (see FIG. 16). In further aspects, the liquid deposits (e.g., first liquid deposit 1503 and second liquid deposit 1505 shown in FIG. 15) can be cured to form masks (e.g., first etch mask 1605 and second etch mask 1609 shown in FIG. 16). Curing the first liquid can comprise heating the first liquid 1513, irradiating the first liquid 1513 with ultraviolet (UV) radiation, and/or waiting a predetermined amount of time (e.g., from about 30 minutes to 24 hours, from about 1 hour to about 8 hours). In aspects, another method (e.g., chemical vapor deposition (CVD) (e.g., low-pressure CVD, plasma-enhanced CVD), physical vapor deposition (PVD) (e.g., evaporation, molecular beam epitaxy, ion plating), atomic layer deposition (ALD), sputtering, spray pyrolysis, chemical bath deposition, sol-gel deposition) may be used to form the etch mask(s) (e.g., etch masks 1605, 1607, and/or 1609 shown in FIG. 16). As shown in FIG. 16, a first etch mask 1605 can be disposed over the first surface area 223 (e.g., first major surface 203 in the first portion 221), a second etch mask 1609 disposed over a third surface area 233 (e.g., first major surface 203 in the second portion 231), and a third etch mask 1607 disposed over the second major surface 205 (e.g., entire second major surface 205). In aspects, a minimum distance 1585 can be defined between the first etch mask 1605 and the second etch mask 1609 that can be within one or more of the ranges discussed above for the width 282 of the central portion 281. In further aspects, as shown, the minimum distance 1585 can be less than the width 282 of the central portion 281 of the resulting foldable substrate 201. In aspects, a material of the etch masks can comprise titanium dioxide (TiO₂), zirconia (ZrO₂), tin oxide (SnO₂), alumina (Al₂O₃), silica (SiO₂), silicon nitride (Si₃N₄), and/or combinations thereof, although other materials for masks can be used in other aspects.

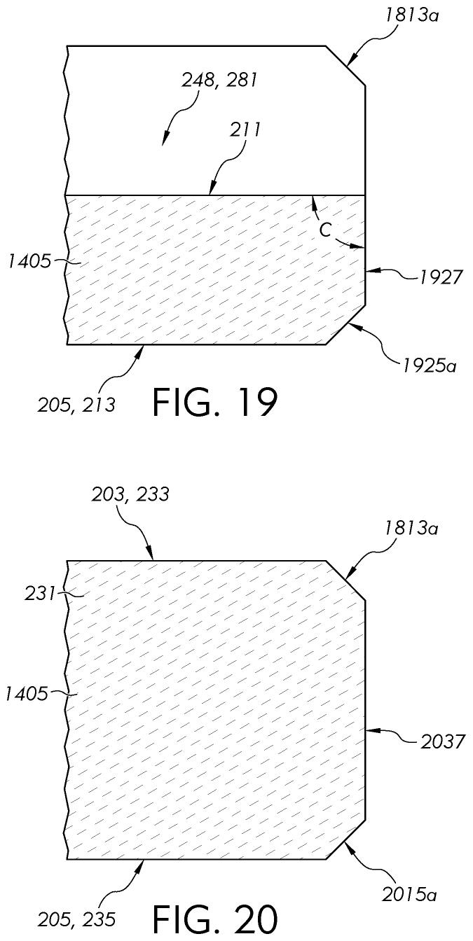

In further aspects, as shown by comparing FIG. 15 and FIG. 16, etching at least a portion of the existing first central surface area 1583 (see FIG. 15) in step 1303 can comprise contacting the central portion 281 of the foldable substrate 1501 comprising the existing first central surface area 1583 of the initial first major surface 1533 with a first etchant 1603 (see FIG. 16) to form the foldable substrate 1405 comprising the first central surface area 211. In even further aspects, as shown in FIG. 16, the central portion 281 of the foldable substrate 1405 can comprise the central thickness 217 between the first central surface area 211 and the second major surface 205 (e.g., second central surface area 213), which can be within one or more of the ranges discussed above for the central thickness 217. In even further aspects, as shown, the central portion 281 of the foldable substrate 1405 can comprise the first central surface area 211 recessed from the first major surface 203 (e.g., first plane 204a) by the first distance 227 that can be within one or more of the ranges discussed above for the first distance 227. In even further aspects, as shown, the etching can undercut the first etch mask 1605 to form the first transition surface area 283 and/or undercut the second etch mask 1609 to form the second transition surface area 285. In even further aspects, the first etchant can comprise one or more acids (e.g., HCl, HF, H₂SO₄, HNO₃). An exemplary aspect of the first etchant can comprise an etching solution comprising hydrofluoric acid. In even further aspects, as shown in FIG. 16, the first etchant 1603 can comprise a liquid etchant that can be contained in an etchant bath 1601. In still further aspects, as shown, the etching can comprise immersing the foldable substrate 1501 in the etchant bath 1601 to from the foldable substrate 1405 comprising the first central surface area 211. In still yet further aspects, as shown in FIGS. 16-20, the etching can form an initial edge comprising blunted initial surface areas 1803a-c (see FIGS. 16-18), 1813a-c (see FIGS. 16-18), 1925a (see FIG. 19), 2005c (see FIGS. 16-17), 2015a (see FIG. 20), and 2015c (see FIGS. 16-17) (further discussed below) of the foldable substrate 1405, for example, by undercutting the outer peripheral edges of the etch masks 1605, 1607, and 1609. In even yet further aspects, as shown, the initial edge can comprise initial edge thickness 1621 corresponding to a distance that the blunted initial surface areas 1803c, 1813c, 2005c, and/or 2015c extend from the outermost periphery of the foldable substrate 1405.

In further aspects, as shown by comparing FIG. 16 and FIG. 17, as shown in FIG. 17, step 1303 can further comprise removing the etch masks 1605, 1607, and 1609 from the first surface area 223, the second major surface 205, and the third surface area 233, respectively. In even further aspects, as shown, removing the etch masks (e.g., etch masks 1605, 1607, and 1609) can comprise moving a grinding tool 1701 in a direction 1703 across the surface (e.g., third surface area 233). In even further aspects, using the tool may comprise sweeping, scraping, grinding, pushing, etc. In further aspects, the etch masks (e.g., etch masks 1605, 1607, and 1609) can be removed by washing the surface (e.g., first surface area 223, third surface area 233, second major surface 205) with a solvent and/or an alkaline solution.

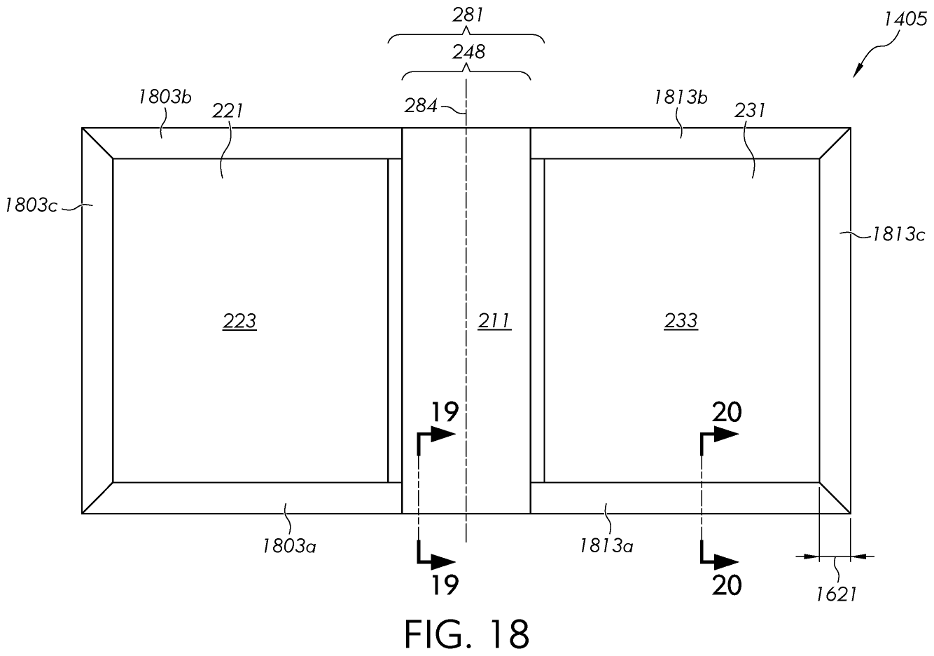

In aspects, as shown in FIGS. 18-20, the foldable substrate 1405 can comprise the initial edge at the end of step 1303. In further aspects, as shown in FIG. 19, the first central surface area 211 of the central portion 281 may not comprise a blunted edge at least because angle C is about 90°, which is not an obtuse angle, where an initial central edge surface 1927 meets the first central surface area 211. Without wishing to be bound by theory, forming the recess 219 (e.g., by etching) in step 1303 can substantially uniformly remove material from the existing first central surface area 1583 (see FIG. 15) since the etch masks 1605 and 1609 do not restrict etching at the edge shown in FIG. 19 nor in the middle of the central portion 281. In contrast, step 1303 can result in an initial second blunted surface area 1925a and 2015a (see FIGS. 19-20) formed from the periphery of the second central surface area 213 because of undercutting of the third etch mask 1607 (see FIG. 16). Likewise, a first blunted initial surface area 1803a-1803c and 1813a-1813c (see FIG. 18) can be formed from the initial first major surface 1533 (see FIG. 15) (e.g., first surface area 223, third surface area 233) by undercutting of the first etch mask 1605 and/or the second etch mask 1609 (see FIG. 16). Consequently, as shown in FIG. 20, the second portion 231 can comprise an initial second edge surface 2037 positioned between the initial first blunted surface area 1813a and the initial second blunted surface area 2015a.

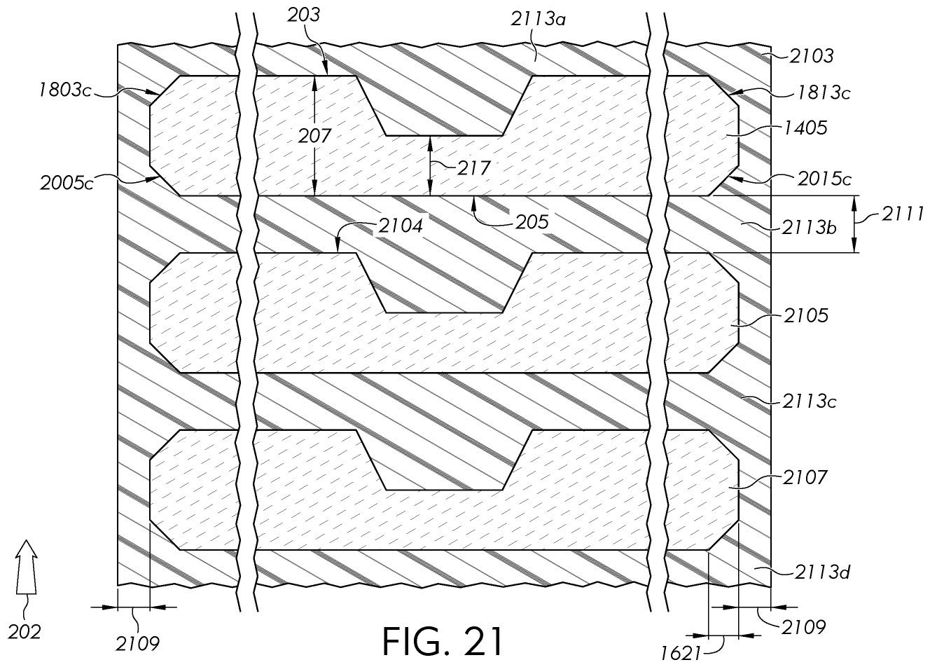

In aspects, after step 1301 or 1303, as shown in FIG. 21, methods can proceed to step 1305 comprising laminating the foldable substrate 1405 with a first support layer 2113a contacting the first major surface 203 and a second support layer 2113b contacting the second major surface 205. In further aspects, as shown, the first support layer 2113a and the second support layer 2113b can comprise a polymer-based portion 2103 encasing (e.g., encapsulating) the foldable substrate 1405 with a polymer thickness 2109 defined as a minimum distance between the foldable substrate 1405 (e.g., blunted initial surface areas 1803c, 1813c, 2005c, and 2015c) and an outer surface of the polymer-based portion 2103. In even further aspects, the polymer thickness 2109 can be about 10 μm or more, about 100 μm or more, about 500 μm or more, about 10 mm or less, about 5 mm or less, or about 1 mm or less. In even further aspects, the polymer thickness can be in a range from about 10 μm to about 10 mm, from about 10 μm to about 5 mm, from about 100 μm to about 5 mm, from about 500 μm to about 5 mm, from about 500 μm to about 1 mm, or any range or subrange therebetween. In further aspects, as shown, more than one foldable substrate (e.g., foldable substrate 1405, another foldable substrate 2105, additional foldable substrate 2107) can be laminated together using support layers (e.g., first support layer 2113a, second support layer 2113b, third support layer 2113c, fourth support layer 2113d). In further aspects, at least one support layer (e.g., second support layer 2113b) can be positioned between adjacent pairs of foldable substrates (e.g., foldable substrate 1405 and another foldable substrate 2105). In even further aspects, a support layer can be bonded to the second major surface of a first foldable substrate and the first major surface of a second foldable substrate. For example, as shown, the second support layer 2113b can be bonded to the second major surface 205 of the foldable substrate 1405 and a first major surface 2104 of the another foldable substrate 2105. In further aspects, a support layer (e.g., second support layer 2113b) can comprise a support thickness 2111 defined as a minimum distance in the direction 202 of the substrate thickness 207. In even further aspects, the support thickness 2111 can be greater than the central thickness 217. In even further aspects, the support thickness 2111 can be about 100 μm or more, about 300 μm or more, about 500 μm or more, about 100 mm or less, about 10 mm or less, or about 1 mm or less. In even further aspects, the support thickness 2111 can be in a range from about 100 μm to about 100 mm, from about 100 μm to about 10 μm, from about 300 μm to about 10 mm, from about 300 μm to about 1 mm, from about 500 μm to about 1 mm, or any range or subrange therebetween. In further aspects, the polymer-based portion 2103 and/or the support layers (e.g., first support layer 2113a, second support layer 2113b, third support layer 2113c, fourth support layer 2113d) can comprise one or more of the materials discussed above for the polymer-based portion 241. In even further aspects, the polymer-based portion 2103 and/or the support layers can comprise wax, silicones, epoxies, acrylates, or combinations thereof, for example, materials in the TEMPLOC product line from Denka Co. Ltd.

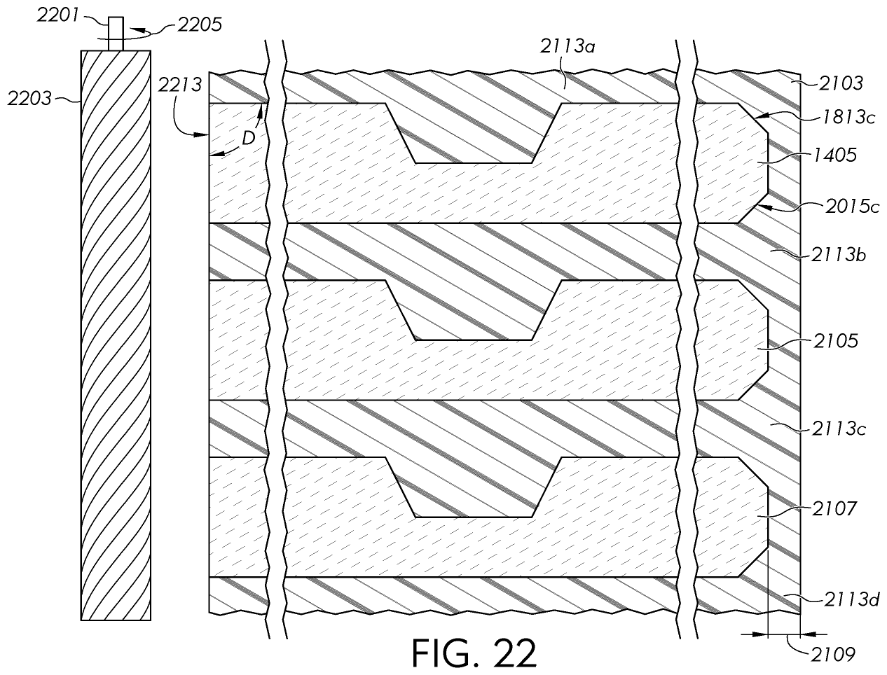

After step 1301 or 1305, as shown in FIG. 22, methods can proceed to step 1307 comprising removing a peripheral portion of the initial edge (e.g., blunted initial surface areas 1803c, 1813c, 2005c, and 2015c) of the foldable substrate 1405 to form an intermediate edge 2213 of the foldable substrate 1405. In aspects, as shown in FIG. 22, step 1307 can comprise removing the peripheral portion of the initial edge by machining the support layers (e.g., polymer-based portion 2103, first support layer 2113a, second support layer 2113b, third support layer 2113c, fourth support layer 2113d) using a grinding tool 2203 mounted on a shaft 2201 and rotating in a direction 2205, where the grinding tool 2203 contact the support layers to remove at least the polymer thickness 2109, and a portion of the initial edge to form an intermediate edge 2213 of the foldable substrate 1405. In further aspects, as shown, step 1307 (e.g., using the grinding tool 2203) can remove at least an initial edge thickness 1621 (see FIGS. 16 and 18) corresponding to a distance the initial edge extends from the outermost periphery of the foldable substrate. In further aspects, as shown, step 1307 can comprise removing the at least a portion of the initial edge between the first major surface and the second major surface in the first portion. In even further aspects, as shown in FIG. 22, step 1307 can comprise removing the at least a portion of the initial edge between the first major surface and the second major surface in the second portion, and/or step 1307 can comprise removing the at least a portion of the initial edge between the first central surface area and the second central surface area in the central portion. In further aspects, the at least a portion removed can be removed from an entire periphery of the foldable substrate. For example, the entire initial edge (e.g., blunted initial surface areas 1803a-c, 1813a-c, 2005a-c, and 2015c) can be removed from the foldable substrate 1405. In further aspects, as shown, the intermediate edge 2213 can comprise non-blunt (e.g., sharp) edges with the first major surface 203 and the second major surface 205. For example, as shown, angle D can be a substantially right angle. In further aspects, although not shown, the intermediate edge can extend between the first central surface area and the second central surface area in the central portion, for example, as a non-blunt edge. In even further aspects, although not shown, the intermediate edge can extend between the second major surface and the first transition surface area and/or between the second major surface and the second transition surface area, for example, as a non-blunt edge. Although not shown, it is to be understood that step 1307 can remove the entire initial edge and optionally a predetermined portion of the periphery of the foldable substrate beyond the initial edge.

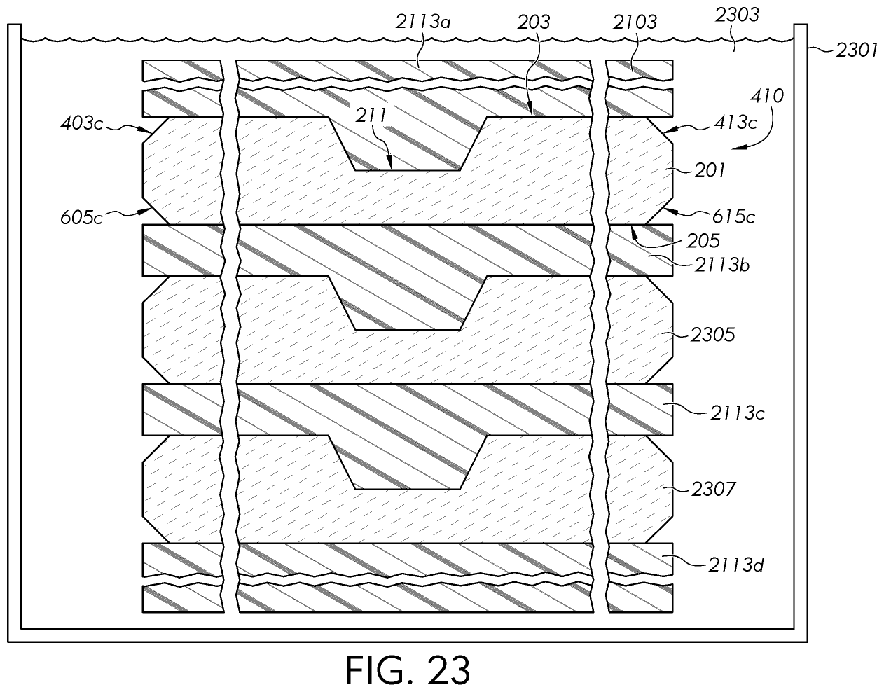

After step 1307, as shown by comparing FIG. 22 and FIG. 23, methods can proceed to step 1309 comprising contacting the intermediate edge 2213 of the foldable substrate 1405 with a second etchant to form the foldable substrate 201 comprising a blunted edge. In aspects, the second etchant can comprise one or more acids (e.g., HCl, HF, H₂SO₄, HNO₃). An exemplary aspect of the second etchant can comprise an etching solution comprising hydrofluoric acid. In further aspects, the first etchant can comprise the same composition as the second etchant. In further aspects, as shown in FIG. 23, the second etchant 2303 can comprise a liquid etchant that can be contained in an etchant bath 2301. In even further aspects, as shown, the etching can comprise immersing the foldable substrate 1405 in the etchant bath 1601 to from the foldable substrate 201 comprising the blunted edge 410 comprising the first blunted surface areas 403a-c and 413a-c, the second blunted surface areas 525a, 605c, 615a, and 615c, and the central blunted surface areas 423a-b (discussed above with reference to FIGS. 4-6). For example, as discussed above with reference to FIGS. 4-6, the blunted edge can extend around an entire periphery of the foldable substrate, which includes between the first major surface and the second major surface in the first portion and the second portion as well as between the first central surface area and the second central surface area in the second central surface area. In still further aspects, as shown in FIGS. 23 and 4-6, the etching can form the blunted edge, for example, by undercutting the outer peripheral edges of the support layers (e.g., support layers 2113a-d). Without wishing to be bound by theory, the etching can form the blunted edge by undercutting the outer peripheral edges when an isotropic etchant is used and the undercut surface faces the support layers (e.g., first support layer 2113a or second support layer 2113b) of the polymer-based portion 2103. As discussed above, the etching in step 1309 can produce the a central blunted surface area 423a-b that can reduce an incidence of mechanical instabilities, for example, by enabling the central region 248 to be symmetric about the third plane 588. In still further aspects, as shown, the another foldable substrate 2105 and the additional foldable substrate 2107 can be transformed into an another foldable substrate 2305 and the additional foldable substrate 2307 by forming blunted edges, for example, similar to or identical to the blunted edge discussed above with reference to FIGS. 4-6. In aspects, the contacting the intermediate edge 2213 with the second etchant in step 1309 can remove an average thickness of about 1 μm or more, about 5 μm or more, about 10 μm or more, about 500 μm or less, about 100 μm or less, about 50 μm or less, about 30 μm or less, or about 20 μm or less from a surface of the intermediate edge. In aspects, the contacting the intermediate edge 2213 with the second etchant in step 1309 can remove an average thickness in a range from about 1 μm to about 500 μm, from about 1 μm to about 100 μm, from about 1 μm to about 50 μm, from about 5 μm to about 50 μm, from about 5 μm to about 30 μm, from about 10 μm to about 30 μm, from about 10 μm to about 20 μm, or any range or subrange therebetween.

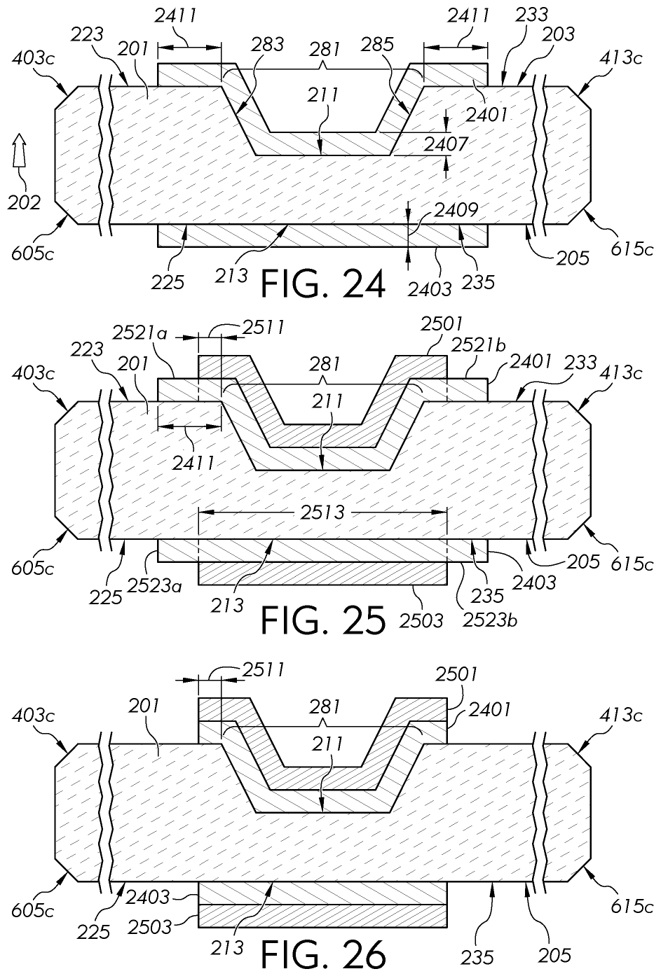

After step 1309, as shown by comparing FIG. 23 with any of FIGS. 24-32, methods can proceed to step 1311 comprising removing the first support layer 2113a from the foldable substrate 201 (e.g., first major surface 203, first central surface area 211), and removing the second support layer 2113b from the foldable substrate 201 (e.g., the second major surface 205). In aspects, the first support layer 2113a and/or the second support layer 2113b can be removed from the foldable substrate 201 using a solvent, an alkaline solution, peeling, grinding, or combinations thereof. For example, the support layers (e.g., first support layer 2113a, the second support layer 2113b) can be removed by contacting the corresponding support layer with a solvent and/or an alkaline solution, which can comprise rinsing with or immersing in the solvent and/or alkaline solution. Without wishing to be bound by theory, the support layers (e.g., first support layer 2113a, the second support layer 2113b) can be removed with a solvent and/or an alkaline solution by dissolving a portion of the corresponding support layer and/or by swelling the corresponding support layer, which can disrupt the interface between the corresponding support layer and the foldable substrate.

After step 1311, as shown in FIGS. 24-27, methods can proceed to step 1313 comprising disposing a first barrier layer 2401 over the first central surface area 211 and disposing a second barrier layer 2403 over the second central surface area 213. In aspects, as shown in FIGS. 24-27, the first barrier layer 2401 can be disposed on and/or contact the first transition surface area 283, the first central surface area 211, and/or the second transition surface area 285. In further aspects, as shown, the first barrier layer 2401 can be disposed on a portion of the first surface area 223 and a portion of the third surface area 233. In even further aspects, as shown in FIG. 24, an initial barrier width 2411 of the first barrier layer 2401 disposed over the first surface area 223 can be about 100 μm or more, about 500 μm or more, about 1 mm or more, about 50 mm or less, about 10 mm or less, about 5 mm or less, or about 2 mm or less. In even further aspects, as shown in FIG. 24, an initial barrier width 2411 of the first barrier layer 2401 disposed over the first surface area 223 can be in a range from about 100 μm to about 50 mm, from about 100 μm to about 10 mm, from about 500 μm to about 10 mm, from about 500 μm to about 5 mm, from about 1 mm to about 5 mm, from about 1 mm to about 2 mm. In even further aspects, although not shown, the first barrier layer 2401 may not contact the first surface area 223 and/or the third surface area 233 (i.e., the initial barrier width 2411). In aspects, as shown in FIGS. 24-27, the second barrier layer 2403 can be disposed on and/or contact the second central surface area 213, and/or at least portion of the second major surface 205 outside of the central portion 281 (e.g., second surface area 225, fourth surface area 235). In further aspects, as shown in FIG. 24, the second barrier layer 2403 can comprise the initial barrier width 2411 over the second surface area 225 and/or the fourth surface area 235.

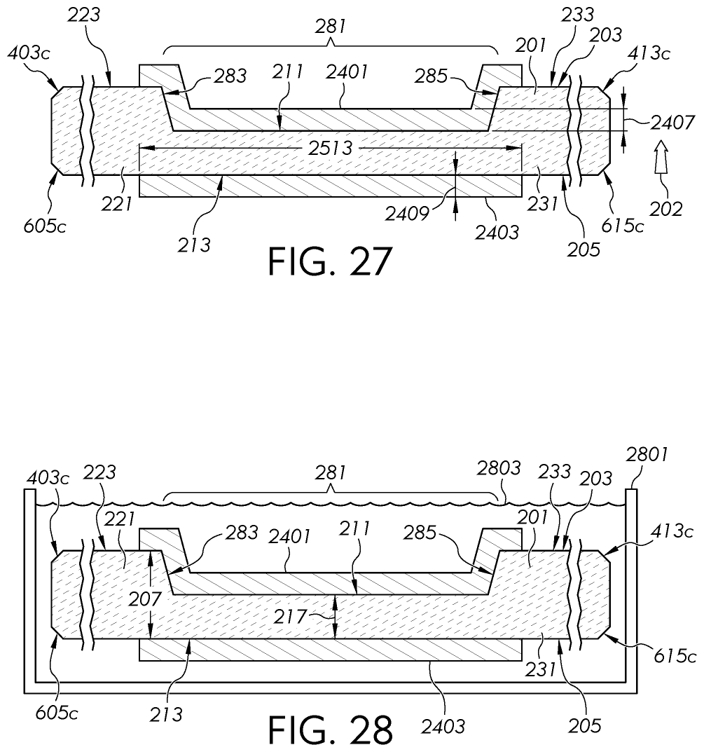

In aspects, the first barrier layer 2401 and/or the second barrier layer 2403 can reduce the diffusion of alkali metal ions therethrough during chemical strengthening in step 1315 (discussed below). In further aspects, the first barrier layer 2401 and/or the second barrier layer 2403 can prevent the diffusion of alkali metal ions therethrough during chemical strengthening in step 1315 (discussed below). In further aspects, the first barrier layer 2401 and/or the second barrier layer 2403 can comprise a covalent solid, as compared with an ionic solid. Without wishing to be bound by theory, a covalent solid can reduce (e.g., prevent, block) the diffusion of alkali metal ions therethrough. In further aspects, the first barrier layer 2401 and/or the second barrier layer 2403 can comprise one aluminum nitride (AlN), aluminum oxynitride (AlON, as described above), sputtered silicon nitride (Si₃N₄), or combinations thereof. In aspects, the second barrier layer 2403 can comprise the same material as the first barrier layer 2401. In aspects, disposing the first barrier layer 2401 and/or the second barrier layer 2403 can comprise sputtering, chemical vapor deposition, thermal evaporation, or electron-beam deposition. An exemplary aspect of disposing the first barrier layer 2401 and/or the second barrier layer 2403 comprises sputtering. In aspects, as shown in FIGS. 24 and 27, the first barrier layer 2401 can comprise a first barrier thickness 2407 measured as the minimum distance between surfaces of the first barrier layer 2401 in the direction 202 of the substrate thickness over the first central surface area 211, and/or the second barrier layer 2403 can comprise a second barrier thickness 2409 measured as the minimum distance between surfaces of the second barrier layer 2403 in the direction 202 of the substrate thickness over the second central surface area 213. In further aspects, the first barrier thickness 2407 and/or the second barrier thickness 2409 can be about 5 nanometers (nm) or more, about 10 nm or more, about 20 nm or more, about 50 nm or more, about 100 nm or more, about 10 μm or less, about 2 μm or less, about 1 μm or less, about 500 nm or less, or about 200 nm or less. In further aspects, the first barrier thickness 2407 and/or the second barrier thickness 2409 can be in a range from about 5 nm to about 10 μm, from about 5 nm to about 2 μm, from about 10 nm to about 2 μm, from about 10 nm to about 1 μm, from about 20 nm to about 1 μm, from about 20 nm to about 500 nm, from about 50 nm to about 500 nm, from about 50 nm to about 200 nm, from about 100 nm to about 200 nm, or any range or subrange therebetween. In further aspects, the first barrier thickness 2407 and/or the second barrier thickness 2409 can be in a range from about 10 nm to about 500 nm, from about 10 nm to about 200 nm, from about 20 nm to about 200 nm, or any range or subrange therebetween. In further aspects, the first barrier thickness 2407 can be substantially equal to the second barrier thickness 2409.

Without wishing to be bound by theory, an increased density of a barrier layer can further reduce the diffusion of alkali metal ions therethrough. Without wishing to be bound by theory, an increased density of a barrier layer can correspond to a greater index of refraction relative to a lower density barrier layer of the same composition. In aspects, a refractive index of the first barrier layer and/or the second barrier layer can be about 1.5 or more, about 1.6 or more, about 1.7 or more, about 1.8 or more, about 2.1 or more, about 2.5 or less, about 2.3 or less, about 2.2 or less, about 2.1 or less, about 2 or less, or about 1.9 or less. In aspects, a refractive index of the first barrier layer and/or the second barrier layer can be in a range from about 1.5 to about 2.5, from about 1.6 to about 2.5, from about 1.6 to about 2.3, from about 1.7 to about 2.2, from about 1.7 to about 2.1, from about 1.7 to about 2, from about 1.7 to about 1.9, or any range or subrange therebetween. In aspects, a refractive index of the first barrier layer and/or the second barrier layer can be in range from about 1.7 to about 2.5, from about 1.8 to about 2.5, from about 2.1 to about 2.5, from about 2.1 to about 2.3, from about 2.2 to about 2.3, or any range or subrange therebetween.

In aspects, as shown in FIG. 25, step 1313 can further comprise disposing a third etch mask 2501 over a portion of first barrier layer 2401. In further aspects, as shown, the third etch mask 2501 can be centered on the first barrier layer 2401. In further aspects, as shown, the third etch mask 2501 can extend across the central portion 281 and extend beyond the central portion 248 over the first surface area 223 for a first barrier width 2511. In further aspects, the third etch mask may not extend beyond the central portion 248 (i.e., the first barrier width 2511 can be 0). In aspects, as shown in FIG. 25, step 1313 can further comprise disposing a fourth etch mask 2503 over a portion of second barrier layer 2403. In further aspects, as shown, the fourth etch mask 2503 can be centered on the second barrier layer 2403. In further aspects, as shown, the fourth etch mask 2503 can extend across the central portion 281 and extend beyond the central portion over the second surface area 225 for the first barrier width 2511. The third etch mask 2501 and/or the fourth etch mask 2503 can be used to control the width of the first barrier layer 2401 and/or the second barrier layer 2403, respectively, for example, if first barrier layer 2401 and/or the second barrier layer 2403 is disposed using a method where a predetermined width cannot be precisely obtained and/or if the chemically-strengthening induced strain profile is to be controlled precisely. For example, the third etch mask 2501 and/or the fourth etch mask 2503 can permit etching away of portions 2521a, 2521b, 2323a, and/or 2523b to produce the first barrier layer 2401 and/or the second barrier layer 2403 comprising a full barrier width 2513. In aspects, as shown in FIG. 25, the third etch mask 2501 and the fourth etch mask 2503 can comprise the full barrier width 2513. In further aspects, the full barrier width 2513 can be equal to or greater than the minimum distance 1585, and/or the full barrier width 2513 can be equal to or greater than the width 282 of the central portion 281. For example, as shown in FIG. 25, the full barrier width 2513 (e.g., width of the barrier layers 2401, 2403 in FIGS. 26-28) is greater than the width 282 of the central portion 281 (see FIG. 2) because the full barrier width 2513 extends beyond the central portion 281 for the first barrier width 2511. In aspects, the width of the third etch mask 2501 (e.g., full barrier width 2513) can be substantially equal to the width of the fourth etch mask 2503 (e.g., full barrier width 2513). In aspects, the third etch mask 2501 and/or the fourth etch mask 2503 can comprise one or more of the materials discussed above for the first etch mask 1605.

In further aspects, as shown between FIG. 25 and FIG. 26, step 1313 can further comprise removing a first portion 2521a of the first barrier layer 2401 and/or a second portion 2521b of the first barrier layer 2401. In further aspects, as shown, step 1313 can further comprise removing a first portion 2523a of the second barrier layer 2403 and/or a second portion 2523b of the second barrier layer 2403. As discussed above, removing one or more portions of the first barrier layer 2401 and/or the second barrier layer 2403 can change the width of the corresponding barrier layer, for example, to be the full barrier width 2513. In even further aspects, removing the portions 2521a, 2521b, 2523a, and/or 2523b can comprise contacting the corresponding portions of the corresponding barrier layer with an alkaline solution. In even further aspects, the alkaline solution can comprise a temperature of about 20° C. or more, about 30° C. or more, about 40° C. or more, about 50° C. or more, about 60° C. or more, about 70° C. or more, about 120° C. or less, about 100° C. or less, about 90° C. or less, or about 80° C. or less. In even further aspects, the alkaline solution can comprise a temperature in a range from about 20° C. to about 120° C., from about 20° C. to about 100° C., from about 30° C. to about 100° C., from about 40° C. to about 100° C., from about 40° C. to about 90° C., from about 50° C. to about 90° C., from about 50° C. to about 80° C., from about 60° C. to about 80° C., from about 70° C. to about 80° C., or any range or subrange therebetween. In even further aspects, the alkaline solution can comprise an alkaline detergent solution, for example, with a concentration of the alkaline detergent from about 1 wt % to about 4 wt % or from about 2 wt % to about 3 wt %. An exemplary aspect of the alkaline detergent solution is Semiclean KG available from Yokohama Oils & Fats Industry Co., Ltd.

Although not shown in FIG. 28, in aspects, the method can proceed from step 1313 to a step 1315 comprising chemically strengthening while the third etch mask 2501 and/or the fourth etch mask 2503 are still disposed over the corresponding first and/or second barrier layers 2401, 2403. In further aspects, as shown between FIG. 26 and FIG. 27, step 1313 can further comprise removing the third etch mask 2501 and/or the fourth etch mask 2503. In even further aspects, removing the third etch mask 2501 and/or the fourth etch mask 2503 can comprise one or more of the techniques discussed above for removing the first etch mask 1605. In aspects, as shown in FIGS. 26-27, at the end of step 1313, a first barrier width 2511 can be within one or more of the ranges discussed above for the initial barrier width 2411. In further aspects, as shown in FIG. 25, the first barrier width 2511 can be less than the initial barrier width 2411. In aspects, as shown in FIGS. 26-27, at the end of step 1313, the second barrier layer 2403 can comprise the first barrier width 2511 (e.g., width of the barrier layers 2401, 2403 in FIGS. 26-28) over the second surface area 225 and/or the fourth surface area 235.

After step 1309, 1311, or 1313, as shown in FIG. 28, methods can proceed to step 1315 comprising chemically strengthening the first portion 221 of the foldable substrate 201 and the second portion 231 of the foldable substrate 201. In aspects, the foldable substrate 201 can be substantially unstrengthened before the chemically strengthening of step 1315. In aspects, as shown, chemically strengthening the foldable substrate 201 can comprise contacting at least a portion of a foldable substrate 201 comprising lithium cations and/or sodium cations with a salt bath 2801 comprising a salt solution 2803. Chemically strengthening a foldable substrate 201 (e.g., glass-based substrate, ceramic-based substrate) by ion exchange can occur when a first cation within a depth of a surface of a foldable substrate 201 is exchanged with a second cation within a molten salt or salt solution 2803 that has a larger radius than the first cation. For example, a lithium cation within the depth of the surface of the foldable substrate 201 can be exchanged with a sodium cation or potassium cation within a salt solution 2803. Consequently, the surface of the foldable substrate 201 is placed in compression and thereby chemically strengthened by the ion exchange process since the lithium cation has a smaller radius than the radius of the exchanged sodium cation or potassium cation within the salt solution 2803. Chemically strengthening the foldable substrate 201 can comprise contacting at least a portion of a foldable substrate 201 comprising lithium cations and/or sodium cations with a salt bath 2801 comprising the salt solution 2803 comprising potassium nitrate, potassium phosphate, potassium chloride, potassium sulfate, sodium chloride, sodium sulfate, sodium nitrate, and/or sodium phosphate, whereby lithium cations and/or sodium cations diffuse from the foldable substrate 201 to the salt solution 2803 contained in the salt bath 2801. In aspects, the temperature of the salt solution 2803 can be about 300° C. or more, about 360° C. or more, about 400° C. or more, about 500° C. or less, about 460° C. or less, or about 420° C. or less. In aspects, the temperature of the salt solution 2803 can be in a range from about 300° C. to about 500° C., from about 360° C. to about 500° C., from about 400° C. to about 500° C., from about 300° C. to about 460° C., from about 360° C. to about 460° C., from about 400° C. to about 460° C., from about 400° C. to about 420° C., from about 300° C. to about 400° C., from about 360° C. to about 420° C., or any range or subrange therebetween. In aspects, the foldable substrate 201 can be in contact with the salt solution 2803 for about 5 minutes or more, about 30 minutes or more, about 1 hour or more, about 3 hours or more, about 48 hours or less, about 24 hours or less, or about 8 hours or less. In aspects, the foldable substrate 201 can be in contact with the salt solution 2803 for a time in a range from about 5 minutes to about 48 hours, from about 30 minutes to about 48 hours, from about 30 minutes to about 24 hours, from about 1 hour to about 24 hours, from about 3 hours to about 24 hours, from about 3 hours to about 8 hours, or any range or subrange therebetween. In aspects, the foldable substrate 201 can be in contact with the salt solution 2803 for a time in a range from about 5 minutes to about 8 hours, from about 30 minutes to about 8 hours, from about 1 hour to about 8 hours, or any range or subrange therebetween.

In aspects, chemically strengthening the foldable substrate 201 in step 1315 can comprise chemically strengthening the first portion 221 comprising at least a portion of the first surface area 223 to form a first compressive stress region extending to a first depth of compression from the first surface area 223. In further aspects, chemically strengthening the foldable substrate 201 in step 1315 can comprise chemically strengthening the second portion 231 comprising at least a portion of the third surface area 233 to form a third compressive stress region extending to a third depth of compression from the first surface area 223. In aspects, chemically strengthening the foldable substrate 201 in step 1315 can comprise chemically strengthening the first portion 221 comprising at least a portion of the second surface area 225 to form a second compressive stress region extending to a second depth of compression from the second surface area 225. In aspects, chemically strengthening the foldable substrate 201 in step 1315 can comprise chemically strengthening the second portion 231 comprising at least a portion of the fourth surface area 235 to form a second compressive stress region extending to a second depth of compression from the fourth surface area 235. Without wishing to be bound by theory, chemically strengthening the foldable substrate 1405 without performing at least steps 1307 and 1309 can result in mechanical instabilities at least due to the lack of symmetry of the central region 248 of the central portion 281.

In aspects, the first depth of compression, second depth of compression, third depth of compression, and/or the fourth depth of compression, as a percentage of the substrate thickness 207 (see FIG. 28), can be about 5% or more, 10% or more, about 12% or more, about 14% or more, about 25% or less, about 20% or less, about 18% or less, or about 16% or less. In aspects, first depth of compression, second depth of compression, third depth of compression, and/or the fourth depth of compression, as a percentage of the substrate thickness 207 (see FIG. 28), can be in a range from about 5% to about 25%, from about 8% to about 25%, from about 8% to about 20%, from about 10% to about 20%, from about 10% to about 18%, from about 12% to about 18%, from about 12% to about 16%, from about 14% to about 16%, or any range or subrange therebetween. In aspects, first depth of compression, second depth of compression, third depth of compression, and/or the fourth depth of compression, as a percentage of the substrate thickness 207 (see FIGS. 2-3 and 28), can be within one or more of the ranges discussed above for the first depth of compression as a percentage of the substrate thickness. In aspects, a first depth of layer of one or more alkali-metal ions associated with the first compressive stress region, a second depth of layer of one or more alkali-metal ions associated with the second compressive stress region, a third depth of layer of one or more alkali-metal ions associated with the third compressive stress region, and/or a fourth depth of layer of one or more alkali-metal ions associated with the fourth compressive stress region as a percentage of the substrate thickness 207 (see FIG. 28), can be about 5% or more, 10% or more, about 12% or more, about 14% or more, about 25% or less, about 20% or less, about 18% or less, or about 16% or less. In aspects, a first depth of layer of one or more alkali-metal ions associated with the first compressive stress region, a second depth of layer of one or more alkali-metal ions associated with the second compressive stress region, a third depth of layer of one or more alkali-metal ions associated with the third compressive stress region, and/or a fourth depth of layer of one or more alkali-metal ions associated with the fourth compressive stress region as a percentage of the substrate thickness 207 (see FIG. 28), can be in a range from about 5% to about 25%, from about 8% to about 25%, from about 8% to about 20%, from about 10% to about 20%, from about 10% to about 18%, from about 12% to about 18%, from about 12% to about 16%, from about 14% to about 16%, or any range or subrange therebetween. In aspects, a first depth of layer of one or more alkali-metal ions associated with the first compressive stress region, a second depth of layer of one or more alkali-metal ions associated with the second compressive stress region, a third depth of layer of one or more alkali-metal ions associated with the third compressive stress region, and/or a fourth depth of layer of one or more alkali-metal ions associated with the fourth compressive stress region as a percentage of the substrate thickness 207 (see FIG. 28), can be within one or more of the ranges discussed above for the first depth of layer as a percentage of the substrate thickness. At the end of step 1315, the foldable substrate 201 can comprise the first compressive stress region, the second compressive stress region, the third compressive stress region, and/or the fourth compressive stress region can comprise a corresponding maximum compressive stress within one or more of the ranges discussed above for the corresponding maximum compress stress of the corresponding compressive stress region and/or the corresponding depth of compression can be within one or more of the ranges discussed above for the corresponding depth of compression of the corresponding compressive stress region.

In aspects, at the end of step 1315, the first compressive stress region can extend for less than the entire first surface area 223, for example, because the first barrier layer 2401 covers a portion of the first surface area 223 (see FIG. 28). In aspects, at the end of step 1315, the second compressive stress region can extend for less than the entire second surface area 225, for example, because the second barrier layer 2403 covers a portion of the second surface area 225 (see FIG. 28). In aspects, at the end of step 1315, the third compressive stress region can extend for less than the entire third surface area 233, for example, because the first barrier layer 2401 covers a portion of the third surface area 233 (see FIG. 28). In aspects, at the end of step 1315, the fourth compressive stress region can extend for less than the entire fourth surface area 235, for example, because the second barrier layer 2403 covers a portion of the fourth surface area 235 (see FIG. 28). In aspects, at the end of step 1315, the central portion 281 can be substantially unstrengthened. For example, as shown in FIG. 28, the first central surface area 211 can be covered by the first barrier layer 2401, and/or the second central surface area 213 can be covered by the second barrier layer 2403. For example, as further shown in FIG. 28, the first transition surface area 283 and/or the second transition surface area 285 can be covered by the first barrier layer 2401.

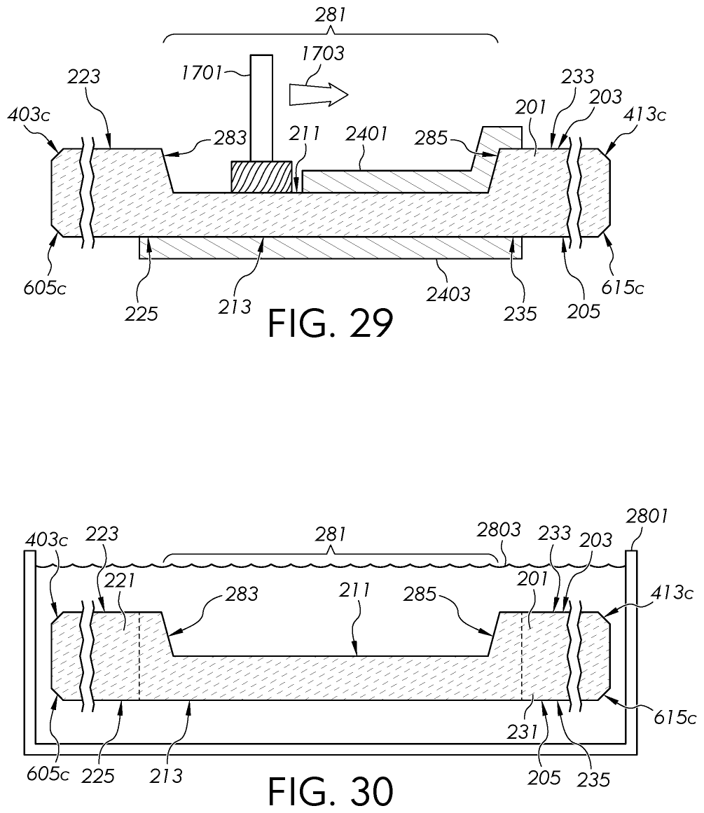

After step 1315, as shown in FIG. 29, methods can proceed to step 1317 comprising removing the first barrier layer 2401 and/or removing the second barrier layer 2403. In aspects, as shown, removing the first barrier layer 2401 can comprise moving the grinding tool 1701 in a direction 1703 across the surface (e.g., first central surface area 211, first transition surface area 283, second transition surface area 285). Likewise, removing the second barrier layer 2403 can comprise moving the grinding tool 1701 across the surface (e.g., second central surface area 213, second major surface 205). In even further aspects, using the tool may comprise sweeping, scraping, grinding, pushing, etc. In further aspects, the first barrier layer 2401 and/or the second barrier layer 2403 can be removed by washing the surface (e.g., first central surface area 211, first transition surface area 283, second transition surface area 285, and/or second central surface area 213, second major surface 205) with a solvent. In even further aspects, removing the first barrier layer 2401 and/or the second barrier layer 2403 can comprise contacting the corresponding barrier layer with an alkaline solution. In even further aspects, the alkaline solution can comprise a temperature of about 20° C. or more, about 30° C. or more, about 40° C. or more, about 50° C. or more, about 60° C. or more, about 70° C. or more, about 120° C. or less, about 100° C. or less, about 90° C. or less, or about 80° C. or less. In even further aspects, the alkaline solution can comprise a temperature in a range from about 20° C. to about 120° C., from about 20° C. to about 100° C., from about 30° C. to about 100° C., from about 40° C. to about 100° C., from about 40° C. to about 90° C., from about 50° C. to about 90° C., from about 50° C. to about 80° C., from about 60° C. to about 80° C., from about 70° C. to about 80° C., or any range or subrange therebetween. In even further aspects, the alkaline solution can comprise an alkaline detergent solution, for example, with a concentration of the alkaline detergent from about 1 wt % to about 4 wt % or from about 2 wt % to about 3 wt %. An exemplary aspect of the alkaline detergent solution is Semiclean KG available from Yokohama Oils & Fats Industry Co., Ltd.

After step 1317, as shown in FIG. 30, methods can proceed to step 1319 comprising further chemically strengthening the foldable substrate 201. In aspects, as shown, chemically strengthening the foldable substrate 201 in step 1319 can comprise contacting at least a portion of a foldable substrate 201 comprising potassium cations and/or sodium cations in the salt bath 2801 comprising the salt solution 2803. In further aspects, a composition of the salt solution 2803 in step 1319 can comprise one or more of the materials discussed above for the salt solution 2803 in step 1315. In further aspects, a composition of the salt solution 2803 in step 1319 can be the same as the salt solution 2803 discussed above in step 1315. In further aspects, a temperature of the salt solution in step 1319 can be within one or more of the ranges discussed above with reference to the temperature of the salt solution 2803 in step 1315. In further aspects, a time that the salt solution contacts the foldable substrate 201 in step 1319 can be within one or more of the ranges discussed above with reference to the time that the salt solution 2803 contacts the foldable substrate 201. In further aspects, a time that the salt solution 2803 contacts the foldable substrate 201 in step 1317 can be less than the time that the salt solution 2803 contacts the foldable substrate 201 in step 1315. In aspects, as shown in FIG. 30, the salt solution 2803 can further chemically strengthen the first portion 221 by contacting the first surface area 223 and/or the second surface area 225. In further aspects, as shown, the salt solution 2803 can contact the entire first surface area 223 and/or the entire second surface area.

In aspects, as shown in FIG. 30, the salt solution 2803 can further chemically strengthen the second portion 231 by contacting the third surface area 233 and/or the fourth surface area 235. In further aspects, as shown, the salt solution 2803 can contact the entire third surface area 233 and/or the entire fourth surface area 235. In aspects, as shown in FIG. 30, the salt solution 2803 can chemically strengthen the central portion 281 comprising the first central surface area 211, first transition surface area 283, the second transition surface area 285, and/or the second central surface area 213. For example, chemically strengthening the central portion 281 in step 1319 can produce a first central compressive stress region extending from at least the first central surface area 211 to a first central depth of compression with an associated first central depth of layer of one or more alkali metal ions associated with the first central depth of compression. For example, chemically strengthening the central portion 281 in step 1319 can produce a second central compressive stress region extending from at least the second central surface area 213 to a second central depth of compression with an associated second central depth of layer of one or more alkali metal ions associated with the second central depth of compression. As a result of step 1317, the regions of the foldable substrate 201 can be extended from the regions of the first portion 221 and/or the second portion 231 previously chemically strengthened and indicated by the dashed lined to encompass the entire foldable substrate 201. At the end of step 1319, the foldable substrate 201 can comprise the first compressive stress region, the second compressive stress region, the third compressive stress region, the fourth compressive stress region, the first central compressive stress region, and/or the second central compressive stress region can comprise a corresponding maximum compressive stress within one or more of the ranges discussed above for the corresponding maximum compress stress of the corresponding compressive stress region and/or the corresponding depth of compression can be within one or more of the ranges discussed above for the corresponding depth of compression of the corresponding compressive stress region.

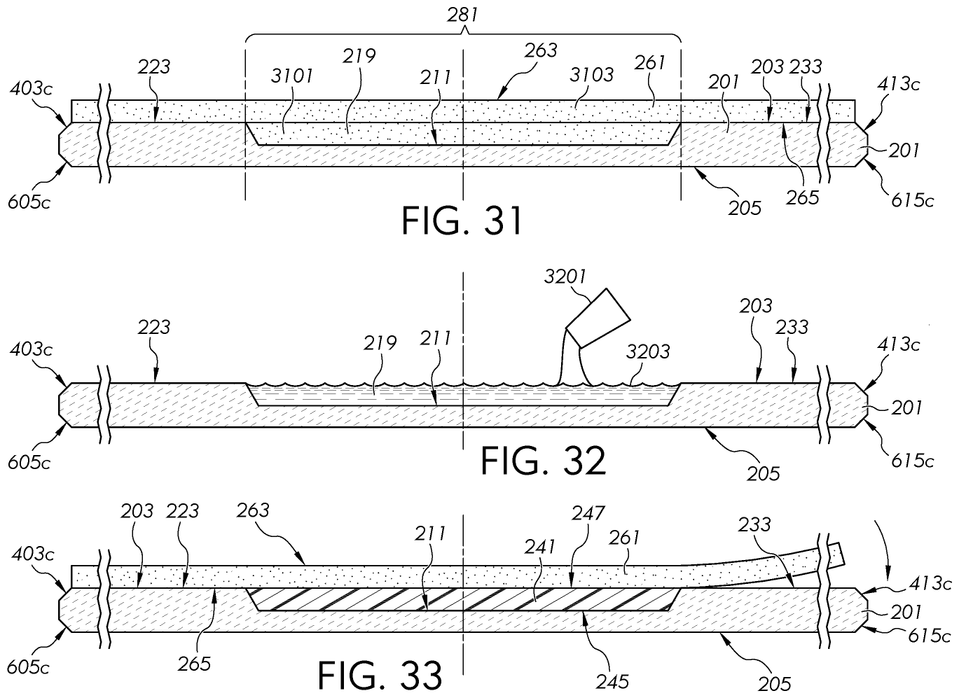

After step 1315, 1317, or 1319, as shown in FIGS. 31-33, methods can proceed to step 1321 comprising assembling the foldable apparatus. In aspects, as shown in FIGS. 31-33, step 1321 can comprise assembling the foldable apparatus by disposing a polymer-based portion 241, an adhesive layer 261, and/or a coating over the foldable substrate 201. In further aspects, as shown in FIG. 31, the adhesive layer 261 can be disposed in the recess 219, over the first central surface area 211, and/or the first major surface 203 (e.g., first surface area 223, third surface area 233). In further aspects, as shown in FIG. 31, the adhesive layer 261 can comprise one or more sheets of an adhesive material (e.g., first sheet 3101 disposed in the recess 219, second sheet 3103 disposed over the first sheet 3101). In further aspects, there can be an integral interface between the one or more sheets comprising the adhesive layer 261, which can reduce (e.g., avoid) optical diffraction and/or optical discontinuities as light travels between the sheets since the one or more sheets can include substantially the same index of refraction. In further aspects, as shown in FIG. 33, the polymer-based portion 241 can be disposed in the recess 219 and/or over the first central surface area 211. In further aspects, although not shown, a coating can be disposed over the second major surface 205. In further aspects, as shown in FIGS. 32-33, the polymer-based portion 241 can be disposed in the recess 219 (e.g., over the first central surface area 211) for example, by dispensing a second liquid 3203 from a container 3201 (e.g., conduit, flexible tube, micropipette, or syringe) over the first central surface area 211 that can be cured to form the polymer-based portion 241. In even further aspects, the second liquid 3203 may comprise a coating precursor, a solvent, particles, nanoparticles, and/or fibers. In still further aspects, the coating precursor can comprise, without limitation, one or more of a monomer, an accelerator, a curing agent, an epoxy, and/or an acrylate. Curing the second liquid 3203 can comprise heating the second liquid 3203, irradiating the second liquid 3203 with ultraviolet (UV) radiation, and/or waiting a predetermined amount of time (e.g., from about 30 minutes to 24 hours, from about 1 hour to about 8 hours). In aspects, although not shown, the polymer-based portion 241 can be disposed in the recess 219 (e.g., fill the recess 219) without contacting the first major surface 203 (e.g., first surface area 223, third surface area 233). In aspects, although not shown, a portion of the polymer-based portion 2103 can be left in the recess 219, which can avoid the need to deposit a polymer-based portion in step 1321, for example, if the foldable substrate 201 is not chemically strengthened.

In further aspects, as shown in FIG. 33, the adhesive layer 261 can be disposed over the polymer-based portion 241, for example, by disposing an already formed sheet of the material of the adhesive layer 261. In even further aspects, as shown in FIGS. 31 and 33, the adhesive layer 261 can be disposed over and/or contact the first major surface 203 (e.g., first surface area 223, third surface area 233). In aspects, although not shown, step 1321 can comprise disposing the adhesive layer 261 over the second major surface 205. In aspects, although not shown, step 1321 can comprise disposing a coating over the first major surface 203 and/or in the recess 219. In aspects, a release liner (e.g., see release liner 271 in FIG. 2) or a display device (e.g., see display device 307 in FIG. 3) may be disposed on the adhesive layer 261 (e.g., first contact surface 263). After step 1311, 1315, 1317, 1319, or 1321, methods of the disclosure according to the flow chart in FIG. 13 of making the foldable substrate and/or foldable apparatus can be complete at step 1323.

In aspects, methods of making a foldable apparatus in accordance with aspects of the disclosure can proceed along steps 1301, 1303, 1305, 1307, 1309, 1311, 1313, 1315, 1317, 1319, 1321, and 1323 of the flow chart in FIG. 13 sequentially, as discussed above. In aspects, arrow 1302 can be followed from step 1301 to step 1305, for example, when the foldable substrate 1405 already comprises the recess 219. In aspects, arrow 1304 can be followed from step 1301 to step 1307, for example, when the foldable substrate 1405 already comprises a laminate with the recess 219. In aspects, arrow 1308 can be followed from step 1309 to step 1315, for example, when the support layers comprise the same material as the barrier layers. In aspects, arrow 1310 can be followed from step 1311 to step 1315, for example, when the central portion 281 of the foldable substrate 201 to be chemically strengthened in step 1315. In aspects, arrow 1312 can be followed from step 1315 to step 1321, for example, when the foldable substrate 201 is not to be further chemically strengthened during the method. In aspects, arrow 1314 can be followed from step 1317 to step 1321, for example, when the foldable substrate 201 is not further chemically strengthened. In aspects, arrow 1306 can be followed from step 1311 to step 1323, for example, when the foldable substrate 201 is complete after step 1311. In aspects, arrow 1318 can be followed from step 1315 to step 1323, for example, when the method is complete after the foldable substrate 201 is chemically strengthened in step 1315. For example, the barrier layers may be part of a larger device that the foldable substrate is to be incorporated into, the barrier layers may be useful for subsequent processing (e.g., in another method), and/or for storage of the foldable substrate prior to subsequent processing (e.g., in another method). In aspects, arrow 1316 can be followed from step 1317 to step 1323, for example, when the method is complete after removing the barrier layers in step 1317. In aspects, arrow 1320 can be followed from step 1319 to step 1323, for example, when the method is complete after the further chemically strengthening the foldable substrate 201 in step 1319. Any of the above options may be combined to make a foldable apparatus in accordance with aspects of the disclosure.

### EXAMPLES

Various aspects will be further clarified by the following examples. Examples A-H and AA comprise a glass-based substrate (Composition 1 having a nominal composition in mol % of: 63.6 SiO₂; 15.7 Al₂O₃; 10.8 Na₂O; 6.2 Li₂O; 1.16 ZnO; 0.04 SnO₂; and 2.5 P₂O₅) with a substrate thickness 207 of 100 μm, a central thickness 217 of 30 μm, a width 282 of the central portion 281 of 20 mm, and the transition between the central region and the first portion or second portion comprised a width of about 100 μm. Examples A-H were processed following the methods described above with the barrier layers (e.g., first barrier layer 2401 and second barrier layer 2403 shown in FIGS. 24-28) comprising the material stated in Tables 1-2. Examples A-E comprised a barrier thickness of about 100 nm while Examples F—H comprised the thickness (barrier thickness) shown in Table 2. For Examples A and E, AlN and Al₂O₃ were deposited using sputtering. For Examples B—C and F—H, AlON and SiAlON were deposited using reactive sputtering. For Example D, SiC was deposited using plasma-enhanced chemical vapor deposition (PECVD). For Examples A-H, the barrier layer was removed using an etching solution comprising dilute phosphoric acid.

Table 1 presents the durability of barrier layer through the chemical strengthening in step 1315 and removal in step 1317. Ideally, the barrier layer serves as a barrier to ions from the salt bath and does not crack or dissolve during step 1317, but the barrier layer can easily be removed in step 1317 with an etching solution. For Example A-H and AA, step 1315 comprised immersing the foldable substrate in a salt bath consisting of 100 wt % KNO₃ maintained at 390° C. for 30 minutes. As shown in Table 1, Example D (SiC) cracked due to thermal shock when placed in the salt bath. Example E (Al₂O₃) was at least partially dissolved in the salt bath. Examples A-C survived the chemical strengthening of step 1315 without problems. However, Example C (SiAlON) was hard to remove using the etching solution without damaging a surface of the foldable substrate. Examples A-B (AlN and AlON) were removed using the etching solution without damaging the foldable substrate.

TABLE 1
Durability of Examples A-E

| Example | Material | Durability |
|---|---|---|
| A | AlN | Good, removed with etching |
| B | AlON | Good, removed with etching |
| C | SiAlON | Good, hard to remove |
| D | SiC | Cracked from thermal shock |
| E | Al₂O₃ | Dissolved in KNO₃ bath |

TABLE 2
Properties of Examples F-H and AA

| | | | | Compressive | Depth of |
|---|---|---|---|---|---|
| | | Thickness | | Stress | Layer |
| Example | Material | (nm) | Durability | (MPa) | (μm) |
| F | AlON | 38 | Good | 0 | 0 |
| G | AlON | 94 | Good | 0 | 0 |
| H | AlON | 335 | Cracked | N/A | N/A |
| AA | None | 0 | N/A | 1,000 | 10.2 |

As shown in Table 2, the barrier layer of Examples F—H comprise AlON while Example AA is a comparative example. In Table 2, “compressive stress” refers to the maximum compressive stress of the first central surface area measured using the FSM-6000 after the barrier layer is removed at the end of step 1317 while the “depth of layer” is determined from using the SCALP-5 at the end of step 1317. Examples F-G were able to prevent diffusion of the ions in the salt bath such that no compressive stress nor depth of layer was detectable. In contrast, Example H cracked due to thermal shock upon being placed in the salt bath. Consequently, providing a thickness of an AlON barrier layer of less than 300 nm can prevent cracking due to thermal shock. Example AA comprised a compressive stress of 1,000 MPa and a depth of layer of 10.2 μm. Comparing Examples F-G with Example AA, 100% of the compressive stress and depth of layer was prevented by the AlON, which had a barrier thickness as low as 38 nm in Example F. Examples F-G were tested in the parallel plate apparatus to a parallel plate distance of 3 mm. Examples F-G were able to obtain the parallel plate distance of 3 mm without encountering any mechanical instabilities.

The above observations can be combined to provide foldable substrates, foldable apparatus comprising foldable substrates, and methods of making foldable substrates that comprise a first portion and a second portion and foldable apparatus comprising foldable substrates. The portions can comprise glass-based and/or ceramic-based portions, which can provide good dimensional stability, reduced incidence of mechanical instabilities, good impact resistance, and/or good puncture resistance. The first portion and/or the second portion can comprise glass-based and/or ceramic-based portions comprising one or more compressive stress regions, which can further provide increased impact resistance and/or increased puncture resistance. By providing a substrate comprising a glass-based and/or ceramic-based substrate, the substrate can also provide increased impact resistance and/or puncture resistance while simultaneously facilitating good folding performance. In aspects, the substrate thickness can be sufficiently large (e.g., from about 80 micrometers (microns or μm) to about 2 millimeters) to further enhance impact resistance and puncture resistance. Providing foldable substrates comprising a central portion comprising a central thickness that is less than a substrate thickness can enable a small parallel plate distance (e.g., about 10 millimeters or less) based on the reduced thickness in the central portion.

In aspects, the foldable apparatus and/or foldable substrates can comprise a recess, for example, a first central surface area recessed from a first major surface by a first distance. Providing a recess can increase bendability of the foldable apparatus since the central thickness can be less than the substrate thickness. Additionally, controlling properties of a material positioned in the recess can control the position of a neutral axis of the foldable apparatus and/or foldable substrates, which can reduce (e.g., mitigate, eliminate) the incidence of mechanical instabilities, apparatus fatigue, and/or apparatus failure.

Providing a blunted edge between the first major surface and the second major surface and/or between the first central surface area and the second major surface can increase an impact resistance and/or decrease an incidence of failure of the foldable substrate. Providing the blunted edge extending around an entire periphery of the foldable substrate can further increase an impact resistance and/or decrease an incidence of failure of the foldable substrate. Further, providing the blunted edge comprising the first blunted surface area, the second blunted surface area, and the central blunted surface area can reduce and/or avoid mechanical instabilities. For example, the foldable substrate can be symmetric about a first plane extending in a direction of the central thickness and along a midline between the first portion and the second portion, and/or the foldable substrate can be symmetric about a second plane extending in the direction of the central thickness and perpendicular to the first plane. Providing a central region of the central portion that can be symmetric about a third plane extending parallel to the first central surface area and the second central surface area at a midpoint therebetween. Since mechanical instabilities can develop from an asymmetry in a region of the foldable substrate as a region where stress and/or strain concentrates, providing the central region symmetric about the first plane, the second plane, and/or the third plane can reduce the incidence of mechanical instabilities. Since the regions comprising the smallest thickness are the most susceptible to mechanical instabilities (e.g., lower critical buckling strain, less stress required to reach a critical buckling strain), reducing the chance of mechanical instabilities in the central region comprising the central thickness reduces the incidence of mechanical instabilities for the foldable substrate overall.

Providing the foldable substrate with a central portion that can be substantially unstrengthened can reduce an incidence of mechanical instabilities. For example, the unstrengthened central portion can result in a chemical strengthening induced expansion strain profile of the foldable substrate measured from a midline of the central portion that monotonically increase, which can reduce an incidence of mechanical instabilities. Similarly, a profile of absolute values of the maximum tensile stress or the maximum compressive stress of the foldable substrate measured from a midline of the central portion can monotonically increase. Alternatively, providing a central portion comprising a depth of compression and/or depth of layer as a percentage of the central thickness that is less than or equal to the corresponding depth of the first portion as a percentage of the substrate thickness can reduce an incidence of mechanical instabilities while increasing the puncture resistance of the entire foldable substrate.

Method aspects of the disclosure can reduce an incidence of mechanical instabilities while increasing an impact resistance and/or increase a puncture resistance of the foldable apparatus. For example, methods can produce the blunted edge described above that includes the central blunted surface area. Using the method of aspects of the disclosure comprising etching the foldable substrate after removing an initial edge can produce an edge surface with minimal surface flaws (e.g., preexisting or generated during prior processing) since surface flaws can be treated (e.g., blunted, removed, reduced) during the etching. By forming the edge surface before chemically strengthening the foldable substrate, mechanical instabilities of the foldable substrate can be avoided during processing as well as in the final foldable substrate. Providing the first barrier layer and the second barrier layer over the central portion can reduce mechanical instabilities by establishing the chemical strengthening induced expansion strain profile, maximum tensile stress profile, and/or compressive stress profile described above, which can reduce an incidence of mechanical instabilities. Providing a barrier layer comprising a covalent solid can minimize an amount of material needed to achieve one of the above-mentioned profiles. Providing a barrier layer comprising aluminum nitride, aluminum oxynitride, and/or sputtered silicon nitride can achieve one of the above-mentioned profiles while being removable without damaging the foldable substrate.

Directional terms as used herein—for example, up, down, right, left, front, back, top, bottom—are made only with reference to the figures as drawn and are not intended to imply absolute orientation.

It will be appreciated that the various disclosed aspects may involve features, elements, or steps that are described in connection with that aspect. It will also be appreciated that a feature, element, or step, although described in relation to one aspect, may be interchanged or combined with alternate aspects in various non-illustrated combinations or permutations.

It is also to be understood that, as used herein the terms “the,” “a,” or “an,” mean “at least one,” and should not be limited to “only one” unless explicitly indicated to the contrary. For example, reference to “a component” comprises aspects having two or more such components unless the context clearly indicates otherwise. Likewise, a “plurality” is intended to denote “more than one.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. Ranges can be expressed herein as from “about” one particular value, and/or to “about” another particular value. When such a range is expressed, aspects include from the one particular value and/or to the other particular value. Similarly, when values are expressed as approximations, by use of the antecedent “about,” it will be understood that the particular value forms another aspect. Whether or not a numerical value or endpoint of a range in the specification recites “about,” the numerical value or endpoint of a range is intended to include two aspects: one modified by “about,” and one not modified by “about.” It will be further understood that the endpoints of each of the ranges are significant both in relation to the other endpoint and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In aspects, “substantially similar” may denote values within about 10% of each other, for example, within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular aspects may be disclosed using the transitional phrase “comprising,” it is to be understood that alternative aspects, including those that may be described using the transitional phrases “consisting of” or “consisting essentially of,” are implied. Thus, for example, implied alternative aspects to an apparatus that comprises A+B+C include aspects where an apparatus consists of A+B+C and aspects where an apparatus consists essentially of A+B+C. As used herein, the terms “comprising” and “including”, and variations thereof shall be construed as synonymous and open-ended unless otherwise indicated.

The above aspects, and the features of those aspects, are exemplary and can be provided alone or in any combination with any one or more features of other aspects provided herein without departing from the scope of the disclosure.

It will be apparent to those skilled in the art that various modifications and variations can be made to the present disclosure without departing from the spirit and scope of the disclosure. Thus, it is intended that the present disclosure cover the modifications and variations of the aspects herein provided they come within the scope of the appended claims and their equivalents.

1. A foldable substrate comprising:
a substrate thickness in a range from about 100 micrometers to about 2 millimeters defined between a first major surface and a second major surface opposite the first major surface;
a first portion comprising the substrate thickness between a first surface area of the first major surface and a second surface area of the second major surface;
a second portion comprising the substrate thickness between a third surface area of the first major surface and a fourth surface area of the second major surface;
a central portion comprising a central thickness in a range from about 25 micrometers to about 200 micrometers defined between a first central surface area and a second central surface area opposite the first central surface area, the first central surface area recessed from the first major surface by a first distance, and the second major surface comprising the second central surface area; and
a blunted edge extending around an entire periphery of the foldable substrate between the first major surface and the second major surface in the first portion and the second portion as well as between the first central surface area and the second central surface area in the central portion, the blunted edge comprising a first blunted surface area where the blunted edge meets the first major surface, and the blunted edge comprising a second blunted surface area where the blunted edge meets the second major surface.

2. The foldable substrate of claim 1, wherein a first thickness of the first blunted surface area in a direction of the substrate thickness is in a range from about 1 micrometer to about 50 micrometers, and a second thickness of the second blunted surface area in the direction of the substrate thickness is in a range from about 1 micrometer to about 50 micrometers.

3. The foldable substrate of claim 1, wherein the first portion comprises a first compressive stress region extending from the first major surface to a first depth of compression from the first major surface and a second compressive stress region extending from the second major surface to a second depth of compression from the second major surface, the second portion comprises a third compressive stress region extending from the first major surface to a third depth of compression from the first major surface and a fourth compressive stress region extending from the second major surface to a fourth depth of compression from the second major surface.

4. The foldable substrate of claim 3, further comprising a first depth of layer of one or more alkali metal ions associated with the first depth of compression, the first depth of layer as a percentage of the substrate thickness is in a range from about 10% to about 30%, a second depth of layer of one or more alkali metal ions associated with the second depth of compression, the second depth of layer as a percentage of the substrate thickness is in a range from about 10% to about 30%, a third depth of layer of one or more alkali metal ions associated with the third depth of compression, the third depth of layer as a percentage of the substrate thickness is in a range from about 10% to about 30%, a fourth depth of layer of one or more alkali metal ions associated with the fourth depth of compression, and the fourth depth of layer as a percentage of the substrate thickness is in a range from about 10% to about 30%.

5. The foldable substrate of claim 1, wherein the central portion is substantially unstrengthened.

6. The foldable substrate of claim 1, wherein the foldable substrate is substantially symmetric about a first plane extending in the direction of the central thickness and along a midline between the first portion and the second portion.

7. The foldable substrate of claim 6, wherein the foldable substrate is substantially symmetric about a second plane extending in the direction of the central thickness and perpendicular to the first plane.

8. The foldable substrate of claim 1, wherein the foldable substrate comprises a glass-based substrate or a ceramic-based substrate.

9. The foldable substrate of claim 1, wherein the foldable substrate achieves a parallel plate distance of 10 millimeters.

10. The foldable substrate of claim 1, wherein the foldable substrate comprises a minimum parallel plate distance in a range from about 2 millimeters to about 10 millimeters.

11. A method of making a foldable substrate comprising a substrate thickness defined between a first major surface and a second major surface opposite the first major surface, a central thickness less than the substrate thickness defined between a first central surface area and a second central surface area opposite the first central surface area, the first central surface area recessed from the first major surface by a first distance, and a central portion comprising the central thickness positioned between a first portion and a second portion, the method comprising:
laminating the foldable substrate with a first support layer contacting the first major surface and a second support layer contacting the second major surface; then,
removing a peripheral portion of an initial edge of the foldable substrate to form an intermediate edge of the foldable substrate, the initial edge extending around an entire periphery of the foldable substrate between the first major surface and the second major surface in the first portion and the second portion as well as between the first central surface area and the second central surface area in the central portion; then,
contacting the intermediate edge with a second etchant to form a blunted edge extending around an entire periphery of the foldable substrate between the first major surface and the second major surface in the first portion and the second portion as well as between the first central surface area and the second central surface area in the central portion, the blunted edge comprising a first blunted surface area where the blunted edge meets the first major surface, and the blunted edge comprising a second blunted surface area where the blunted edge meets the second major surface;
removing the first support layer and the second support layer; then,
disposing a first barrier layer over the first central surface area and disposing a second barrier layer over the second central surface area opposite the first central surface area; then,
chemically strengthening the first portion and the second portion; and then,
removing the first barrier layer and removing the second barrier layer.

12. The method of claim 11, wherein the first barrier layer comprises one of aluminum nitride, aluminum oxynitride, sputtered silicon nitride, or combinations thereof.

13. The method of claim 11, wherein the disposing the first barrier layer comprises sputtering, chemical vapor deposition, thermal evaporation, or electron-beam deposition.

14. The method of claim 11, wherein a first thickness of the first blunted surface area in a direction of the substrate thickness is in a range from about 1 micrometer to about 50 micrometers, and a second thickness of the second blunted surface area in the direction of the substrate thickness is in a range from about 1 micrometer to about 50 micrometers.

15. The method of claim 11, wherein contacting the intermediate edge with a second etchant comprises removing from about 1 micrometer to about 50 micrometers of material from the intermediate edge.

16. The method of claim 11, wherein, before the chemically strengthening, the foldable substrate is substantially unstrengthened.

17. The method of claim 11, further comprising, after removing the etch mask, further chemically strengthening the foldable substrate.

18. The method of claim 11, wherein the foldable substrate comprises a glass-based substrate or a ceramic-based substrate.

19. The method of claim 11, wherein the foldable substrate achieves a parallel plate distance of 10 millimeters.

20. The method of claim 11, wherein the foldable substrate comprises a minimum parallel plate distance in a range from about 2 millimeters to about 10 millimeters.
